(19) United States
(12) Patent Application Publication
(10) Pub. No.: US 2012/0120346 A1
(43) Pub. Date: May 17, 2012

(54) LIQUID CRYSTAL DISPLAY DEVICE AND METHOD FOR MANUFACTURING SAME

(76) Inventors: Iichiroh Inoue, Osaka (JP); Koichi Miyachi, Osaka (JP)

(21) Appl. No.: 13/387,484

(22) PCT Filed: Jul. 27, 2010
(86) PCT No.: PCT/JP2010/062585

§ 371 Date: Jan. 27, 2012

(30) Foreign Application Priority Data
Jul. 28, 2009 (JP) 2009175742

(51) Int. Cl. G02F 1/1337; H01L 33/08; G02F 1/1333

(52) U.S. Cl. 349/85; 349/123; 438/30; 257/E33.012

(57) ABSTRACT

A liquid crystal display device (100) according to the present invention includes a vertical alignment type liquid crystal layer (3); and a pair of optical alignment films (12, 22). Each of a plurality of picture elements includes four liquid crystal domains (D1 through D4) having different tilt directions of liquid crystal molecules (3a) in the presence of an applied voltage. The four liquid crystal domains (D1 through D4) are arranged in a matrix of 2 rows×2 columns. The plurality of picture elements are an even number of picture elements including at least four picture elements for displaying different colors from each other, and include a first picture element of which a side parallel to a first direction has a prescribed first length L1 and a second picture element of which a side parallel to the first direction has a second length L2, which is different from the first length L1. In the first picture element, the four liquid crystal domains are arranged in a first pattern; and in the second picture element, the four liquid crystal domains are arranged in a second pattern which is different from the first pattern. The present invention can suppress increase of the cost and time required for optical alignment processing when the 4D-RTN mode is adopted to a multiple primary color liquid crystal display device or a liquid crystal display device using the picture element division driving technology.

### TECHNICAL FIELD

The present invention relates to a liquid crystal display device and a method for producing the same, and specifically a liquid crystal display device having a wide viewing angle characteristic and a method for producing the same.

### BACKGROUND ART

Liquid crystal display devices have been improved in terms of display characteristics, and are now used for TV receivers and the like more and more widely. The viewing angle characteristics of the liquid crystal display devices have been improved but are desired to be further improved. Especially, the viewing angle characteristics of liquid crystal display devices using a vertical alignment type liquid crystal layer (also referred to as the “VA-mode liquid crystal display devices”) are strongly desired to be improved.

VA-mode liquid crystal display devices currently used for large display devices of TVs and the like adopt a multi-domain structure in which a plurality of liquid crystal domains are formed in one picture element in order to improve the viewing angle characteristics. A mainly used method for forming the multi-domain structure is an MVA mode. The MVA mode is disclosed in, for example, Patent Document 1.

According to the MVA mode, a pair of substrates facing each other with a vertical alignment type liquid crystal layer interposed therebetween each include an alignment regulation structure on a surface thereof on the liquid crystal layer side. Owing to such alignment regulation structures, a plurality of domains having different alignment directions (tilt directions) of liquid crystal molecules (typically, there are four types of alignment directions) are formed in each picture element. As the alignment regulation structures, slits (openings) or ribs (protrusion structures) provided in or on electrodes are used, and an alignment regulation force is exerted from both sides of the liquid crystal layer.

However, in the case where the slits or ribs are used, unlike in the case where pretilt directions are defined by alignment films used in the conventional TN mode, the alignment regulation force on the liquid crystal molecules is nonuniform in the picture element because the slits and ribs are linear. This causes a problem that there occurs a response speed distribution. There is another problem that since the light transmittance of an area where the slits or ribs are provided is lowered, the display luminance is decreased.

In order to avoid the above-described problems, it is preferable that even in a VA-mode liquid crystal display device, the multi-domain structure is formed by defining the pretilt direction by means of alignment films. The present applicant has proposed a VA-mode liquid crystal display device having such a multi-domain structure in Patent Document 2.

In the liquid crystal display device disclosed in Patent Document 2, the pretilt directions are defined by alignment films to form a 4-domain alignment structure. Namely, when a voltage is applied to the liquid crystal layer, four liquid crystal domains are formed in one picture element. Such a 4-domain alignment structure is occasionally referred simply as the “4D structure”.

In the liquid crystal display device disclosed in Patent Document 2, the pretilt direction defined by one of a pair of alignment films facing each other with the liquid crystal layer interposed therebetween and the pretilt direction defined by the other alignment film are different from each other by about 90°. Therefore, in the presence of an applied voltage, liquid crystal molecules are twist-aligned. A VA-mode in which the liquid crystal molecules are twist-aligned by use of a pair of vertical alignment films provided such that the pretilt directions (alignment directions) are perpendicular to each other is occasionally referred to also as the “VAIN (Vertical Alignment Twisted Nematic) mode” or the “RTN (Reverse Twisted Nematic) mode”. As described above, since the liquid crystal display device disclosed in Patent Document 2 forms the 4D structure, the present applicant refers the display mode of the liquid crystal display device disclosed in Patent Document 2 as the “4D-RTN mode”.

As a specific technique for causing the alignment films to define the pretilt directions of the liquid crystal molecules, as described in Patent Document 2, optical alignment processing is considered prospective. Optical alignment, which can be performed in a non-contact manner, does not generate static electricity due to friction unlike rubbing and thus can improve the yield.

Recently, for the purpose of further improving the viewing angle characteristics of VA-mode liquid crystal display devices, a picture element division driving technology have been put into practice (e.g., Patent Documents 3 and 4). According to the picture element division driving technology, the problem that the γ characteristic (gamma characteristic) as observed in a front direction and the γ characteristic as observed in an oblique direction are different from each other is alleviated; namely, the viewing angle dependence of the γ characteristic is improved. The “γ characteristic” is a gray scale dependence of the display luminance. According to the picture element division driving technology, one picture element is formed of a plurality of sub picture elements which can display different levels of luminance from each other, so that a prescribed luminance for a display signal voltage which is input to the picture element is displayed. Namely, the picture element division driving technology is a technology for improving the viewing angle dependence of the γ characteristic of a picture element by synthesizing different γ characteristics of a plurality of sub picture elements included in the picture element.

Recently, it is desired to enlarge a color reproduction range of a liquid crystal display device (range of displayable colors) in addition to the above-described improvement of the viewing angle characteristics. In a general liquid crystal display device, one pixel is formed of three picture elements respectively for displaying three primary colors of light, i.e., red, green and blue. Owing to this, color display is realized. By contrast, a technique of enlarging the color reproduction range of a liquid crystal display device by using four or more colors for display has been proposed as disclosed in Patent Document 5.

For example, in a liquid crystal display device 900 shown in FIG. 77, one pixel P is formed of four picture elements R, G, B and Y for displaying red, green, blue and yellow respectively. Owing to this structure, the color reproduction range can be enlarged. Alternatively, one pixel may be formed of five picture elements for displaying red, green, blue, yellow and cyan respectively, or of six picture elements for displaying red, green, blue, yellow, cyan and magenta respectively. By use of four or more primary colors, the color reproduction range can be made larger than that of a conventional liquid crystal display device which provides display by use of three primary colors. A liquid crystal display device which provides display by use of four or more primary colors is referred to as the “multiple primary color display device”.

### CITATION LIST

### Patent Literature

Patent Document 1: Japanese Laid-Open Patent Publication No. 11-242225

Patent Document 2: WO2006/132369

Patent Document 3: Japanese Laid-Open Patent Publication No. 2004-62146

Patent Document 4: Japanese Laid-Open Patent Publication No. 2004-78157

Patent Document 5: PCT Japanese National-Phase Laid-Open Patent Publication No. 2004-529396

### SUMMARY OF INVENTION

### Technical Problem

As a result of making studies on adopting the 4D-RTN mode to a multiple primary color liquid crystal display device, the present inventors found that in the case where pixels have a certain structure, a problem occurs in terms of production when the 4D-RTN mode is adopted. Specifically, in the case where one pixel includes a picture element of a different size from that of another picture element, “shifted exposure” cannot be performed for the optical alignment processing as described in detail later. This increases the cost and time required for the optical alignment processing. As a result of making studies on adopting the 4D-RTN mode to a liquid crystal display device using the picture element division driving technology, the present inventors found that substantially the same problem occurs in the case where one picture element includes a sub picture element of a different size from that of another sub picture element.

The present invention, made in light of the above-described problems, has an object of suppressing the increase of the cost and time required for optical alignment processing when the 4D-RTN mode is adopted to a multiple primary color liquid crystal display device or a liquid crystal display device using the picture element division driving technology.

### Solution to Problem

A liquid crystal display device according to the present invention includes a vertical alignment type liquid crystal layer; a first substrate and a second substrate facing each other with the liquid crystal layer interposed therebetween; a first electrode provided on the liquid crystal layer side of the first substrate and a second electrode provided on the liquid crystal layer side of the second substrate; and a pair of optical alignment films provided between the first electrode and the liquid crystal layer and between the second electrode and the liquid crystal layer. There are pixels which are each defined by a plurality of picture elements each having a shape including a side parallel to a prescribed first direction and a side parallel to a second direction crossing the first direction; each of the plurality of picture elements includes a first liquid crystal domain in which a tilt direction of liquid crystal molecules at a center and in the vicinity thereof in a layer plane and in a thickness direction of the liquid crystal layer when a voltage is applied between the first electrode and the second electrode is a predetermined first tilt direction, a second liquid crystal domain in which the tilt direction is a predetermined second tilt direction, a third liquid crystal domain in which the tilt direction is a predetermined third tilt direction, and a fourth liquid crystal domain in which the tilt direction is a predetermined fourth tilt direction; the first, second, third and fourth tilt directions are such that a difference between any two these four directions is approximately equal to an integral multiple of 90°; and the first, second, third and fourth liquid crystal domains are arranged in a matrix of 2 rows×2 columns; the plurality of picture elements are an even number of picture elements including at least four picture elements for displaying different colors from each other; the even number of picture elements include a first picture element of which the side parallel to the first direction has a prescribed first length L1 and a second picture element of which the side parallel to the first direction has a second length L2 which is different from the first length L1; in the first picture element, the first, second, third and fourth liquid crystal domains are arranged in a first pattern; and in the second picture element, the first, second, third and fourth liquid crystal domains are arranged in a second pattern which is different from the first pattern.

In a preferable embodiment, in each of the even number of picture elements, when a gray scale is displayed, a dark area darker than the gray scale appears; the dark area appearing in the first picture element is generally gammadion-shaped; and the dark area appearing in the second picture element is generally shaped like the letter “8”.

In a preferable embodiment, the first, second, third and fourth liquid crystal domains are located such that the tilt directions of two adjacent liquid crystal domains thereamong are different by 90° from each other; the first tilt direction and the third tilt direction have an angle of about 180° with respect to each other. In the first picture element, a portion of edges of the first electrode close to the first liquid crystal domain includes a first edge portion such that an azimuthal angle direction perpendicular to the first edge portion and directed to the inside of the first electrode has an angle exceeding 90° with respect to the first tilt direction; a portion of edges of the first electrode close to the second liquid crystal domain includes a second edge portion such that an azimuthal angle direction perpendicular to the second edge portion and directed to the inside of the first electrode has an angle exceeding 90° with respect to the second tilt direction; a portion of edges of the first electrode close to the third liquid crystal domain includes a third edge portion such that an azimuthal angle direction perpendicular to the third edge portion and directed to the inside of the first electrode has an angle exceeding 90° with respect to the third tilt direction; a portion of edges of the first electrode close to the fourth liquid crystal domain includes a fourth edge portion such that an azimuthal angle direction perpendicular to the fourth edge portion and directed to the inside of the first electrode has an angle exceeding 90° with respect to the fourth tilt direction; and the first edge portion and the third edge portion are generally parallel to one of a horizontal direction and a vertical direction of a display plane, and the second edge portion and the fourth edge portion are generally parallel to the other of the horizontal direction and the vertical direction of the display plane. In the second picture element, a portion of edges of the first electrode close to a first liquid crystal domain includes a first edge portion such that an azimuthal angle direction perpendicular to the first edge portion and directed to the inside of the first electrode has an angle exceeding 90° with respect to the first tilt direction; a portion of edges of the first electrode close to the third liquid crystal domain includes a third edge portion such that an azimuthal angle direction perpendicular to the third edge portion and directed to the inside of the first electrode has an angle exceeding 90° with respect to the third tilt direction; and the first edge portion and the third edge portion each include a first portion generally parallel to the horizontal direction of the display plane and a second portion generally parallel to the vertical direction of the display plane.

In a preferable embodiment, the side of each of the first picture element and the second picture element which is parallel to the second direction has a prescribed third length L3; and the even number of picture elements further include a third picture element of which the side parallel to the second direction has a fourth length L4 which is different from the third length L3, and a fourth picture element of which the side parallel to the second direction has the fourth length L4.

In a preferable embodiment, in the third picture element, the first, second, third and fourth liquid crystal domains are arranged in a third pattern which is different from the first and second patterns; and in the fourth picture element, the first, second, third and fourth liquid crystal domains are arranged in a fourth pattern which is different from the first, second and third patterns.

In a preferable embodiment, the at least four picture elements for displaying different colors from each other include a red picture element for displaying red, a green picture element for displaying green, a blue picture element for displaying blue, and a yellow picture element for displaying yellow.

In a preferable embodiment, the at least four picture elements further include a cyan picture element for displaying cyan, and a magenta picture element for displaying magenta.

Alternatively, a liquid crystal display device according to the present invention includes a vertical alignment type liquid crystal layer; a first substrate and a second substrate facing each other with the liquid crystal layer interposed therebetween; a first electrode provided on the liquid crystal layer side of the first substrate and a second electrode provided on the liquid crystal layer side of the second substrate; and a pair of optical alignment films provided between the first electrode and the liquid crystal layer and between the second electrode and the liquid crystal layer. There are pixels which are each defined by a plurality of picture elements; each of the plurality of picture elements includes a plurality of sub picture elements capable of applying different voltages to parts of the liquid crystal layer corresponding to the respective sub picture elements; each of the plurality of sub picture elements includes a first liquid crystal domain in which a tilt direction of liquid crystal molecules at a center and in the vicinity thereof in a layer plane and in a thickness direction of the liquid crystal layer when a voltage is applied between the first electrode and the second electrode is a predetermined first tilt direction, a second liquid crystal domain in which the tilt direction is a predetermined second tilt direction, a third liquid crystal domain in which the tilt direction is a predetermined third tilt direction, and a fourth liquid crystal domain in which the tilt direction is a predetermined fourth tilt direction; the first, second, third and fourth tilt directions are such that a difference between any two of these four directions is approximately equal to an integral multiple of 90°; and the first, second, third and fourth liquid crystal domains are arranged in a matrix of 2 rows×2 columns; the plurality of sub picture elements are an even number of sub picture elements each having a shape including a side parallel to a prescribed first direction and a side parallel to a second direction crossing the first direction; the even number of sub picture elements include a first sub picture element of which the side parallel to the first direction has a prescribed first length L1 and a second sub picture element of which the side parallel to the first direction has a second length L2 which is different from the first length L1; in the first sub picture element, the first, second, third and fourth liquid crystal domains are arranged in a first pattern; and in the second sub picture element, the first, second, third and fourth liquid crystal domains are arranged in a second pattern which is different from the first pattern.

In a preferable embodiment, in each of the even number of sub picture elements, when a gray scale is displayed, a dark area darker than the gray scale appears; the dark area appearing in the first sub picture element is generally gammadion-shaped; and the dark area appearing in the second sub picture element is generally shaped like the letter “8”.

In a preferable embodiment, the first, second, third and fourth liquid crystal domains are located such that the tilt directions of two adjacent liquid crystal domains thereamong are different by 90° from each other; the first tilt direction and the third tilt direction have an angle of about 180° with respect to each other. In the first sub picture element, a portion of edges of the first electrode close to the first liquid crystal domain includes a first edge portion such that an azimuthal angle direction perpendicular to the first edge portion and directed to the inside of the first electrode has an angle exceeding 90° with respect to the first tilt direction; a portion of edges of the first electrode close to the second liquid crystal domain includes a second edge portion such that an azimuthal angle direction perpendicular to the second edge portion and directed to the inside of the first electrode has an angle exceeding 90° with respect to the second tilt direction; a portion of edges of the first electrode close to the third liquid crystal domain includes a third edge portion such that an azimuthal angle direction perpendicular to the third edge portion and directed to the inside of the first electrode has an angle exceeding 90° with respect to the third tilt direction; a portion of edges of the first electrode close to the fourth liquid crystal domain includes a fourth edge portion such that an azimuthal angle direction perpendicular to the fourth edge portion and directed to the inside of the first electrode has an angle exceeding 90° with respect to the fourth tilt direction; and the first edge portion and the third edge portion are generally parallel to one of a horizontal direction and a vertical direction of a display plane, and the second edge portion and the fourth edge portion are generally parallel to the other of the horizontal direction and the vertical direction of the display plane. In the second sub picture element, a portion of edges of the first electrode close to a first liquid crystal domain includes a first edge portion such that an azimuthal angle direction perpendicular to the first edge portion and directed to the inside of the first electrode has an angle exceeding 90° with respect to the first tilt direction; a portion of edges of the first electrode close to the third liquid crystal domain includes a third edge portion such that an azimuthal angle direction perpendicular to the third edge portion and directed to the inside of the first electrode has an angle exceeding 90° with respect to the third tilt direction; and the first edge portion and the third edge portion each include a first portion generally parallel to the horizontal direction of the display plane and a second portion generally parallel to the vertical direction of the display plane.

In a preferable embodiment, the liquid crystal display device according to the present invention further includes a pair of polarizing plates facing each other with the liquid crystal layer interposed therebetween and located such that transmission axes thereof are generally perpendicular to each other. The tilt directions of the first, second, third and fourth liquid crystal domains have an angle of about 45° with respect to the transmission axes of the pair of polarizing plates.

In a preferable embodiment, the liquid crystal layer contains the liquid crystal molecules having a negative dielectric anisotropy; and a pretilt direction defined by one of the pair of optical alignment films and a pretilt direction defined by the other of the pair of optical alignment films are different by 90° from each other.

A method for producing a liquid crystal display device according to the present invention is a method for producing a liquid crystal display device including a vertical alignment type liquid crystal layer; a first substrate and a second substrate facing each other with the liquid crystal layer interposed therebetween; a first electrode provided on the liquid crystal layer side of the first substrate and a second electrode provided on the liquid crystal layer side of the second substrate; and a first optical alignment film provided between the first electrode and the liquid crystal layer and a second optical alignment film provided between the second electrode and the liquid crystal layer; wherein there are pixels which are each defined by a plurality of picture elements each having a shape including a side parallel to a prescribed first direction and a side parallel to a second direction crossing the first direction; each of the plurality of picture elements includes a first liquid crystal domain in which a tilt direction of liquid crystal molecules at a center and in the vicinity thereof in a layer plane and in a thickness direction of the liquid crystal layer when a voltage is applied between the first electrode and the second electrode is a predetermined first tilt direction, a second liquid crystal domain in which the tilt direction is a predetermined second tilt direction, a third liquid crystal domain in which the tilt direction is a predetermined third tilt direction, and a fourth liquid crystal domain in which the tilt direction is a predetermined fourth tilt direction; the first, second, third and fourth tilt directions are such that a difference between any two of these four directions is approximately equal to an integral multiple of 90°; and the first, second, third and fourth liquid crystal domains are arranged in a matrix of 2 rows×2 columns; the plurality of picture elements are an even number of picture elements including at least four picture elements for displaying different colors from each other; and the even number of picture elements include a first picture element of which the side parallel to the first direction has a prescribed first length L1 and a second picture element of which the side parallel to the first direction has a second length L2 which is different from the first length L1. The method includes a step (A) of forming a first area having a first pretilt direction and a second area having a second pretilt direction which is antiparallel to the first pretilt direction, in an area of the first optical alignment film corresponding to each of the even number of picture elements by optical alignment processing; and a step (B) of forming a third area having a third pretilt direction and a fourth area having a fourth pretilt direction which is antiparallel to the third pretilt direction, in an area of the second optical alignment film corresponding to each of the even number of picture elements by optical alignment processing. The step (A) of forming the first area and the second area includes a first exposure step of directing light to a part of the first optical alignment film which is to be the first area; and a second exposure step of directing light to a part of the first optical alignment film which is to be the second area, after the first exposure step. The first exposure step and the second exposure step are performed by use of one, common first photomask including a plurality of light shielding parts extending like stripes parallel to the second direction and a plurality of light transmitting parts located between the plurality of light shielding parts; and each of the plurality of light transmitting parts of the first photomask has a width W1 which is equal to a sum of half of the first length L1 and half of the second length L2.

In a preferable embodiment, the step (A) of forming the first area and the second area further includes a first photomask locating step of, before the first exposure step, locating the first photomask such that a part of the first optical alignment film corresponding to about half of the first picture element and about half of the second picture element overlaps each of the plurality of light transmitting parts; and a first photomask moving step of, between the first exposure step and the second exposure step, shifting the first photomask in the first direction by a prescribed distance D1.

In a preferable embodiment, the prescribed distance D1 is about 1/m (m is an even number of 2 or greater) of a width PW1 of the pixel in the first direction.

In a preferable embodiment, the width W1 of each of the plurality of light transmitting parts, a width W2 of each of the plurality of light shielding parts, the first length L1 and the second L2 fulfill the following relationship expression:

W1=W2=(L1+L2)/2.

In a preferable embodiment, the width W1 (μm) of each of the plurality of light transmitting parts, a width W2 (μm) of each of the plurality of light shielding parts, the first length L1 (μm) and the second length L2 (μm) fulfill the following relationship expressions:

W1=(L1+L2)/2+Δ

W2=(L1+L2)/2−Δ

0<Δ≦10.

In a preferable embodiment, the side of each of the first picture element and the second picture element which is parallel to the second direction has a prescribed third length L3; and the even number of picture elements further include a third picture element of which the side parallel to the second direction has a fourth length L4 which is different from the third length L3, and a fourth picture element of which the side parallel to the second direction has the fourth length L4. The step (B) of forming the third area and the fourth area includes a third exposure step of directing light to a part of the second optical alignment film which is to be the third area; and a fourth exposure step of directing light to a part of the second optical alignment film which is to be the fourth area, after the third exposure step. The third exposure step and the fourth exposure step are performed by use of one, common second photomask including a plurality of light shielding parts extending like stripes parallel to the first direction and a plurality of light transmitting parts located between the plurality of light shielding parts; and each of the plurality of light transmitting parts of the second photomask has a width W3 which is equal to a sum of half of the third length L3 and half of the fourth length L4.

In a preferable embodiment, the step (B) of forming the third area and the fourth area further includes a second photomask locating step of, before the third exposure step, locating the second photomask such that a part of the second optical alignment film corresponding to about half of the third picture element and about half of the fourth picture element overlaps each of the plurality of light transmitting parts; and a second photomask moving step of, between the third exposure step and the fourth exposure step, shifting the second photomask in the second direction by a prescribed distance D2.

In a preferable embodiment, the prescribed distance D2 is about 1/n (n is an even number of 2 or greater) of a width PW2 of the pixel in the second direction.

In a preferable embodiment, the width W3 of each of the plurality of light transmitting parts of the second photomask, a width W4 of each of the plurality of light shielding parts of the second photomask, the third length L3 and the fourth length L4 fulfill the following relationship expression:

W3=W4=(L3+L4)/2.

In a preferable embodiment, the width W3 (μm) of each of the plurality of light transmitting parts of the second photomask, a width W4 (μm) of each of the plurality of light shielding parts of the second photomask, the third length L3 (μm) and the fourth length L4 (μm) fulfill the following relationship expressions:

W3=(L3+L4)/2+Δ′

W4=(L3+L4)/2−Δ′

0<Δ′≦10.

Alternatively, a method for producing a liquid crystal display device is a method for producing a liquid crystal display device including a vertical alignment type liquid crystal layer; a first substrate and a second substrate facing each other with the liquid crystal layer interposed therebetween; a first electrode provided on the liquid crystal layer side of the first substrate and a second electrode provided on the liquid crystal layer side of the second substrate; and a first of optical alignment film provided between the first electrode and the liquid crystal layer and a second optical alignment film provided between the second electrode and the liquid crystal layer; wherein: there are pixels which are each defined by a plurality of picture elements; each of the plurality of picture elements includes a plurality of sub picture elements capable of applying different voltages to parts of the liquid crystal layer corresponding to the respective sub picture elements; each of the plurality of sub picture elements includes a first liquid crystal domain in which a tilt direction of liquid crystal molecules at a center and in the vicinity thereof in a layer plane and in a thickness direction of the liquid crystal layer when a voltage is applied between the first electrode and the second electrode is a predetermined first tilt direction, a second liquid crystal domain in which the tilt direction is a predetermined second tilt direction, a third liquid crystal domain in which the tilt direction is a predetermined third tilt direction, and a fourth liquid crystal domain in which the tilt direction is a predetermined fourth tilt direction; the first, second, third and fourth tilt directions are such that a difference between any two of these four directions is approximately equal to an integral multiple of 90°; and the first, second, third and fourth liquid crystal domains are arranged in a matrix of 2 rows×2 columns; the plurality of sub picture elements are an even number of sub picture elements each having a shape including a side parallel to a prescribed first direction and a side parallel to a second direction crossing the first direction; and the even number of sub picture elements include a first sub picture element of which the side parallel to the first direction has a prescribed first length L1 and a second sub picture element of which the side parallel to the first direction has a second length L2 which is different from the first length L1. The method includes a step (A) of forming a first area having a first pretilt direction and a second area having a second pretilt direction which is antiparallel to the first pretilt direction, in an area of the first optical alignment film corresponding to each of the even number of sub picture elements by optical alignment processing; and a step (B) of forming a third area having a third pretilt direction and a fourth area having a fourth pretilt direction which is antiparallel to the third pretilt direction, in an area of the second optical alignment film corresponding to each of the even number of sub picture elements by optical alignment processing. The step (A) of forming the first area and the second area includes a first exposure step of directing light to a part of the first optical alignment film which is to be the first area; and a second exposure step of directing light to a part of the first optical alignment film which is to be the second area, after the first exposure step. The first exposure step and the second exposure step are performed by use of one, common first photomask including a plurality of light shielding parts extending like stripes parallel to the second direction and a plurality of light transmitting parts located between the plurality of light shielding parts; and each of the plurality of light transmitting parts of the first photomask has a width W1 which is equal to a sum of half of the first length L1 and half of the second length L2.

In a preferable embodiment, the step (A) of forming the first area and the second area further includes a first photomask locating step of, before the first exposure step, locating the first photomask such that a part of the first optical alignment film corresponding to about half of the first sub picture element and about half of the second sub picture element overlaps each of the plurality of light transmitting parts; and a first photomask moving step of, between the first exposure step and the second exposure step, shifting the first photomask in the first direction by a prescribed distance D1.

In a preferable embodiment, the prescribed distance D1 is about 1/m (m is an even number of 2 or greater) of a width PW1 of the picture element in the first direction.

In a preferable embodiment, the width W1 of each of the plurality of light transmitting parts, a width W2 of each of the plurality of light shielding parts, the first length L1 and the second L2 fulfill the following relationship expression:

W1=W2=(L1+L2)/2.

In a preferable embodiment, the width W1 (μm) of each of the plurality of light transmitting parts, a width W2 (μm) of each of the plurality of light shielding parts, the first length L1 (μm) and the second length L2 (μm) fulfill the following relationship expressions:

W1=(L1+L2)/2+Δ

W2=(L1+L2)/2−Δ

0<Δ≦10.

### Advantageous Effects of Invention

According to the present invention, the increase of the cost and time required for optical alignment processing can be suppressed even when the 4D-RTN mode is adopted to a multiple primary color liquid crystal display device or a liquid crystal display device using the picture element division driving technology.

### BRIEF DESCRIPTION OF DRAWINGS

FIG. 1 shows an example of picture element having a 4-domain alignment structure.

FIG. 2 shows a method for dividing the picture element shown in FIG. 1 into domains having different alignment directions; FIG. 2(a) shows pretilt directions on the side of a TFT substrate side; FIG. 2(b) shows pretilt directions on the side of a CF substrate side; and FIG. 2(c) shows tilt directions and a dark area obtained when a voltage is applied to a liquid crystal layer.

FIG. 3 is provided for explaining why dark lines appear in the vicinity of edges of a picture element electrode corresponding to the picture element shown in FIG. 1.

FIG. 4 shows another method for dividing a picture element into domains having different alignment directions; FIG. 4(a) shows a pretilt direction on the side of the TFT substrate side; FIG. 4(b) shows a pretilt direction on the side of the CF substrate side; and FIG. 4(c) shows tilt directions and a dark area obtained when a voltage is applied to the liquid crystal layer.

FIG. 5 shows still another method for dividing a picture element into domains having different alignment directions; FIG. 5(a) shows a pretilt direction on the side of the TFT substrate side; FIG. 5(b) shows a pretilt direction on the side of the CF substrate side; and FIG. 5(c) shows tilt directions and a dark area obtained when a voltage is applied to the liquid crystal layer.

FIG. 6 shows still another method for dividing a picture element into domains having different alignment directions; FIG. 6(a) shows a pretilt direction on the side of the TFT substrate side; FIG. 6(b) shows a pretilt direction on the side of the CF substrate side; and FIG. 6(c) shows tilt directions and a dark area obtained when a voltage is applied to the liquid crystal layer.

FIG. 7 schematically shows a structure of a conventional liquid crystal display device 900 adopting the 4D-RTN mode, and is a plan view showing two pixels.

FIGS. 8(a), (b) and (c) show optical alignment processing for realizing the structure shown in FIG. 7; FIG. 8(a) shows a photomask used for the optical alignment processing performed on an optical alignment film of the TFT substrate; and FIGS. 8(b) and (c) show exposure steps performed in the optical alignment processing on the optical alignment film of the TFT substrate.

FIGS. 9(a), (b) and (c) show the optical alignment processing for realizing the structure shown in FIG. 7; FIG. 9(a) shows a photomask used for the optical alignment processing performed on an optical alignment film of the CF substrate; and FIGS. 9(b) and (c) show exposure steps performed in the optical alignment processing on the optical alignment film of the CF substrate.

FIG. 10 schematically shows a structure of a liquid crystal display device 900′ in which a red picture element R and a blue picture element B have a size larger than that of a green picture element G and a yellow picture element Y, and is a plan view showing two pixels.

FIG. 11 shows a photomask used for the optical alignment processing performed on an optical alignment film of a TFT substrate included in the liquid crystal display device 900′.

FIGS. 12(a), (b) and (c) show exposure steps performed in the optical alignment processing on the optical alignment film of the TFT substrate.

FIG. 13 schematically shows a liquid crystal display device 100 in a preferable embodiment according to the present invention, and is a cross-sectional view showing one picture element.

FIG. 14 schematically shows the liquid crystal display device 100 in the preferable embodiment according to the present invention, and is a plan view showing two pixels.

FIG. 15 shows a photomask used for the optical alignment processing performed on an optical alignment film of a TFT substrate included in the liquid crystal display device 100.

FIGS. 16(a), (b) and (c) show the optical alignment processing performed on the optical alignment film of the TFT substrate included in the liquid crystal display device 100.

FIGS. 17(a), (b) and (c) show the optical alignment processing performed on the optical alignment film of the TFT substrate included in the liquid crystal display device 100.

FIG. 18 shows a photomask used for the optical alignment processing performed on an optical alignment film of a CF substrate included in the liquid crystal display device 100.

FIGS. 19(a), (b) and (c) show the optical alignment processing performed on the optical alignment film of the CF substrate included in the liquid crystal display device 100.

FIGS. 20(a), (b) and (c) show the optical alignment processing performed on the optical alignment film of the CF substrate included in the liquid crystal display device 100.

FIG. 21 schematically shows the liquid crystal display device 100 in the preferable embodiment according to the present invention, and is a plan view showing two pixels.

FIGS. 22(a), (b) and (c) show the optical alignment processing performed on the optical alignment film of the TFT substrate included in the liquid crystal display device 100.

FIGS. 23(a), (b) and (c) show the optical alignment processing performed on the optical alignment film of the TFT substrate included in the liquid crystal display device 100.

FIG. 24 shows double-exposed areas formed by the optical alignment processing shown in FIG. 22 and FIG. 23.

FIG. 25 schematically shows a liquid crystal display device 200 in a preferable embodiment according to the present invention, and is a plan view showing two pixels.

FIG. 26 shows a photomask used for the optical alignment processing performed on an optical alignment film of a TFT substrate included in the liquid crystal display device 200.

FIGS. 27(a), (b) and (c) show the optical alignment processing performed on the optical alignment film of the TFT substrate included in the liquid crystal display device 200.

FIGS. 28(a), (b) and (c) show the optical alignment processing performed on the optical alignment film of the TFT substrate included in the liquid crystal display device 200.

FIG. 29 shows a photomask used for the optical alignment processing performed on an optical alignment film of a CF substrate included in the liquid crystal display device 200.

FIGS. 30(a), (b) and (c) show the optical alignment processing performed on the optical alignment film of the CF substrate included in the liquid crystal display device 200.

FIGS. 31(a), (b) and (c) show the optical alignment processing performed on the optical alignment film of the CF substrate included in the liquid crystal display device 200.

FIG. 32 schematically shows a liquid crystal display device 300 in a preferable embodiment according to the present invention, and is a plan view showing two pixels.

FIG. 33 shows a photomask used for the optical alignment processing performed on an optical alignment film of a CF substrate included in the liquid crystal display device 300.

FIGS. 34(a), (b) and (c) show the optical alignment processing performed on the optical alignment film of the CF substrate included in the liquid crystal display device 300.

FIGS. 35(a), (b) and (c) show the optical alignment processing performed on the optical alignment film of the CF substrate included in the liquid crystal display device 300.

FIG. 36 shows a photomask used for the optical alignment processing performed on an optical alignment film of a TFT substrate included in the liquid crystal display device 300.

FIGS. 37(a), (b) and (c) show the optical alignment processing performed on the optical alignment film of the TFT substrate included in the liquid crystal display device 300.

FIGS. 38(a), (b) and (c) show the optical alignment processing performed on the optical alignment film of the TFT substrate included in the liquid crystal display device 300.

FIG. 39 schematically shows the liquid crystal display device 300 in the preferable embodiment according to the present invention, and is a plan view showing two pixels.

FIG. 40 schematically shows a liquid crystal display device 400 in a preferable embodiment according to the present invention, and is a plan view showing two pixels.

FIG. 41 shows a photomask used for the optical alignment processing performed on an optical alignment film of a CF substrate included in the liquid crystal display device 400.

FIGS. 42(a), (b) and (c) show the optical alignment processing performed on the optical alignment film of the CF substrate included in the liquid crystal display device 400.

FIGS. 43(a), (b) and (c) show the optical alignment processing performed on the optical alignment film of the CF substrate included in the liquid crystal display device 400.

FIG. 44 shows a photomask used for the optical alignment processing performed on an optical alignment film of a TFT substrate included in the liquid crystal display device 400.

FIGS. 45(a), (b) and (c) show the optical alignment processing performed on the optical alignment film of the TFT substrate included in the liquid crystal display device 400.

FIGS. 46(a), (b) and (c) show the optical alignment processing performed on the optical alignment film of the TFT substrate included in the liquid crystal display device 400.

FIG. 47 schematically shows a liquid crystal display device 500 in a preferable embodiment according to the present invention, and is a plan view showing two pixels.

FIG. 48 shows a photomask used for the optical alignment processing performed on an optical alignment film of a TFT substrate included in the liquid crystal display device 500.

FIGS. 49(a), (b) and (c) show the optical alignment processing performed on the optical alignment film of the TFT substrate included in the liquid crystal display device 500.

FIGS. 50(a), (b) and (c) show the optical alignment processing performed on the optical alignment film of the TFT substrate included in the liquid crystal display device 500.

FIG. 51 shows a photomask used for the optical alignment processing performed on an optical alignment film of a CF substrate included in the liquid crystal display device 500.

FIGS. 52(a), (b) and (c) show the optical alignment processing performed on the optical alignment film of the CF substrate included in the liquid crystal display device 500.

FIGS. 53(a), (b) and (c) show the optical alignment processing performed on the optical alignment film of the CF substrate included in the liquid crystal display device 500.

FIG. 54 schematically shows a liquid crystal display device 600 in a preferable embodiment according to the present invention, and is a plan view showing two pixels.

FIG. 55 shows a photomask used for the optical alignment processing performed on an optical alignment film of a TFT substrate included in the liquid crystal display device 600.

FIGS. 56(a), (b) and (c) show the optical alignment processing performed on the optical alignment film of the TFT substrate included in the liquid crystal display device 600.

FIGS. 57(a), (b) and (c) show the optical alignment processing performed on the optical alignment film of the TFT substrate included in the liquid crystal display device 600.

FIG. 58 shows a photomask used for the optical alignment processing performed on an optical alignment film of a CF substrate included in the liquid crystal display device 600.

FIGS. 59(a), (b) and (c) show the optical alignment processing performed on the optical alignment film of the CF substrate included in the liquid crystal display device 600.

FIGS. 60(a), (b) and (c) show the optical alignment processing performed on the optical alignment film of the CF substrate included in the liquid crystal display device 600.

FIG. 61 schematically shows a liquid crystal display device 700 in a preferable embodiment according to the present invention, and is a plan view showing two pixels.

FIG. 62 shows a photomask used for the optical alignment processing performed on an optical alignment film of a CF substrate included in the liquid crystal display device 700.

FIGS. 63(a), (b) and (c) show the optical alignment processing performed on the optical alignment film of the CF substrate included in the liquid crystal display device 700.

FIGS. 64(a), (b) and (c) show the optical alignment processing performed on the optical alignment film of the CF substrate included in the liquid crystal display device 700.

FIG. 65 shows a photomask used for the optical alignment processing performed on an optical alignment film of a TFT substrate included in the liquid crystal display device 700.

FIGS. 66(a), (b) and (c) show the optical alignment processing performed on the optical alignment film of the TFT substrate included in the liquid crystal display device 700.

FIGS. 67(a), (b) and (c) show the optical alignment processing performed on the optical alignment film of the TFT substrate included in the liquid crystal display device 700.

FIG. 68 shows an example of structure of a picture element for performing picture element division driving.

FIG. 69 shows another example of structure of a picture element for performing picture element division driving.

FIG. 70 schematically shows a liquid crystal display device 800 in a preferable embodiment according to the present invention, and is a plan view showing two pixels.

FIG. 71 shows a photomask used for the optical alignment processing performed on an optical alignment film of a CF substrate included in the liquid crystal display device 800.

FIGS. 72(a), (b) and (c) show the optical alignment processing performed on the optical alignment film of the CF substrate included in the liquid crystal display device 800.

FIGS. 73(a), (b) and (c) show the optical alignment processing performed on the optical alignment film of the CF substrate included in the liquid crystal display device 800.

FIG. 74 shows a photomask used for the optical alignment processing performed on an optical alignment film of a TFT substrate included in the liquid crystal display device 800.

FIGS. 75(a), (b) and (c) show the optical alignment processing performed on the optical alignment film of the TFT substrate included in the liquid crystal display device 800.

FIGS. 76(a), (b) and (c) show the optical alignment processing performed on the optical alignment film of the TFT substrate included in the liquid crystal display device 800.

FIG. 77 schematically shows a conventional multiple primary color liquid crystal display device 900, and is a plan view showing two pixels.

### DESCRIPTION OF EMBODIMENTS

Hereinafter, embodiments of the present invention will be described with reference to the drawings. The present invention is not limited to the following embodiments, and is widely applicable to a multiple primary color liquid crystal display device adopting the 4D-RTN mode, or a liquid crystal display device using the picture element division driving technology and adopting the 4D-RTN mode. The 4D-RTN mode is, as described above, the RTN mode in which each picture element has a 4-domain alignment structure (4D structure) (VAIN mode). A liquid crystal display device adopting the 4D-RTN mode includes a vertical alignment type liquid crystal layer.

In this specification, the term “vertical alignment type liquid crystal layer” refers to a liquid crystal layer in which liquid crystal molecules are aligned at an angle of about 85° or greater with respect to surfaces of vertical alignment films. The liquid crystal molecules contained in the vertical alignment type liquid crystal layer have a negative dielectric anisotropy. By a combination of the vertical alignment type liquid crystal layer and a pair of polarizing plates facing each other with the liquid crystal layer interposed therebetween and located in crossed Nicols (i.e., located such that transmission axes thereof are generally perpendicular to each other), normally black mode display is provided.

In this specification, the term “picture element” refers to the minimum unit which represents a particular gray scale level in display, and corresponds to a unit representing a gray scale level of each of primary colors used for display (red, green, blue and the like) (a “picture element” is also referred to as a “dot”). A combination of a plurality of picture elements forms (defines) one “pixel”, which is the minimum unit for providing color display. The term “sub picture element” refers to a unit for displaying a level of luminance. A plurality of sub picture elements are included in one picture element and are capable of displaying different levels of luminance from each other. Such a plurality of sub picture elements display a prescribed level of luminance (gray scale) for a display signal voltage which is input to one picture element.

The term “pretilt direction” refers to an alignment direction of a liquid crystal molecule defined by an alignment film and is an azimuthal angle direction in a display plane. An angle of the liquid crystal molecule with respect to the surface of the alignment film when the liquid crystal molecule is aligned in the pretilt direction is referred to as the “pretilt angle”. In this specification, performing processing on the alignment film to allow the alignment film to exert a capability of defining a prescribed pretilt direction is expressed as “giving a pretilt direction to the alignment film”. The pretilt direction defined by the alignment film is occasionally referred to simply as the “pretilt direction of the alignment film”.

By changing the combination of the pretilt directions given by a pair of alignment films facing each other with the liquid crystal layer interposed therebetween, a 4-domain alignment structure can be formed. A picture element divided into four has four liquid crystal domains.

Each liquid crystal domain is characterized by the tilt direction (also referred to as the “reference alignment direction”) of the liquid crystal molecules at a center and in the vicinity thereof in a layer plane and in a thickness direction of the liquid crystal layer when a voltage is applied to the liquid crystal layer. This tilt direction (reference alignment direction) has a dominant influence on the viewing angle dependence of each domain. This tilt direction is also an azimuthal angle direction. The reference based on which the azimuthal angle direction is measured is a horizontal direction of the display plane, and the counterclockwise direction is the forward direction (assuming that the display plane is the face of a clock, the o'clock direction is an azimuthal angle of 0° and the counterclockwise direction is the forward direction). Where the tilt directions of the four liquid crystal domains are set such that a difference between any two tilt directions among the four tilt directions is approximately equal to an integral multiple of 90° (e.g., 12 o'clock direction, 9 o'clock direction, 6 o'clock direction and 3 o'clock direction), the viewing angle characteristics are averaged and thus good display can be provided. From the viewpoint of uniformizing the viewing angle characteristics, it is preferable that the area sizes of the four liquid crystal domains in the picture element are approximately equal to each other. Specifically, it is preferable that a difference between the area size of the largest liquid crystal domain and the area size of the smallest liquid crystal domain among the four liquid crystal domains is 25% or less of the area size of the largest liquid crystal domain.

A vertical alignment type liquid crystal layer shown as an example in the following embodiments contains liquid crystal molecules having a negative dielectric anisotropy (a nematic liquid crystal material having a negative dielectric anisotropy). The pretilt direction defined by one of the alignment films and the pretilt direction defined by the other alignment film are different by about 90° from each other. A direction at the middle between these two pretilt directions is defined as the tilt direction (reference alignment direction). When a voltage is applied to the liquid crystal layer, the liquid crystal molecules are twist-aligned in accordance with the alignment regulation forces of the alignment films. When necessary, a chiral agent may be incorporated into the liquid crystal layer.

It is preferable that the pretilt angles respectively defined by the pair of alignment films are approximately equal to each other. When the pretilt angles are approximately equal to each other, there is an advantage that the display luminance characteristic can be improved. Especially where the difference between the pretilt angles is 1° or less, the tilt direction (reference alignment direction) of the liquid crystal molecules at the center and in the vicinity thereof of the liquid crystal layer can be controlled to be stable and thus the display luminance characteristic can be improved. A conceivable reason for this is that when the difference between the pretilt angles exceeds 1°, the tilt direction is dispersed in accordance with the position in the liquid crystal layer, and as a result, the transmittance is dispersed (i.e., an area having a transmittance lower than a desired transmittance is formed).

A pretilt direction is given to each alignment film by optical alignment processing. When an optical alignment film containing a photosensitive group is used, the variance in the pretilt angle can be controlled to be 1° or less. It is preferable that the optical alignment film contains, as the photosensitive group, at least one selected from the group consisting of 4-chalcone group, 4′-chalcone group, coumarin group and cinnamoyl group.

In the following embodiments, an active matrix driving type liquid crystal display device including thin film transistors (TFTs) will be shown as a typical example, but the present invention is applicable to any other system of liquid crystal display device, needless to say.

### Embodiment 1

Before Describing this Embodiment, a Method for dividing one picture element of a general 4D-RTN mode into domains having different alignment directions, and a problem occurring when the 4D-RTN mode is adopted to a multiple primary color liquid crystal display device, will be described.

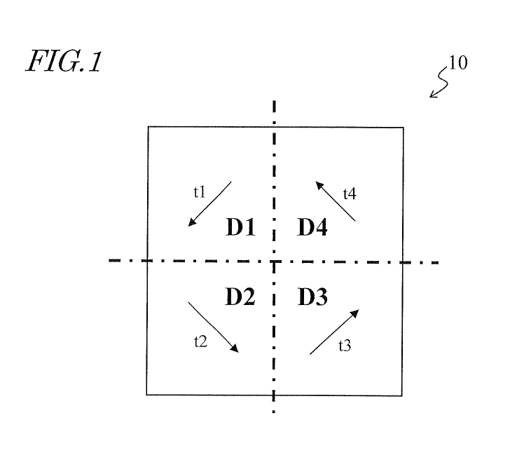

FIG. 1 shows a picture element 10 having a 4-domain alignment structure (4D structure). In FIG. 1, the picture element 10 is generally square in correspondence with a generally square picture element electrode for the sake of simplicity, but there is no limitation on the shape of the picture element. For example, the picture element 10 may be generally rectangular.

As shown in FIG. 1, the picture element 10 includes four liquid crystal domains D1, D2, D3 and D4. In FIG. 1, the liquid crystal domains D1, D2, D3 and D4 have an equal area size, and the example shown in FIG. 1 is the most preferable 4D structure from the viewpoint of viewing angle characteristics. The four liquid crystal domains D1, D2, D3 and D4 are arranged in a matrix of 2 rows×2 columns.

The tilt directions (reference alignment directions) of the liquid crystal domains D1, D2, D3 and D4 are respectively represented as t1, t2, t3 and t4. A difference between any two among these four directions is approximately equal to an integral multiple of 90°. Where the azimuthal angle of the horizontal direction of the display plane (3 o'clock direction) is 0°, the tilt direction t1 of the liquid crystal domain D1 is a direction of about 225°, the tilt direction t2 of the liquid crystal domain D2 is a direction of about 315°, the tilt direction t3 of the liquid crystal domain D3 is a direction of about 45°, and tilt direction t4 of the liquid crystal domain D4 is a direction of about 135°. Namely, the liquid crystal domains D1, D2, D3 and D4 are located such that the tilt directions thereof are different by about 90° between adjacent domains among the liquid crystal domains D1, D2, D3 and D4.

A pair of polarizing plates facing each other with a liquid crystal layer interposed therebetween are located such that transmission axes (polarization axes) thereof are generally perpendicular to each other. More specifically, the transmission axis of one of the polarizing plates is generally parallel to the horizontal direction of the display plane, and the transmission axis of the other polarizing plate is generally parallel to a vertical direction of the display plane. Accordingly, the tilt directions t1, t2, t3 and t4 have an angle of about 45° with respect to the transmission axes of the pair of polarizing plates. Hereinafter, unless otherwise specified, the transmission axes of the polarizing plates are located as described above.

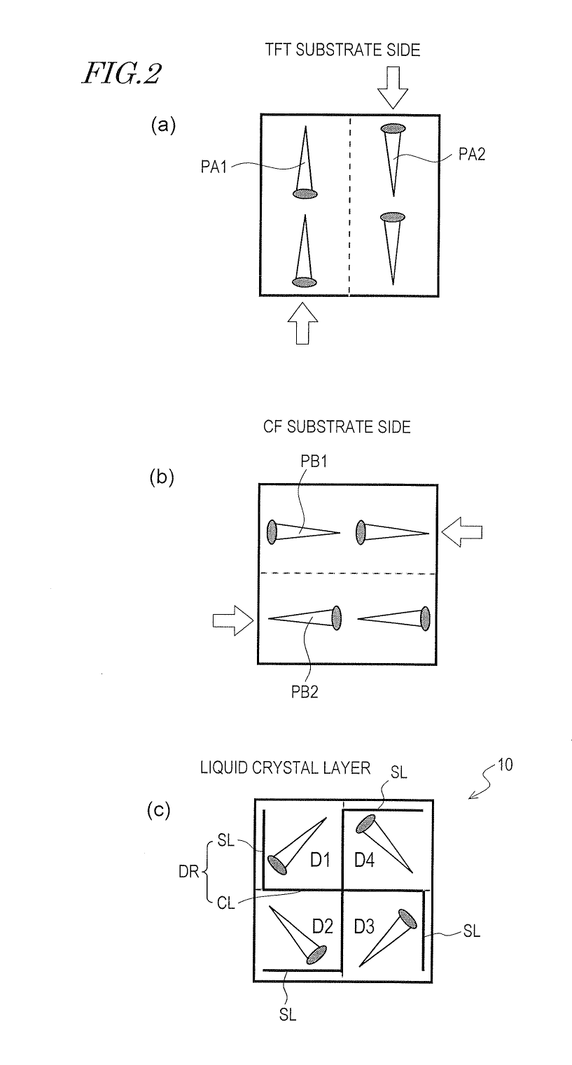

The 4D structure of the picture element 10 shown in FIG. 1 is obtained as shown in FIG. 2. FIGS. 2(a), (b) and (c) illustrate a method for dividing the picture element 10 shown in FIG. 1 into domains having different alignment directions. FIG. 2(a) shows pretilt directions PA1 and PA2 of an alignment film provided on a TFT substrate (lower substrate), and FIG. 2(b) shows pretilt directions PB1 and PB2 of an alignment film provided on a color filter (CF) substrate (upper substrate). FIG. 2(c) shows the tilt directions when a voltage is applied to the liquid crystal layer. In these figures, the alignment directions of the liquid crystal molecules as seen from the observer are schematically shown. Each liquid crystal molecule shown as having a conical shape is tilted such that the bottom end of the cone is closer to the observer than the tip of the cone.

As shown in FIG. 2(a), an area on the TFT substrate side (area corresponding to one picture element 10) is divided into two, namely, a left area and a right area, and the vertical alignment film is align-processed such that the pretilt directions PA1 and PA2 antiparallel to each other are given to the respective areas (left area and right area) of the vertical alignment film. Specifically, optical alignment processing is performed by ultraviolet rays directed obliquely in the directions represented by the arrows. When the light is to be directed to the left area, the right area is shielded by a light shielding part of a photomask. When the light is to be directed to the right area, the left area is shielded in a similar manner.

As shown in FIG. 2(b), an area on the CF substrate side (area corresponding to one pixel area 10) is divided into two, namely, a top area and a bottom area, and the vertical alignment film is alignment-processed such that the pretilt directions PB1 and PB2 antiparallel to each other are given to the respective areas (top area and bottom area) of the vertical alignment film. Specifically, optical alignment processing is performed by ultraviolet rays directed obliquely in the directions represented by the arrows. When the light is to be directed to the top area, the bottom area is shielded by a light shielding part of a photomask. When the light is to be directed to the bottom area, the top area is shielded in a similar manner.

By bringing together the TFT substrate and the CF substrate alignment-processed as shown in FIGS. 2(a) and (b), the picture element 10 divided to have domains as shown in FIG. 2(c) can be formed. As can be seen from FIGS. 2(a), (b) and (c), in each of the liquid crystal domains D1 through D4, the pretilt direction of the alignment film on the TFT substrate and the pretilt direction of the alignment film on the CF substrate are different by 90° from each other, and a direction at the middle of these two pretilt directions is defined as the tilt direction (reference alignment direction). Among the liquid crystal domains D1 through D4, the combination of the pretilt directions provided by the top and bottom alignment films is different. Owing to this, four tilt directions are realized in one picture element 10.

In the picture element 10 of the 4D-RTN mode, when a gray scale is displayed, as shown in FIG. 2(c), a dark area DR, which is darker than the gray scale to be displayed, appears. The dark area DR includes a cross-shaped dark line (cross-shaped part) CL located at borders between each two adjacent liquid crystal domains among the liquid crystal domains D1, D2, D3 and D4 and straight dark lines (straight parts) SL located in the vicinity of edges of the picture element electrode and extending generally parallel to the edges. The dark area DR is generally gammadion-shaped as a whole.

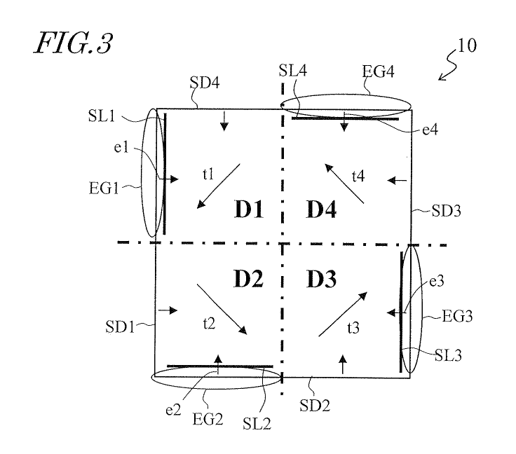

The cross-shaped dark line CL is formed when the liquid crystal molecules are aligned to be parallel or perpendicular to the transmission axes of the polarizing plates at the borders between adjacent liquid crystal domains and thus the alignment of the liquid crystal molecules is continuous between adjacent liquid crystal domains. Each of straight dark lines SL, which is formed in the vicinity of an edge of the picture element electrode which is close to the corresponding liquid crystal domain, is formed when the respective edge includes an edge portion such that an azimuthal angle direction perpendicular to the edge portion and directed to the inside of the picture element electrode has an angle exceeding 90° with respect to the tilt direction (reference alignment direction) of the corresponding liquid crystal domain. This is conceived to occur because the tilt direction of the liquid crystal domain and the direction of the alignment regulation force caused by the oblique electric field generated at the edge of the picture element electrode have components facing each other and therefore the liquid crystal molecules are aligned to be parallel or perpendicular to the transmission axes of the polarizing plates in this area. Hereinafter, a reason why the dark lines SL appear in the vicinity of the edges will be specifically described regarding the picture element 10 of the 4D structure shown in FIG. 1 with reference to FIG. 3. In FIG. 3, the cross-shaped dark line CL is omitted.

As shown in FIG. 3, the picture element electrode has four edges (sides) SD1, SD2, SD3 and SD4. Each of the oblique electric fields generated when a voltage is applied exhibits an alignment regulation force having a component of a direction (azimuthal angle direction) perpendicular to the respective side and directed to the inside of the picture element electrode. In FIG. 3, the azimuthal angle directions respectively perpendicular to the four edges SD1, SD2, SD3 and SD4 and directed to the inside of the picture element electrode are represented by arrows e1, e2, e3 and e4.

Each of the four liquid crystal domains D1, D2, D3 and D4 is close to two among the four edges SD1, SD2, SD3 and SD4 of the picture element electrode, and in the presence of a voltage, receives alignment regulation forces caused by the oblique electric fields generated along the respective edges.

Regarding an edge portion EG1 at the edges of the picture element electrode close to the liquid crystal domain D1, the azimuthal angle direction e1 perpendicular to the edge portion EG1 and directed to the inside of the picture element electrode makes an angle exceeding 90° with respect to the tilt direction t1 of the liquid crystal domain A. As a result, in the liquid crystal domain D1, a dark line SL1 appears generally parallel to the edge portion EG1 when a voltage is applied.

Similarly, regarding an edge portion EG2 at the edges of the picture element electrode close to the liquid crystal domain D2, the azimuthal angle direction e2 perpendicular to the edge portion EG2 and directed to the inside of the picture element electrode makes an angle exceeding 90° with respect to the tilt direction t2 of the liquid crystal domain D2. As a result, in the liquid crystal domain D2, a dark line SL2 appears generally parallel to the edge portion EG2 when a voltage is applied.

Similarly, regarding an edge portion EG3 at the edges of the picture element electrode close to the liquid crystal domain D3, the azimuthal angle direction e3 perpendicular to the edge portion EG3 and directed to the inside of the picture element electrode makes an angle exceeding 90° with respect to the tilt direction t3 of the liquid crystal domain D3. As a result, in the liquid crystal domain D3, a dark line SL3 appears generally parallel to the edge portion EG3 when a voltage is applied.

Similarly, regarding an edge portion EG4 at the edges of the picture element electrode close to the liquid crystal domain D4, the azimuthal angle direction e4 perpendicular to the edge portion EG4 and directed to the inside of the picture element electrode makes an angle exceeding 90° with respect to the tilt direction t4 of the liquid crystal domain D4. As a result, in the liquid crystal domain D4, a dark line SL4 appears generally parallel to the edge portion EG4 when a voltage is applied.

The angles made between the tilt directions t1, t2, t3 and t4 of the liquid crystal domains D1, D2, D3 and D4 and the azimuthal angle components e1, e2, e3 and e4 of the alignment regulation forces caused by the oblique electric fields generated in the edge portions EG1, EG2, EG3 and EG4 close to the liquid crystal domains D1, D2, D3 and D4, respectively, are all about 135°.

As described above, in the liquid crystal domain D1, the dark line SL1 appears generally parallel to the edge portion EG1. In the liquid crystal domain D2, the dark line SL2 appears generally parallel to the edge portion EG2. In the liquid crystal domain D3, the dark line SL3 appears generally parallel to the edge portion EG3. In the liquid crystal domain D4, the dark line SL4 appears generally parallel to the edge portion EG4. The dark line SL1 and the dark line SL3 are generally parallel to the vertical direction of the display plane, and the dark line SL2 and the dark line SL4 are generally parallel to the horizontal direction of the display plane. Namely, the edge portion EG1 and the edge portion EG3 are generally parallel to the vertical direction, and the edge portion EG2 and the edge portion EG4 are generally parallel to the horizontal direction.

The method for dividing one picture element into four liquid crystal domains D1 through D4 (i.e., the method for determining the positions of the liquid crystal domains D1 through D4 in the picture element) is not limited to the example shown in FIGS. 1 through 3.

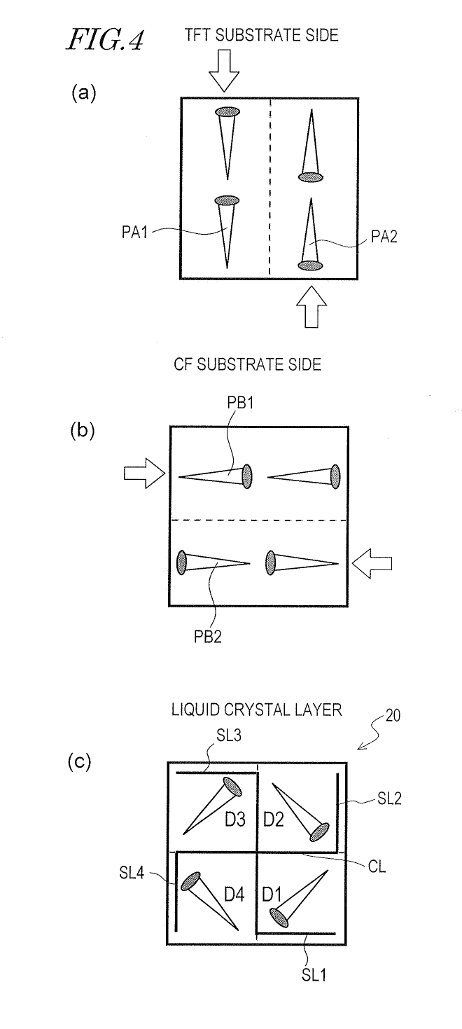

For example, by bringing together the TFT substrate and the CF substrate alignment-processed as shown in FIGS. 4(a) and (b), a picture element 20 divided to have domains having different alignment directions as shown in FIG. 4(c) can be formed. Like the picture element 10, the picture element 20 includes four liquid crystal domains D1 through D4. The tilt directions of the liquid crystal domains D1 through D4 are the same as those of the liquid crystal domains D1 through D4 in the picture element 10.

It should be noted that in the picture element 10, the liquid crystal domains D1 through D4 are located in the order of top left, bottom left, bottom right and top right (i.e., counterclockwise from top left); whereas in the picture element 20, the liquid crystal domains D1 through D4 are located in the order of bottom right, top right, top left and bottom left (i.e., counterclockwise from bottom right). A reason for this is that the pretilt directions of the left area and the right area on the TFT substrate side are opposite, and the pretilt directions of the top area and the bottom area on the CF substrate side are opposite, between the picture element 10 and the picture element 20. The dark lines SL1 and SL3 appearing in the liquid crystal domains D1 and D3 are generally parallel to the horizontal direction of the display plane, and the dark lines SL2 and SL4 appearing in the liquid crystal domains D2 and D4 are generally parallel to the vertical direction of the display plane. Namely, the edge portions EG1 and EG3 are generally parallel to the horizontal direction of the display plane, and the edge portions EG2 and EG4 are generally parallel to the vertical direction of the display plane.

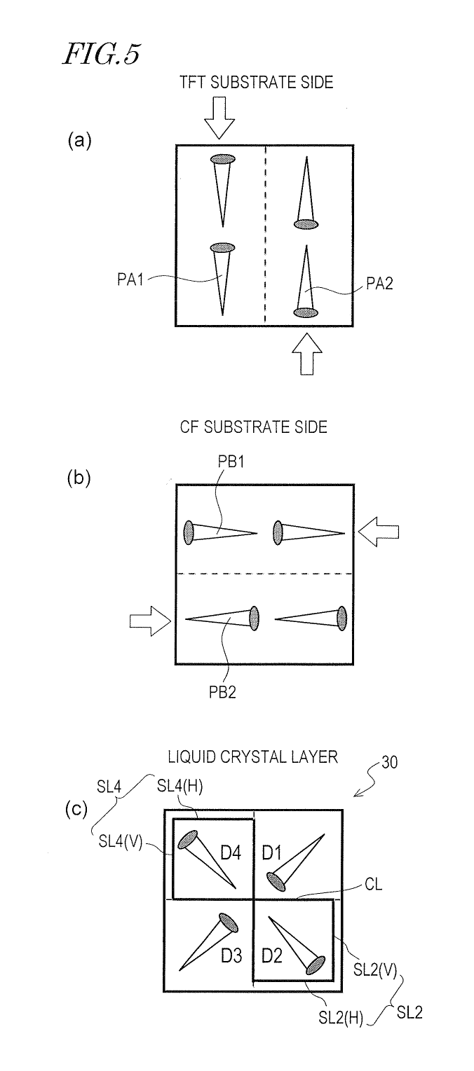

Alternatively, by bringing together the TFT substrate and the CF substrate alignment-processed as shown in FIGS. 5(a) and (b), a picture element 30 divided to have domains having different alignment directions as shown in FIG. 5(c) can be formed. Like the picture element 10, the picture element 30 includes four liquid crystal domains D1 through D4. The tilt directions of the liquid crystal domains D1 through D4 are the same as those of the liquid crystal domains D1 through D4 in the picture element 10.

It should be noted that in the picture element 30, the liquid crystal domains D1 through D4 are located in the order of top right, bottom right, bottom left and top left (i.e., clockwise from top right). A reason for this is that the pretilt directions of the left area and the right area on the TFT substrate side are opposite between the picture element 10 and the picture element 30.

In the picture element 30, no dark line appears in the liquid crystal domains D1 and D3. A reason for this is that the edges of the picture element electrode close to the liquid crystal domains D1 and D3 does not have an edge portion such that the azimuthal angle direction perpendicular to the edge portion and directed to the inside of the picture element electrode has an angle exceeding 90° with respect to the corresponding tilt direction. By contrast, the dark lines SL2 and SL4 appear in the liquid crystal domains D2 and D4. A reason for this is that the edges of the picture element electrode close to the liquid crystal domains D2 and D4 has an edge portion such that the azimuthal angle direction perpendicular to the edge portion and directed to the inside of the picture element electrode has an angle exceeding 90° with respect to the corresponding tilt direction. The dark lines SL2 and SL4 respectively include portions SL2(H) and SL4(H) parallel to the horizontal direction and portions SL2(V) and SL4(V) parallel to the vertical direction. A reason for this is that the tilt direction of each of the liquid crystal domains D2 and D4 has an angle exceeding 90° with respect to both of an azimuthal angle direction perpendicular to the horizontal edge and directed to the inside of the picture element electrode and an azimuthal angle direction perpendicular to the vertical edge and directed to the inside of the picture element electrode.

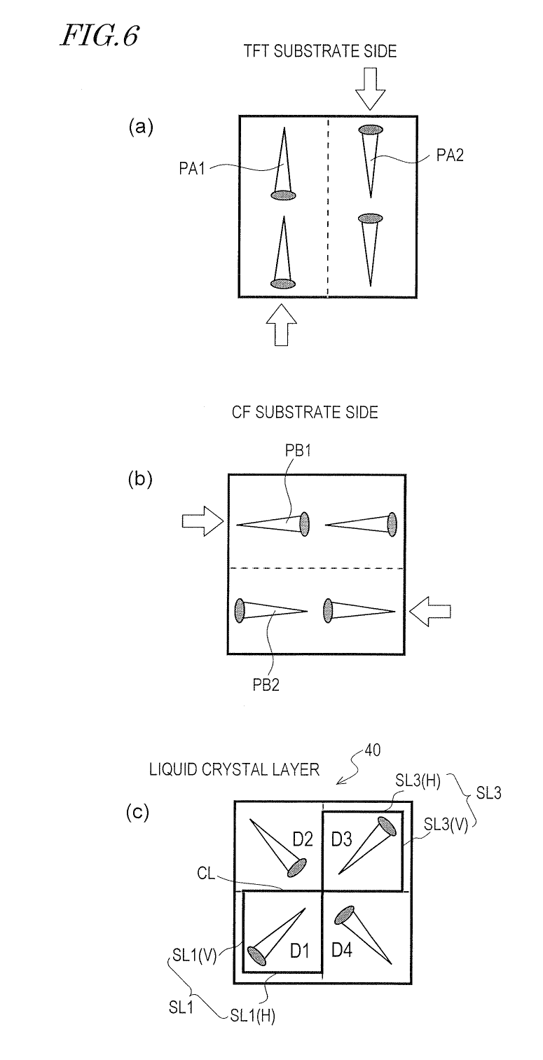

By bringing together the TFT substrate and the CF substrate alignment-processed as shown in FIGS. 6(a) and (b), a picture element 40 divided to have domains having different alignment directions as shown in FIG. 6(c) can be formed. Like the picture element 10, the picture element 40 includes four liquid crystal domains D1 through D4. The tilt directions of the liquid crystal domains D1 through D4 are the same as those of the liquid crystal domains D1 through D4 in the picture element 10.

It should be noted that in the picture element 40, the liquid crystal domains D1 through D4 are located in the order of bottom left, top left, top right and top bottom (i.e., clockwise from bottom left). A reason for this is that the pretilt directions of the top area and the bottom area on the CF substrate side are opposite between the picture element 10 and the picture element 40.

In the picture element 40, no dark line appears in the liquid crystal domains D2 and D4. A reason for this is that the edges of the picture element electrode close to the liquid crystal domains D2 and D4 does not have an edge portion such that the azimuthal angle direction perpendicular to the edge portion and directed to the inside of the picture element electrode has an angle exceeding 90° with respect to the corresponding tilt direction. By contrast, the dark lines SL1 and SL3 appear in the liquid crystal domains D1 and D3. A reason for this is that the edges of the picture element electrode close to the liquid crystal domains D1 and D3 has an edge portion such that the azimuthal angle direction perpendicular to the edge portion and directed to the inside of the picture element electrode has an angle exceeding 90° with respect to the corresponding tilt direction. The dark lines SL1 and SL3 respectively include portions SL1(H) and SL3(H) parallel to the horizontal direction and portions SL1(V) and SL3(V) parallel to the vertical direction. A reason for this is that the tilt direction of each of the liquid crystal domains D1 and D3 has an angle exceeding 90° with respect to both of an azimuthal angle direction perpendicular to the horizontal edge and directed to the inside of the picture element electrode and an azimuthal angle direction perpendicular to the vertical edge and directed to the inside of the picture element electrode.

As described above, the liquid crystal domains D1 through D4 may be arranged in any of various manners in a picture element. As shown in FIGS. 2 through 6, when the arrangement of the liquid crystal domains D1 through D4 is different, the pattern of the dark lines SL in the vicinity of the edges is different. Therefore, the entire shape of the dark area DR is different. In the picture elements 10 and 20 shown in FIGS. 2 and 4, the dark line DR is generally gammadion-shaped; whereas in the picture elements 30 and 40 shown in FIGS. 5 and 6, the dark area DR is generally shaped like the letter “8” (the letter inclined from the vertical direction). In this specification, the expression “gammadion-shaped” encompasses both of “right gammadion-shaped” (see FIG. 2) and “left gammadion-shaped” (see FIG. 4).

As described above, the shape of the dark area DR varies in accordance with the arrangement of the liquid crystal domains D1 through D4. Thus, the shape of the dark area DR is considered to characterize the arrangement of the liquid crystal domains D1 through D4. Therefore, in the figures referred to below, a dark area DR may be occasionally shown instead of (or in addition to) the liquid crystal domains D1 through D4.

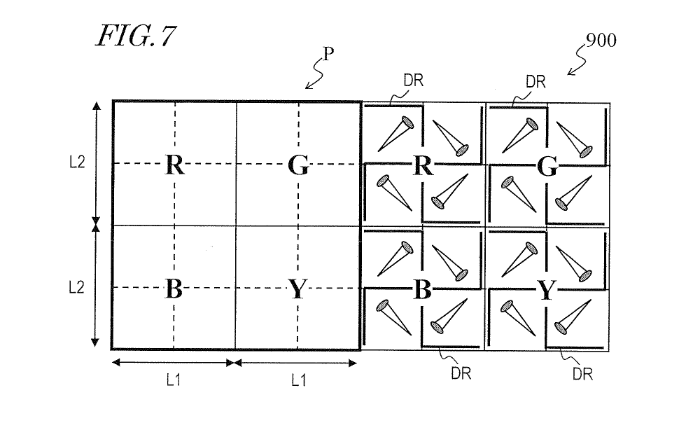

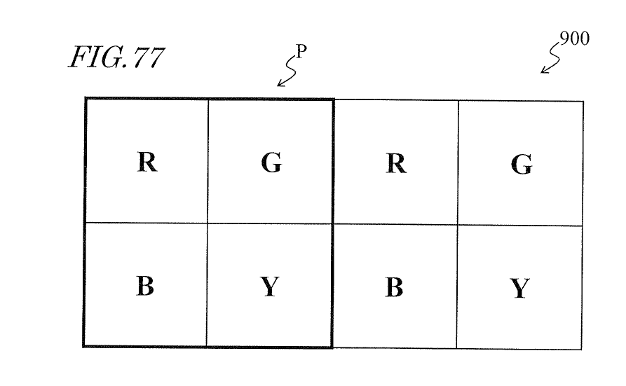

Now, optical alignment processing performed in the case where the 4D-RTN mode is adopted to a multiple primary color liquid crystal display device 900 shown in FIG. 77 will be specifically described. In this example, as shown in FIG. 7, the liquid crystal domains are located such that a generally gammadion-shaped dark area DR appears in each of a red picture element R, a green picture element G, a blue picture element B and a yellow picture element Y (same as the arrangement in the picture element 20 shown in FIG. 4).

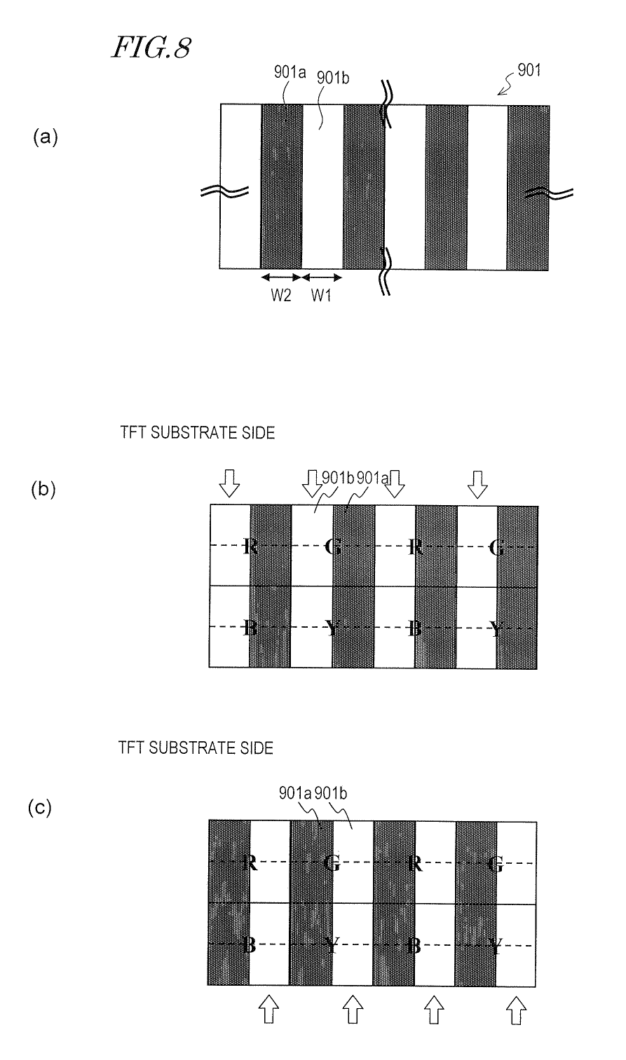

On the alignment film on the TFT substrate side, the optical alignment processing is performed as shown in FIG. 8. First, a photomask 901 as shown in FIG. 8(a) is prepared. The photomask 901 includes a plurality of light shielding parts 901a extending like stripes in a column direction (vertical direction) and a plurality of light transmitting parts 901b located between the plurality of light shielding parts 901a. A width W1 of each of the plurality of light transmitting parts 901b (width in the row direction) is half of a length L1 of sides of each picture element parallel to the row direction (see FIG. 7) (i.e., W1=L1/2). A width W2 of each of the plurality of light shielding parts 901a (width in the row direction) is also half of the length L1 of the sides of each picture element parallel to the row direction (i.e., W2=L1/2; W1+W2=L1).

As shown in FIG. 8(b), the photomask 901 is located such that each light shielding part 901a overlaps a right half of each picture element and each light transmitting part 901b overlaps a left half of each picture element. In this state, ultraviolet rays are directed obliquely in the direction represented by the arrows. As a result of this exposure step, a part of the alignment film on the TFT substrate side corresponding to the left half of each picture element is given a prescribed pretilt direction (pretilt direction PA1 shown in FIG. 4(a)).

Next, the photomask 901 is shifted in the row direction by half of the width L1 of the picture element such that as shown in FIG. 8(c), each light shielding part 901a overlaps the left half of each picture element and each light transmitting part 901b overlaps the right half of each picture element. In this state, ultraviolet rays are directed obliquely in the direction represented by the arrows. As a result of this exposure step, a part of the alignment film on the TFT substrate side corresponding to the right half of each picture element is given a prescribed pretilt direction (pretilt direction PA2 shown in FIG. 4(a)).

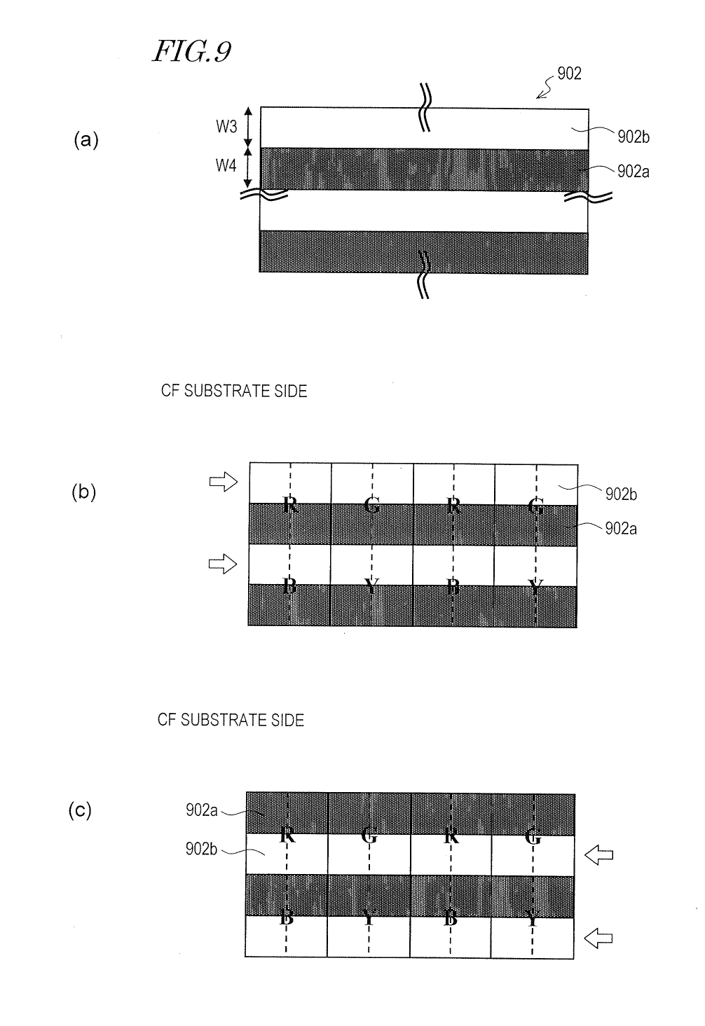

On the alignment film on the CF substrate side, the optical alignment processing is performed as shown in FIG. 9. First, a photomask 902 as shown in FIG. 9(a) is prepared. The photomask 902 includes a plurality of light shielding parts 902a extending like stripes in the row direction (horizontal direction) and a plurality of light transmitting parts 902b located between the plurality of light shielding parts 902a. A width W3 of each of the plurality of light transmitting parts 902b (width in the column direction) is half of a length L2 of sides of each picture element parallel to the column direction (see FIG. 7) (i.e., W3=L2/2). A width W4 of each of the plurality of light shielding parts 902a (width in the column direction) is also half of the length L2 of the sides of each picture element parallel to the column direction (i.e., W4=L2/2; W3+W4=L2).

As shown in FIG. 9(b), the photomask 902 is located such that each light shielding part 902a overlaps a bottom half of each picture element and each light transmitting part 902b overlaps a top half of each picture element. In this state, ultraviolet rays are directed obliquely in the direction represented by the arrows. As a result of this exposure step, a part of the alignment film on the CF substrate side corresponding to the top half of each picture element is given a prescribed pretilt direction (pretilt direction PB1 shown in FIG. 4(b)).

Next, the photomask 902 is shifted in the column direction by half of the width L2 of the picture element such that as shown in FIG. 9(c), each light shielding part 902a overlaps the top half of each picture element and each light transmitting part 902b overlaps the bottom half of each picture element. In this state, ultraviolet rays are directed obliquely in the direction represented by the arrows. As a result of this exposure step, a part of the alignment film on the CF substrate side corresponding to the bottom half of each picture element is given a prescribed pretilt direction (pretilt direction PB2 shown in FIG. 4(b)).

As described above, for the optical alignment processing performed on the alignment film on the TFT substrate side, the photomask 901 used in the first exposure step is shifted before the second exposure step and used as it is for the second exposure step. Also for the optical alignment processing performed on the alignment film on the CF substrate side, the photomask 902 used in the first exposure step is shifted before the second exposure step and used as it is for the second exposure step. In this specification, such a technique of exposure is referred to as the “shifted exposure”.

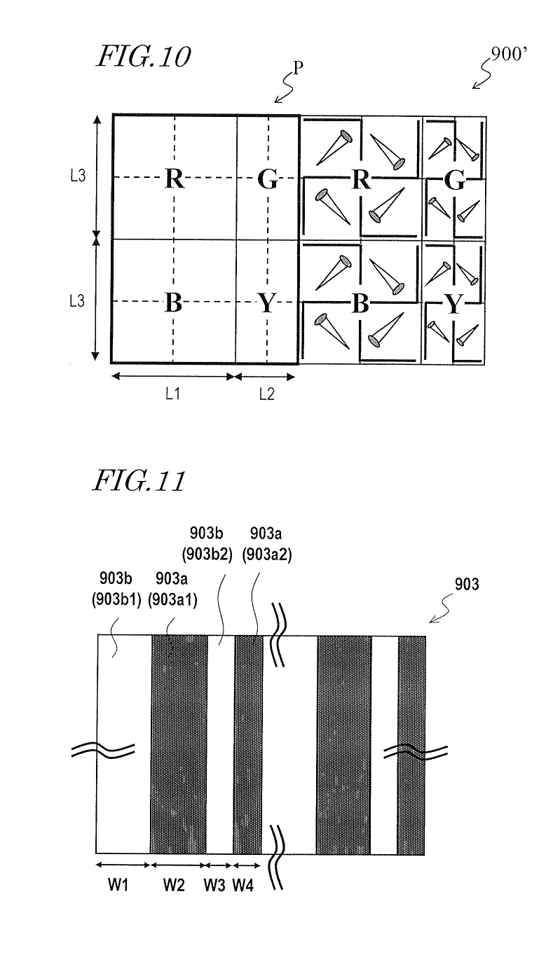

However, when one pixel includes a picture element having a different size from that of another picture element, the shifted exposure cannot be performed on the alignment film on the TFT substrate side and/or the alignment film on the CF substrate side. For example, in a multiple primary color liquid crystal display device 900′ shown in FIG. 10, sides of all the picture elements parallel to the column direction have an equal length L3, whereas a length L1 of sides of a red picture element R and a blue picture element B parallel to the row direction is different from a length L2 of sides of a green picture element G and a yellow picture element Y parallel to the row direction. Specifically, the length L2 of the sides of the green picture element G and the yellow picture element Y parallel to the row direction is half of the length L1 of the sides of the red picture element R and the blue picture element B parallel to the row direction (i.e., L2=L1/2). In this manner, in the liquid crystal display device 900′, in one pixel P, the size of the red picture element R and the blue picture element B is different from the size of the green picture element G and the yellow picture element Y.

A liquid crystal display device in which the size of the red picture element R is larger than the yellow picture element Y like the liquid crystal display device 900′ shown in FIG. 10 is disclosed in WO2007/148519. When the size of the red picture element R is larger than the yellow picture element Y, brighter red (red having a higher lightness) can be displayed than in the case where all the picture elements have the same size.

When the optical alignment processing is to be performed on this liquid crystal display device 900′ to realize the liquid crystal arrangement as shown in the right half of FIG. 10 (same as the arrangement shown in the right half of FIG. 7), the shifted exposure cannot be made on the alignment film on the TFT substrate side as described below.

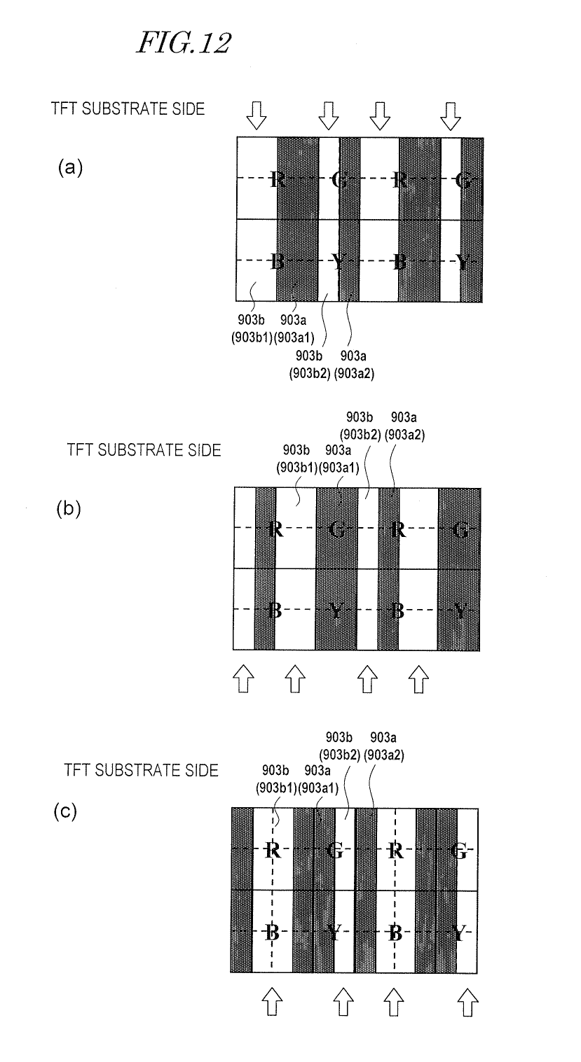

For performing the optical alignment processing on the alignment film on the TFT substrate side of the liquid crystal display device 900′, first, a photomask 903 as shown in FIG. 11 is prepared. The photomask 903 includes a plurality of light shielding parts 903a extending like stripes in the column direction (vertical direction) and a plurality of light transmitting parts 903b located between the plurality of light shielding parts 903a. It should be noted that the plurality of light shielding parts 903a include two types of light shielding parts 903a1 and 903a2 having different widths from each other. The plurality of light transmitting parts 903b include two types of light transmitting parts 903b1 and 903b2 having different widths from each other.

A width W1 of the light transmitting part 903b1, among the two types of light transmitting parts 903b1 and 903b2, is half of the length L1 of the sides of the red picture element R and the blue picture element B parallel to the row direction (see FIG. 10) (i.e., W1=L1/2). By contrast, a width W3 of the other light transmitting part 903b2 is half of the length L2 of the sides of the green picture element G and the yellow picture element Y parallel to the row direction (see FIG. 10) (i.e., W3=L2/2).

A width W2 of the light shielding part 903a1, among the two types of light shielding parts 903a1 and 903a2, is half of the length L1 of the sides of the red picture element R and the blue picture element B parallel to the row direction (i.e., W2=L1/2; W1+W2=L1). By contrast, a width W4 of the other light shielding part 903a2 is half of the length L2 of the sides of the green picture element G and the yellow picture element Y parallel to the row direction (i.e., W4=L2/2; W3+W4=L2).

The wider light transmitting part 903b1, the wider light shielding part 903a1, the narrower light transmitting part 903b2 and the narrower light shielding part 903a2 described above are arranged cyclically in this order. The photomask 903 is located such that as shown in FIG. 12(a), the wider light shielding part 903a1 overlaps a right half of the red picture element R and the blue picture element B and the narrower light shielding part 903a2 overlaps a right half of the green picture element G and the yellow picture element Y (namely, such that the wider light transmitting part 903b1 overlaps a left half of the red picture element R and the blue picture element B and the narrower light transmitting part 903b2 overlaps a left half of the green picture elements G and the yellow picture elements Y). In this state, ultraviolet rays are directed obliquely in the direction represented by the arrows. As a result of this exposure step, parts of the alignment film on the TFT substrate side corresponding to the left half of the picture elements are given a prescribed pretilt direction (pretilt direction PA1 shown in FIG. 4(a)).

The shifted exposure, which would be performed to give a prescribed pretilt direction to the remaining parts (right half) of the alignment film, cannot be performed with the photomask 903 shown in FIG. 11.

For example, it is assumed that from the state shown in FIG. 12(a), the photomask 903 is shifted in the row direction rightward by half of the width L1 of the red picture element R and the blue picture element B. In this case, as shown in FIG. 12(b), the wider light shielding part 903a1 overlaps the entirety of the green picture element G and the yellow picture element Y, and the narrower light shielding part 903a2 overlaps a right half of the left half of the red picture element R and the blue picture element B. Namely, the wider light transmitting part 903b1 overlaps the right half of the red picture element R and the blue picture element B, and the narrower light transmitting part 903b2 overlaps a left half of the left half of the red picture element R and the blue picture element B. When the ultraviolet rays are directed in the direction represented by the arrows in this state, the part corresponding to the right half of the red picture element R and the blue picture element B is given a prescribed pretilt direction (pretilt direction PA2 shown in FIG. 4(a)) but the part corresponding to the right half of the green picture element G and the yellow picture element Y is not given a prescribed pretilt direction. The reason is that the right half of the green picture element G and the yellow picture element Y is shielded by the light shielding part 903a1. The left half of the left half of the red picture element R and the blue picture element B is not shielded and thus irradiated with the ultraviolet rays, namely, is exposed double. The double-exposed areas cannot define a desired pretilt direction (pretilt direction given by the first exposure).

It is assumed that from the state shown in FIG. 12(a), the photomask 903 is shifted in the row direction rightward by ¼ of the width L1 of the red picture element R and the blue picture element B (i.e., ½ of the length L2 of the green picture element G and the yellow picture element Y). In this case, as shown in FIG. 12(c), the wider light shielding part 903a1 overlaps the left half of the green picture element G and the yellow picture element Y and also a right half of the right half of the red picture element R and the blue picture element B, and the narrower light shielding part 903a2 overlaps the left half of the left half of the red picture element R and the blue picture element B. Namely, the wider light transmitting parts 903b1 overlap a central part (left half of the right half and right half of the left half) of the red picture element R and the blue picture element B, and the narrower light transmitting part 903b2 overlaps the right half of the green picture element G and the yellow picture element Y. When the ultraviolet rays are directed in the direction represented by the arrows in this state, the part corresponding to the right half of the green picture element G and the yellow picture element Y is given a prescribed pretilt direction (pretilt direction PA2 shown in FIG. 4(a)) but the part corresponding to the right half of the right half of the red picture element R and the blue picture element B is not given a prescribed pretilt direction. The reason is that the right half of the right half of the red picture element R and the blue picture element B is shielded by the light shielding part 903a1. The right half of the left half of the red picture element R and the blue picture element B is not shielded and thus irradiated with the ultraviolet rays, namely, is exposed double.

As described above, when one pixel includes a picture element having a different size from that of another picture element, the shifted exposure cannot be performed. Specifically, the shifted exposure cannot be performed in the direction in which there are two types of width of the picture elements (row direction in the above example). By contrast, according to the present invention, even when one pixel includes a picture element having a different size from that of another picture element, the shifted exposure can be performed. Hereinafter, a liquid crystal display device and a method for producing the same according to the present invention will be specifically described.

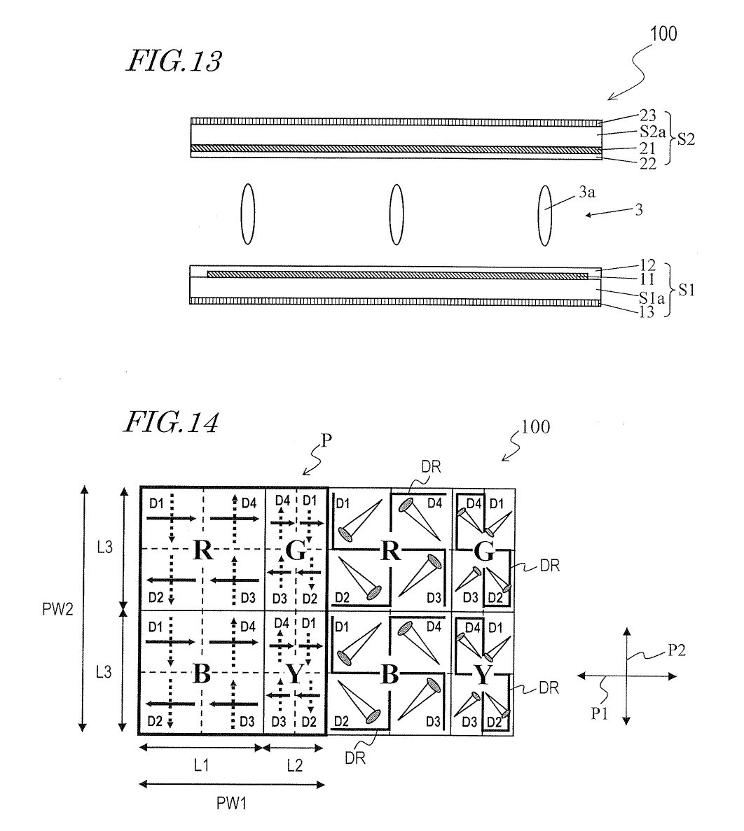

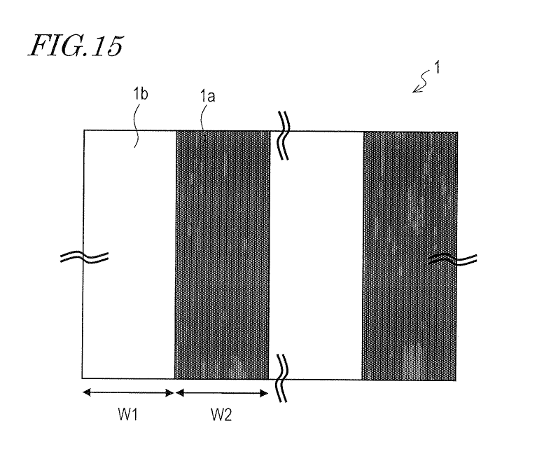

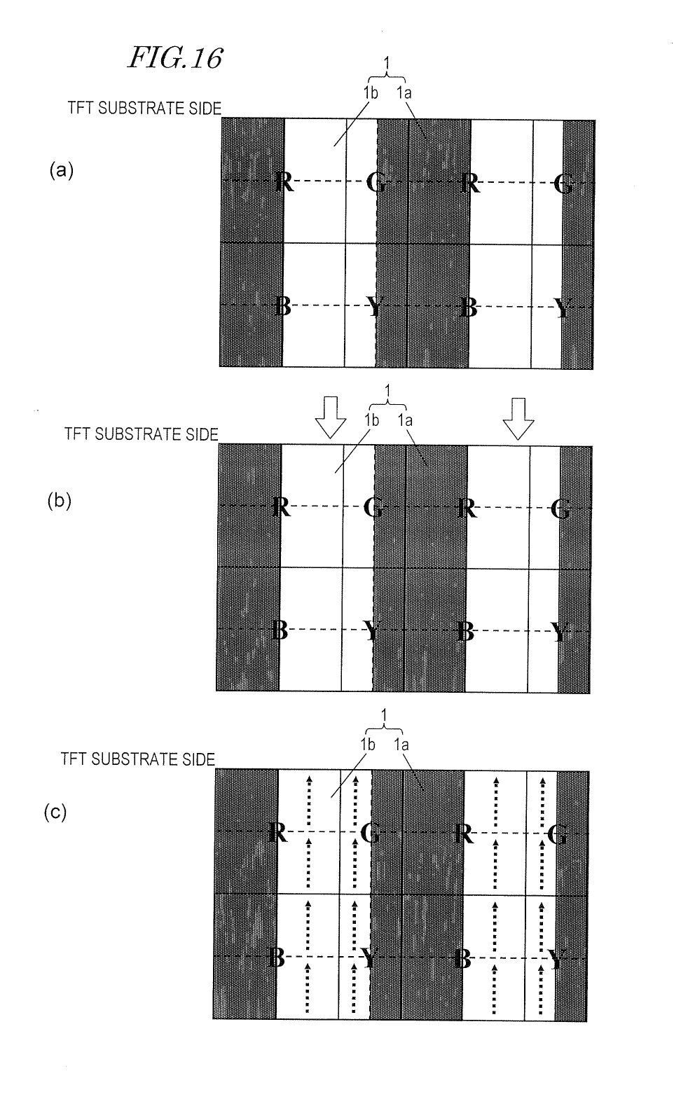

FIG. 13 and FIG. 14 show a liquid crystal display device 100 in this embodiment. FIG. 13 is a cross-sectional view schematically showing one picture element of the liquid crystal display device 100, and FIG. 14 is a plan view schematically showing two pixels P of the liquid crystal display device 100. As described later, the liquid crystal display device 100 is a multiple primary color liquid crystal display device which provides display using four primary colors. The liquid crystal display device 100 provides display in the 4D-RTN mode.

As shown in FIG. 13, the liquid crystal display device 100 includes a vertical alignment type liquid crystal layer 3, a TFT substrate (also referred to as the “active matrix substrate” occasionally) S1 and a CF substrate (also referred to as the “counter substrate” occasionally) S2 which face each other with the liquid crystal layer 3 interposed therebetween, a picture element electrode 11 provided on the liquid crystal layer 3 side of the TFT substrate S1 and a counter electrode 21 provided on the liquid crystal layer 3 side of the CF substrate S2.

The liquid crystal layer 3 contains liquid crystal molecules 3a having a negative dielectric anisotropy (i.e., Δ∈<0). When no voltage is applied to the liquid crystal layer 3 (i.e., when no voltage is applied between the picture element electrode 11 and the counter electrode 21), as shown in FIG. 13, the liquid crystal molecules 3a are aligned generally vertically with respect to surfaces of the substrates. The picture element electrode 11 is provided on an insulating transparent plate (e.g., glass plate or plastic plate) S1a, and the counter electrode 21 is provided on an insulating transparent plate (e.g., glass plate or plastic plate) S2a.

The liquid crystal display device 100 further includes a pair of optical alignment films 12 and 22 and a pair of polarizing plates 13 and 23. Among the pair of optical alignment films 12 and 22, one optical alignment film 12 is provided between the picture element electrode 11 and the liquid crystal layer 3, and the other optical alignment film 22 is provided between the counter electrode 21 and the liquid crystal layer 3. The pair of polarizing plates 13 and 23 face each other with the liquid crystal layer 3 interposed therebetween, and are located, as shown in FIG. 14, such that respective transmission axes (polarization axes) P1 and P2 are generally perpendicular to each other.

Although not shown, the TFT substrate S1 further includes thin film transistors (TFTs), scanning lines for supplying a scanning signal to the TFTs, signal lines for supplying a video signal to the TFTs and the like. The CF substrate S2 further includes color filters and a black matrix (light shielding layer).

As shown in FIG. 14, the liquid crystal display device 100 includes a plurality of pixels P. FIG. 14 shows two pixels P arranged in 1 row×2 columns, but the plurality of pixels P of the liquid crystal display device 100 are arranged in a matrix of a plurality of rows and a plurality of columns.

Each of the plurality of pixels P is defined by a plurality of picture elements. Each of the plurality of picture elements has a shape including a side parallel to a prescribed first direction and a side parallel to a second direction crossing the first direction. More specifically, each picture element has a shape of a rectangle (encompassing a square) including sides parallel to the row direction and sides parallel to the column direction (perpendicular to the row direction).

The plurality of picture elements which define one pixel P are an even number of picture elements including at least four picture elements for displaying different colors from each other. In this embodiment, the plurality of picture elements which define one pixel P are a red picture element R, a green picture element G, a blue picture element B and a yellow picture element Y. The red picture element R, the green picture element G, the blue picture element B and the yellow picture element Y are arranged in a matrix of 2 rows×2 columns in the pixel P.

The red picture element R, the green picture element G, the blue picture element B and the yellow picture element Y are each divided into four areas having different alignment directions. Specifically, each picture element includes four liquid crystal domain D1 through D4 respectively having tilt directions of about 225°, about 315°, about 45° and about 135° when a voltage is applied between the picture element electrode 11 and the counter electrode 21. As described above, the transmission axis P1 of one of the pair of polarizing plates 13 and 23 is generally parallel to the horizontal direction of the display plane, and the transmission axis P2 of the other polarizing plate is generally parallel to the vertical direction of the display plane. Accordingly, the tilt directions of the liquid crystal domains D1 through D4 each have an angle of about 45° with respect to the transmission axes P1 and P2 of the polarizing plates 13 and 23.

In the right pixel P of FIG. 14, the tilt direction (reference alignment direction) and a pattern of the dark area DR are shown for each of the liquid crystal domains D1 through D4. In the left pixel P of FIG. 14, for each of the liquid crystal domains D1 through D4, the pretilt direction of the optical alignment film 12 of the TFT substrate S1 is represented by the dashed arrows, and the pretilt direction of the optical alignment film 22 of the CF substrate S2 is represented by the solid arrows. These arrows representing the pretilt directions show that the liquid crystal molecules 3a are pretilted such that an end on the arrow tip side is farther from the substrate (substrate on which the respective alignment film is provided) than an end on the opposite side. In the area of the optical alignment films corresponding to each of the liquid crystal domains D1 through D4, the pretilt direction of one alignment film 12 and the pretilt direction of the other alignment film 22 are different by about 90° from each other. It is preferable that the pretilt angle defined by one alignment film 12 and the pretilt angle defined by the other alignment film 22 are approximately equal to each other as described above.

As shown in FIG. 14, an even number of (four) picture elements forming one pixel P include the red picture element R and the blue picture element B in which the sides parallel to the row direction have a prescribed length L1 and the green picture element G and the yellow picture element Y in which the sides parallel to the row direction have a prescribed length L2, which is different from the length L1. Namely, the length L1 of the sides of the red picture element R and the blue picture element B which are parallel to the row direction is different from the length L2 of the sides of the green picture element G and the yellow picture element Y which are parallel to the row direction. Specifically, the length L1 is longer than the length L2 (i.e., L1>L2). By contrast, the sides of all the picture elements which are parallel to the column direction have an equal length L3. As can be seen from the above, in the pixel P of the liquid crystal display device 100 in this embodiment, there is one width of the picture elements in the column direction, whereas there are two widths of the picture elements in the row direction.

In each of the red picture element R and the blue picture element B, the liquid crystal domains D1 through D4 are located in the order of top left, bottom left, bottom right and top right (i.e., counterclockwise from top left). Therefore, the dark area DR appearing in each of the red picture element R and the blue picture element B is generally gammadion-shaped. By contrast, in each of the green picture element G and the yellow picture element Y, the liquid crystal domains D1 through D4 are located in the order of top right, bottom right, bottom left and top left (i.e., clockwise from top right). Therefore, the dark area DR appearing in each of the green picture element G and the yellow picture element Y is generally shaped like the letter “8”.

As described above, in the liquid crystal display device 100 in this embodiment, the arrangement pattern of the liquid crystal domains D1 through D4 in the red picture element R and the blue picture element B is different from that in the green picture element G and the yellow picture element Y. In the liquid crystal display device 100 having such a structure, the shifted exposure can be performed on the optical alignment film 12 of the TFT substrate S1 and the optical alignment film 22 of the CF substrate S2. Hereinafter, a method for producing the liquid crystal display device 100 will be described. The steps of producing the liquid crystal display device 100 except for the optical alignment processing on the optical alignment films 12 and 22 can be carried out by a known technique. Hence, the optical alignment processing on the optical alignment film 12 of the TFT substrate S1 and the optical alignment processing on the optical alignment film 22 of the CF substrate S2 will be described below. The exposure steps in the optical alignment processing may be carried out by using, for example, a proximity exposure device produced by Ushio Inc.

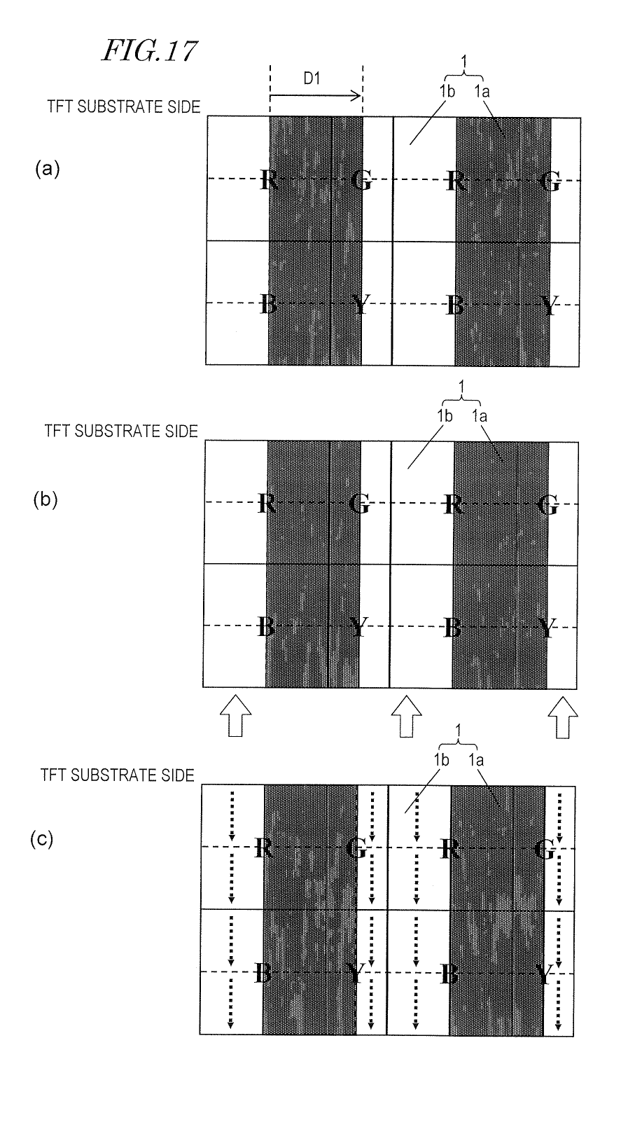

First, with reference to FIG. 15 through FIG. 17, the optical alignment processing on the optical alignment film 12 of the TFT substrate S1 will be described.

First, a photomask 1 shown in FIG. 15 is prepared. As shown in FIG. 15, the photomask 1 includes a plurality of light shielding parts 1a extending like stripes in the column direction (vertical direction) and a plurality of light transmitting parts 1b located between the plurality of light shielding parts 1a. A width W1 of each of the plurality of light transmitting parts 1b (width in the row direction) is equal to a sum of half of the length L1 of the sides of the red picture element R and the blue picture element B which are parallel to the row direction and half of the length L2 of the sides of the green picture element G and the yellow picture element Y which are parallel to the row direction (i.e., W1=(L1+L2)/2). A width W2 of each of the plurality of light shielding parts 1a (width in the row direction) is also equal to a sum of half of the length L1 of the sides of the red picture element R and the blue picture element B which are parallel to the row direction and half of the length L2 of the sides of the green picture element G and the yellow picture element Y which are parallel to the row direction (i.e., W2=(L1+L2)/2; W1+W2=L1+L2).

Next, as shown in FIG. 16(a), the photomask 1 is located such that a part of the optical alignment film 12 corresponding to a right half of the red picture element R and the blue picture element B and a left half of the green picture element G and the yellow picture element Y overlaps the light transmitting part 1b (i.e., such that a part of the optical alignment film 12 corresponding to a left half of the red picture element R and the blue picture element B and a right half of the green picture element G and the yellow picture element Y overlaps the light shielding part 1a).

Next, as shown in FIG. 16(b), ultraviolet rays are directed obliquely in the direction represented by the arrows. As a result of this exposure step, as shown in FIG. 16(c), the part of the optical alignment film 12 corresponding to the right half of the red picture element R and the blue picture element B and the left half of the green picture element G and the yellow picture element Y is given a prescribed pretilt direction. The pretilt direction given at this point is the same as the pretilt direction PA2 shown in FIG. 2(a). Hereinafter, this pretilt direction will be referred to as the “first pretilt direction” for the sake of convenience.

Next, as shown in FIG. 17(a), the photomask 1 is shifted in the row direction by a prescribed distance D1. In this example, the prescribed distance D1 is half (½) of a width PW1 (see FIG. 14) of the pixel P in the row direction. As a result of this movement, the part of the optical alignment film 12 corresponding to the left half of the red picture element R and the blue picture element B and the right half of the green picture element G and the yellow picture element Y overlaps the light transmitting part 1b of the photomask 1. Namely, the part of the optical alignment film 12 corresponding to the right half of the red picture element R and the blue picture element B and the left half of the green picture element G and the yellow picture element Y overlaps the light shielding part 1a of the photomask 1.

Next, as shown in FIG. 17(b), ultraviolet rays are directed obliquely in the direction represented by the arrows. As a result of this exposure step, as shown in FIG. 17(c), the remaining part of the optical alignment film 12, namely, the part thereof corresponding to the left half of the red picture element R and the blue picture element B and the right half of the green picture element G and the yellow picture element Y is given a prescribed pretilt direction. The pretilt direction given at this point is the same as the pretilt direction PA1 shown in FIG. 2(a) and is antiparallel to the first pretilt direction. Hereinafter, this pretilt direction will be referred to as the “second pretilt direction” for the sake of convenience.

As a result of the above-described optical alignment processing, in an area of the optical alignment film 12 corresponding to each picture element, an area having the first pretilt direction and an area having the second pretilt direction antiparallel to the first pretilt direction are formed. Hereinafter, the area having the first pretilt direction will be referred to as the “first area” for the sake of convenience, and the area having the second pretilt direction will be referred to as the “second area” for the sake of convenience. In each of the exposure step of directing the light toward the part of the optical alignment film 12 which is to be the first area and the exposure step of directing the light toward the part of the optical alignment film 12 which is to be the second area, light (typically, ultraviolet rays as in this example) is directed in a direction inclining at, for example, 30° to 50° with respect to the normal direction to the substrate. The pretilt angle defined by the optical alignment film 12 is, for example, 88.5° to 89°.

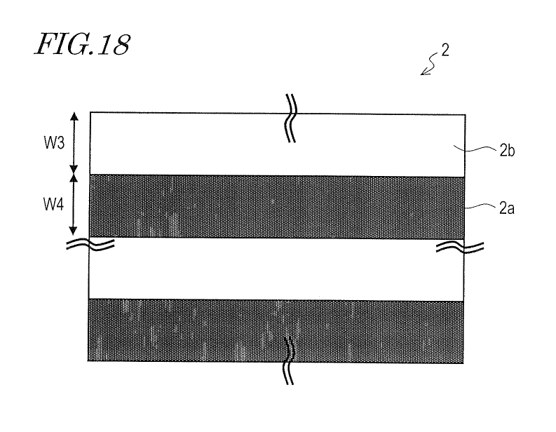

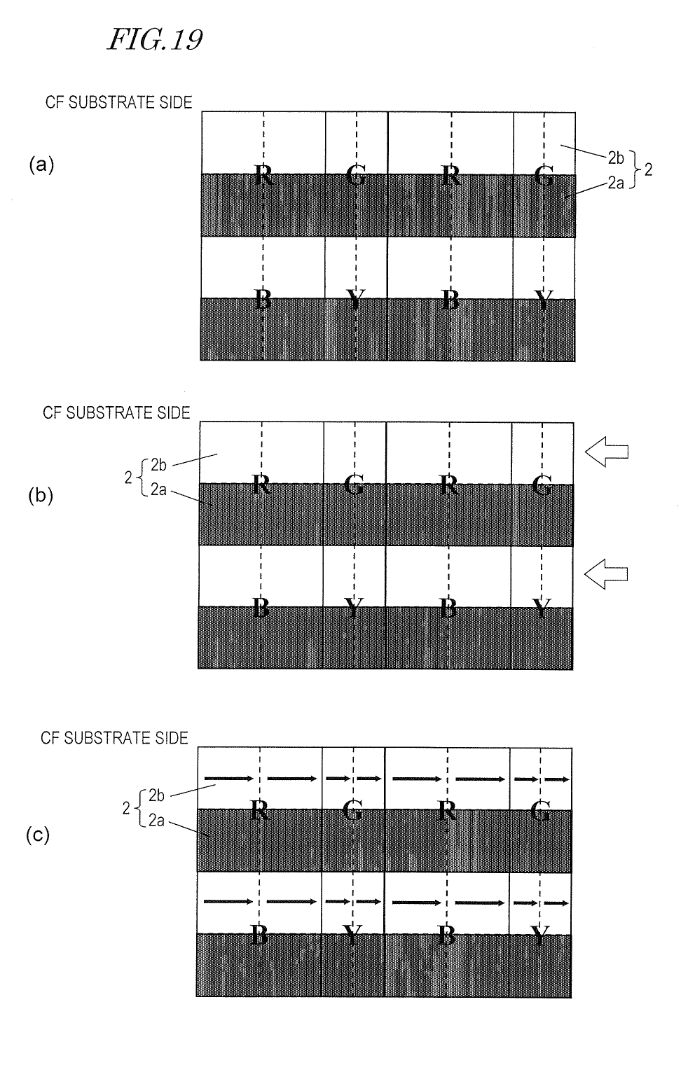

Now, with reference to FIG. 18 through FIG. 20, the optical alignment processing on the optical alignment film 22 of the CF substrate S2 will be described.

First, a photomask 2 shown in FIG. 18 is prepared. As shown in FIG. 18, the photomask 2 includes a plurality of light shielding parts 2a extending like stripes in the row direction (horizontal direction) and a plurality of light transmitting parts 2b located between the plurality of light shielding parts 2a. A width W3 of each of the plurality of light transmitting parts 2b (width in the column direction) is half of the length L3 of the sides of each picture element which are parallel to the column direction (i.e., W3=L3/2). A width W4 of each of the plurality of light shielding parts 2a (width in the column direction) is also half of the length L3 of the sides of each picture element which are parallel to the column direction (i.e., W4=L3/2; W3+W4=L3).

Next, as shown in FIG. 19(a), the photomask 2 is located such that a part of the optical alignment film 22 corresponding to a top half of the picture elements overlaps the light transmitting part 2b (i.e., such that a part of the optical alignment film 22 corresponding to a bottom half of the picture elements overlaps the light shielding part 2a).

Next, as shown in FIG. 19(b), ultraviolet rays are directed obliquely in the direction represented by the arrows. As a result of this exposure step, as shown in FIG. 19(c), the part of the optical alignment film 22 corresponding to the top half of the picture elements is given a prescribed pretilt direction. The pretilt direction given at this point is the same as the pretilt direction PB1 shown in FIG. 2(b). Hereinafter, this pretilt direction will be referred to as the “third pretilt direction” for the sake of convenience.

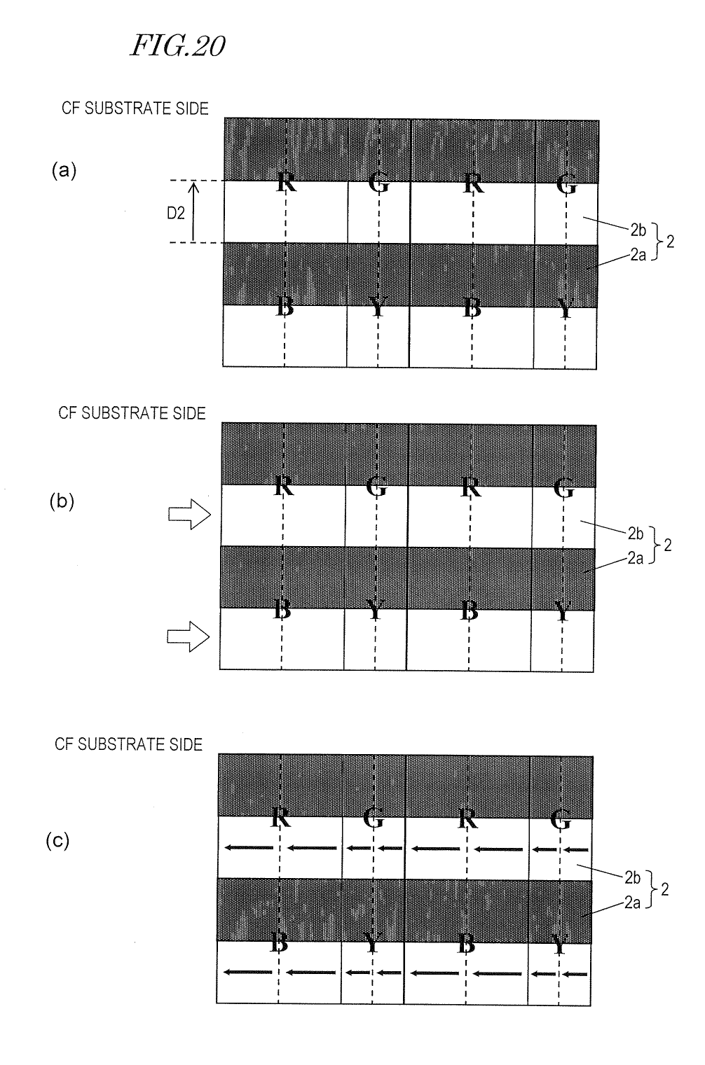

Next, as shown in FIG. 20(a), the photomask 2 is shifted in the column direction by a prescribed distance D2. In this example, the prescribed distance D2 is ¼ of a width PW2 (see FIG. 14) of the pixel P in the column direction, and is half (½) of the length L3 of the sides of each picture element which are parallel to the column direction. As a result of this movement, the part of the optical alignment film 22 corresponding to the bottom half of the picture elements overlaps the light transmitting part 2b of the photomask 2. Namely, the part of the optical alignment film corresponding to the top half of the picture elements overlaps the light shielding part 2a of the photomask 2.

Next, as shown in FIG. 20(b), ultraviolet rays are directed obliquely in the direction represented by the arrows. As a result of this exposure step, as shown in FIG. 20(c), the remaining part of the optical alignment film 22, namely, the part thereof corresponding to the bottom half of the picture elements is given a prescribed pretilt direction. The pretilt direction given at this point is the same as the pretilt direction PB2 shown in FIG. 2(b) and is antiparallel to the third pretilt direction. Hereinafter, this pretilt direction will be referred to as the “fourth pretilt direction” for the sake of convenience.

As a result of the above-described optical alignment processing, in an area of the optical alignment film 22 corresponding to each picture element, an area having the third pretilt direction and an area having the fourth pretilt direction antiparallel to the third pretilt direction are formed. Hereinafter, the area having the third pretilt direction will be referred to as the “third area” for the sake of convenience, and the area having the fourth pretilt direction will be referred to as the “fourth area” for the sake of convenience. In each of the exposure step of directing the light toward the part of the optical alignment film 22 which is to be the third area and the exposure step of directing the light toward the part of the optical alignment film 22 which is to be the fourth area, light (typically, ultraviolet rays as in this example) is directed in a direction inclining at, for example, 30° to 50° with respect to the normal direction to the substrate. The pretilt angle defined by the optical alignment film 22 is, for example, 88.5° to 89°.

By bringing together the TFT substrate S1 and the CF substrate S2 processed with the optical alignment in the above-described manner, the liquid crystal display device 100 shown in FIG. 14 in which each picture element is divided into liquid crystal domains having different alignment directions is obtained.

In the above-described production method, in the step of forming the first area and the second area (step of performing the optical alignment processing on the optical alignment film 12 of the TFT substrate S1), two exposure steps are performed by use of one, common photomask 1. In the step of forming the third area and the fourth area (step of performing the optical alignment processing on the optical alignment film 22 of the CF substrate S2), two exposure steps are performed by use of one, common photomask 2. Namely, according to the production method in this embodiment, the shifted exposure can be performed in the row direction in which there are two widths of the picture elements in addition to the column direction in which there is one width of the picture elements. Therefore, the optical alignment processing can be realized at low cost and in a short takt time. Inversely describing, because one pixel P includes picture elements having different arrangement patterns of the liquid crystal domains D1 through D4 (having different shapes of the dark area DR), the liquid crystal display device 100 in this embodiment can be produced by the method in which the shifted exposure is used for the optical alignment processing. By contrast, in the case where the 4D-RTN mode is merely adopted to a multiple primary color liquid crystal display device, as in the liquid crystal display device 900 shown in FIG. 10, all the picture elements in one pixel P have the same arrangement pattern of the liquid crystal domains D1 through D4. Therefore, the shifted exposure cannot be performed for the optical alignment processing on at least one of the substrates. In the liquid crystal display device 100 in this embodiment, one pixel P includes picture elements having different arrangement patterns of the liquid crystal domains D1 through D4, but this does not have any adverse influence on the viewing angle characteristics.

As described above, according to the present invention, even when the 4D-RTN mode is adopted to a multiple primary color liquid crystal display device, increase of the cost and time required for the optical alignment processing can be suppressed. As described above, in the photomask 1 used for the shifted exposure in the row direction (direction in which there are two widths of the picture elements) in the production method in this embodiment, the width W1 of the light transmitting part 1b is equal to the sum of half of the length L1 of the sides of the red picture element R and the blue picture element B which are parallel to the row direction and half of the length L2 of the sides of the green picture element G and the yellow picture element Y which are parallel to the row direction. Namely, the width W1 of the light transmitting part 1b is equal to the sum of half of the larger width among the two widths of the picture elements (i.e., the length L1) and half of the smaller width (length L2). By contrast, in the photomask 903 shown in FIG. 11, the width of the light transmitting part 903b is equal to half of either one of the two widths of the picture elements. More specifically, the width W1 of the light transmitting part 903b1, among the two types of light transmitting parts 903b1 and 903b2, is equal to half of the larger width (length L1), and the width W3 of the other transmitting part 903b2 is equal to half of the smaller width (length L2). As is seen from the above, according to the production method in this embodiment, the shifted exposure in the direction in which there are two widths of the picture elements is realized by use of the photomask 1 designed with a different conception from the conventional conception.

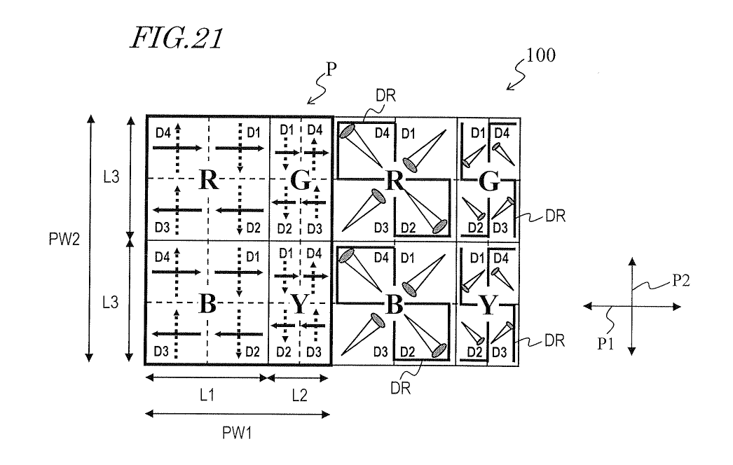

In this embodiment, in the red picture element R and the blue picture element B, the generally gammadion-shaped dark area DR appears; and in the green picture element G and the yellow picture element Y, the dark area DR generally shaped like the letter “8” appears. However, the present invention is not limited to this. As shown in FIG. 21, the dark area DR generally shaped like the letter “8” may appear in the red picture element R and the blue picture element B, and the generally gammadion-shaped dark area DR may appear in the green picture element G and the yellow picture element Y. In the structure shown in FIG. 21, in the red picture element R and the blue picture element B, the liquid crystal domains D1 through D4 are located in the order of top right, bottom right, bottom left and top left (i.e., clockwise from top right). By contrast, in the green picture element G and the yellow picture element Y, the liquid crystal domains D1 through D4 are located in the order of top left, bottom left, bottom right and top right (i.e., counterclockwise from top left). The arrangement of the liquid crystal domains shown in FIG. 21 can be realized by, for example, directing the light in the opposite directions in the exposure step shown in FIG. 16(b) and the exposure step shown in FIG. 17(b).

In this embodiment, the width W1 of the light transmitting part 1b and the width W2 of the light shielding part 1a of the photomask 1 are equal to each other, and are equal to the sum of half of the length L1 of the sides of the red picture element R and the blue picture element B which are parallel to the row direction and half of the length L2 of the sides of the green picture element G and the yellow picture element Y which are parallel to the row direction (i.e., W1=W2=(L1+L2)/2). It is sufficient that the width W1 of the light transmitting part 1b and the width W2 of the light shielding part 1a are generally equal to (L1+L2)/2, and the width W1 and the width W2 do not need to be precisely equal to (L1+L2)/2. For example, the width W1 of the light transmitting part 1b may be increased by a prescribed amount Δ (i.e., W1=(L1+L2)/2+Δ) and the width W2 of the light shielding part 1a may be decreased by the same amount (i.e., W2=(L1+L2)/2−Δ).

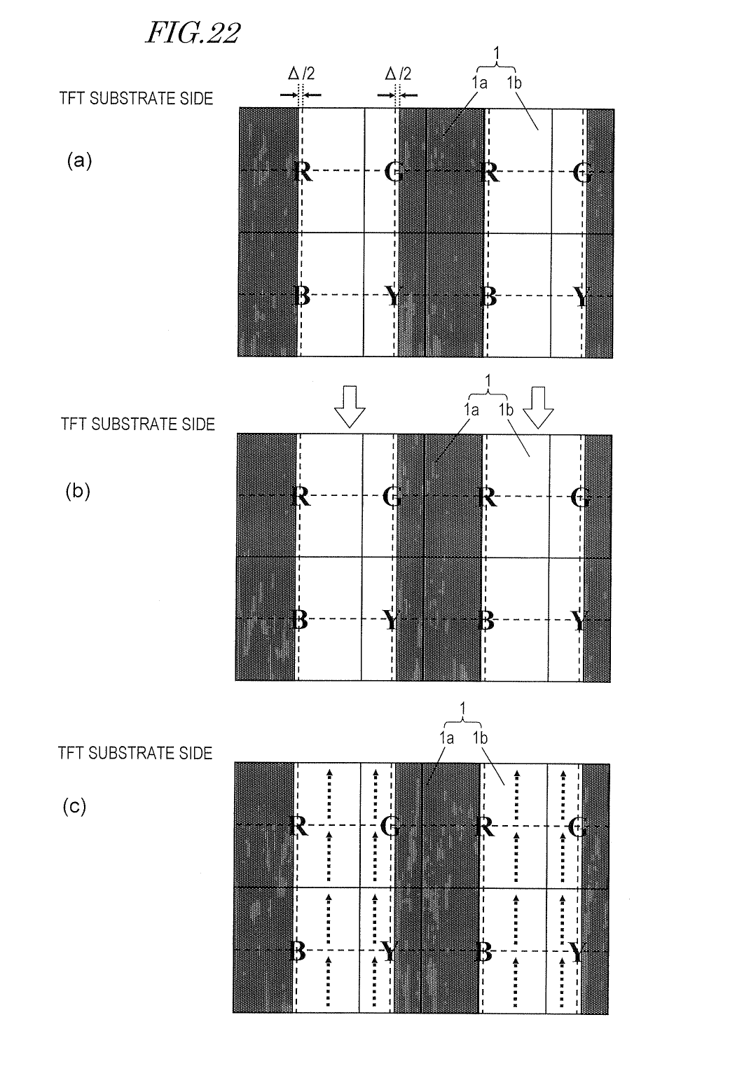

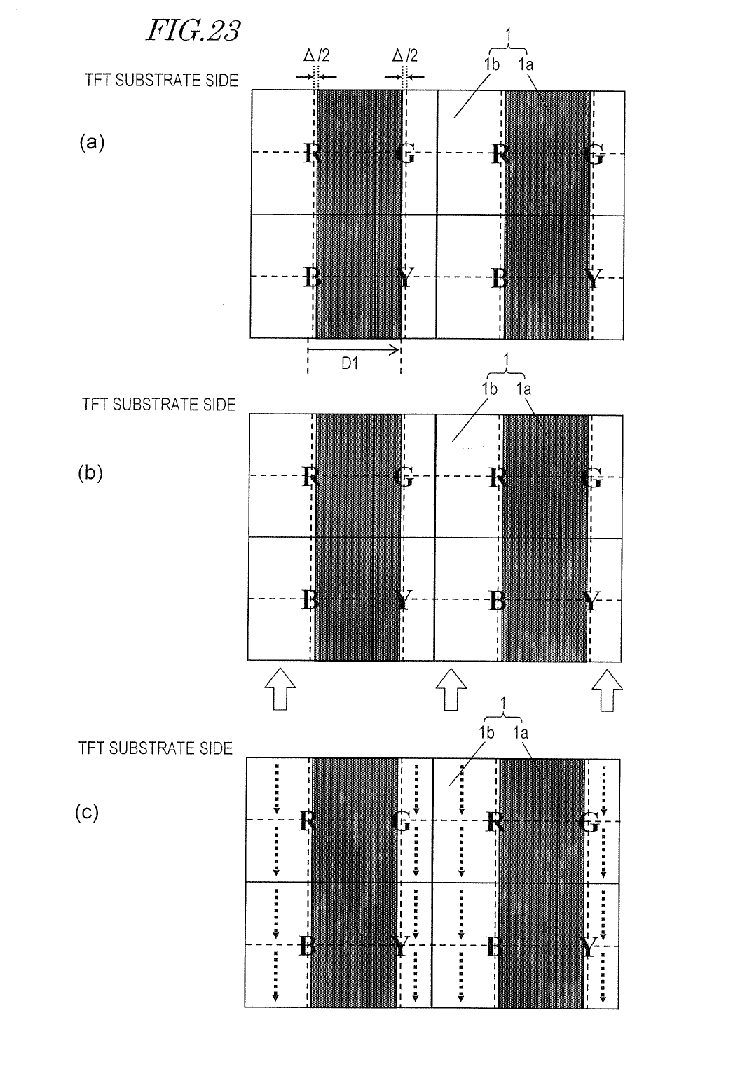

Regarding the case where the width W1 of the light transmitting part 1b of the photomask 1, the width W2 of the light shielding part 1a of the photomask 1, the length L1 of the sides of the red picture element R and the blue picture element B which are parallel to the row direction, and the length L2 of the sides of the green picture element G and the yellow picture element Y which are parallel to the row direction fulfill the relationships of W1=(L1+L2)/2+Δ and W2=(L1+L2)/2−Δ, the optical alignment processing on the optical alignment film 12 of the TFT substrate S1 will be described with reference to FIG. 22 and FIG. 23.

First, as shown in FIG. 22(a), the photomask 1 is located such that a part of the optical alignment film 12 corresponding to the right half of the red picture element R and the blue picture element B and the left half of the green picture element G and the yellow picture element Y overlaps the light transmitting part 1b. Since the width W1 of the light transmitting part 1b of the photomask 1 is larger than (L1+L2)/2 by Δ, a part of the optical alignment film 12 corresponding to a small part of the left half of the red picture element R and the blue picture element B and a part of the optical alignment film 12 corresponding to a small part of the right half of the green picture element G and the yellow picture element Y (the small parts each have a width of Δ/2) also overlap the light transmitting part 1b.

Next, as shown in FIG. 22(b), ultraviolet rays are directed obliquely in the direction represented by the arrows. As a result of this exposure step, as shown in FIG. 22(c), the part of the optical alignment film 12 corresponding to the right half of the red picture element R and the blue picture element B and the left half of the green picture element G and the yellow picture element Y is given a prescribed pretilt direction.

Next, as shown in FIG. 23(a), the photomask 1 is shifted in the row direction by the prescribed distance D1 (specifically, half of the width PW1 of the pixel P in the row direction). As a result of this movement, the part of the optical alignment film 12 corresponding to the left half of the red picture element R and the blue picture element B and the right half of the green picture element G and the yellow picture element Y overlaps the light transmitting part lb of the photomask 1. Since the width W1 of the light transmitting part 1b of the photomask 1 is larger than (L1+L2)/2 by Δ, a part of the optical alignment film 12 corresponding to a small part of the right half of the red picture element R and the blue picture element B and a part of the optical alignment film 12 corresponding to a small part of the left half of the green picture element G and the yellow picture element Y (the small parts each have a width of λ/2) also overlap the light transmitting part 1b.

Next, as shown in FIG. 23(b), ultraviolet rays are directed obliquely in the direction represented by the arrows. As a result of this exposure step, as shown in FIG. 23(c), the remaining part of the optical alignment film 12, namely, the part thereof corresponding to the left half of the red picture element R and the blue picture element B and the right half of the green picture element G and the yellow picture element Y is given a prescribed pretilt direction.

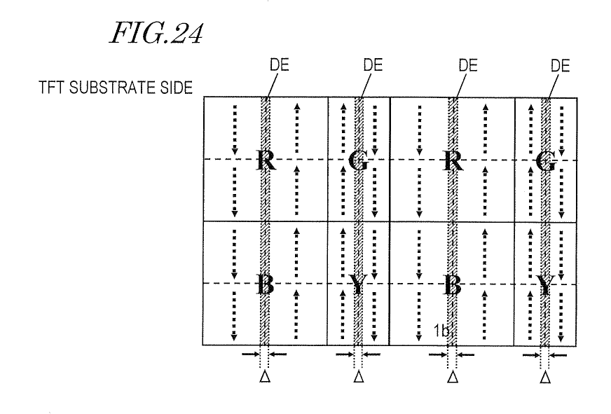

In the case where the optical alignment processing is performed as described above, as shown in FIG. 24, an area DE irradiated with the light in both of the first exposure step and the second exposure step (double-exposed area DE) is formed in a central part of each picture element (central part in the row direction). The double-exposed area DE has a width equal to the increasing amount Δ of the width W1 of the light transmitting part 1b.

The double-exposed area DE is an area for obtaining a margin against an alignment divergence which is caused when the photomask 1 is shifted for exposure. The alignment precision of the exposure device is about ±several micrometers at the maximum. Therefore, it is preferable from the viewpoint of reliability that no unexposed area is formed in a picture element even if the alignment divergence occurs. When there is an unexposed area, ion components, which are impurities in the liquid crystal layer 3 and the alignment films 12 and 22, are attracted to the unexposed area, which may cause faults such as DC divergence (divergence of the DC level between the signal voltage and the counter voltage), stains or the like.

When the conditions under which the double-exposed area DE is formed, namely, the relationships of W1=(L1+L2)/2+Δ and W2=(L1+L2)/2−Δ, are fulfilled, formation of an unexposed area can be prevented even if an alignment divergence occurs. From the viewpoint of preventing the formation of the unexposed area with more certainty, it is preferable that the increasing amount Δ of the width W1 of the transmitting part 1b is larger. However, when the increasing amount Δ is too large, namely, when the width of the double-exposed area is too large, the width of the dark line at or in the vicinity of the center of the picture element (part of the cross-shaped dark line CL which extends in the vertical direction) is increased and thus the transmittance is decreased. From the viewpoint of suppressing the decrease of the transmittance, it is preferable that the increasing amount Δ of the width W1 of the light transmitting part 1b is equal to or smaller than 10 μm (i.e., 0<Δ≦10). From the viewpoint of further suppressing the decrease of the transmittance and preventing the formation of an unexposed area with more certainty, it is preferable that the increasing amount Δ is equal to or larger than 1 μm and equal to or smaller than 5 μm (i.e., 1≦Δ5).

In this embodiment, an area of the optical alignment film 12 of the TFT substrate S1 corresponding to each picture element is divided into the left part and the right part and an area of the optical alignment film 22 of the CF substrate S2 corresponding to each picture element is divided into the top part and the bottom part. The present invention is not limited to this structure. An area of the optical alignment film 12 of the TFT substrate S1 corresponding to each picture element may be divided into the top part and the bottom part and an area of the optical alignment film 22 of the CF substrate S2 corresponding to each picture element may be divided into the left part and the right part. In this case, for performing the optical alignment processing on the optical alignment film 12 of the TFT substrate S1, the photomask 2 shown in FIG. 18 may be used to perform the shifted exposure in the column direction, and for performing the optical alignment processing on the optical alignment film 22 of the CF substrate S2, the photomask 1 shown in FIG. 15 may be used to perform the shifted exposure in the row direction.

### Embodiment 2

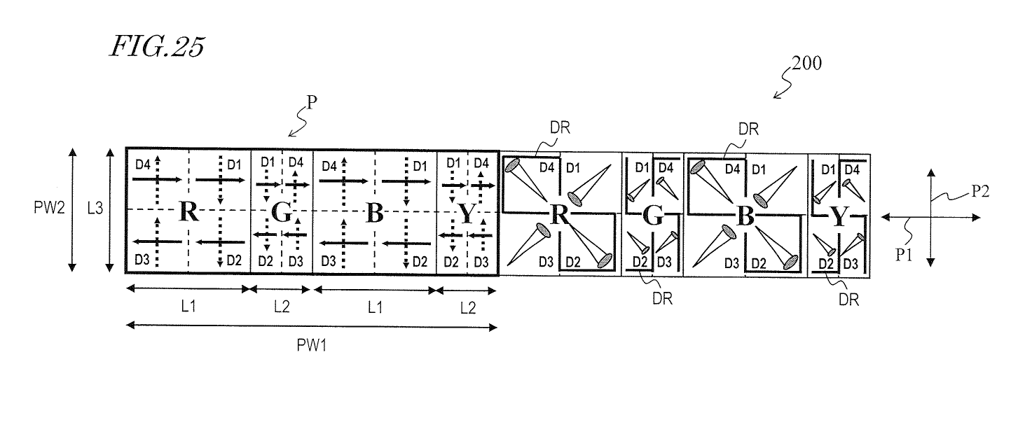

FIG. 25 shows a liquid crystal display device 200 in this embodiment. FIG. 25 is a plan view schematically showing two pixels P of the liquid crystal display device 200.

In the liquid crystal display device 100 shown in FIG. 14, one pixel P includes a red picture element R, a green picture element G, a blue picture element B and a yellow picture element Y arranged in a matrix of 2 rows×2 columns. Namely, the color filters are arranged like the Chinese character “ [symbol] ”. By contrast, in the liquid crystal display device 200 in this embodiment, as shown in FIG. 25, one pixel P includes a red picture element R, a green picture element G, a blue picture element B and a yellow picture element Y arranged in 1 row×4 columns. Namely, the color filters are arranged in stripes.

A length L1 of the sides of the red picture element R and the blue picture element B which are parallel to the row direction is different from a length L2 of the sides of the green picture element G and the yellow picture element Y which are parallel to the row direction. Specifically, the length L1 is longer than the length L2 (i.e., L1>L2). By contrast, the sides of all the picture elements which are parallel to the column direction have an equal length L3. As can be seen from the above, in the pixel P of the liquid crystal display device 200 in this embodiment also, there is one width of the picture elements in the column direction, whereas there are two widths of the picture elements in the row direction.

In the pixel P, the red picture element R, the blue picture element B, the green picture element G and the yellow picture element Y are arranged in this order from the left. Namely, in the pixel P, the relatively wider picture elements and the relatively narrower picture elements are arranged alternately in the row direction.

In each of the red picture element R and the blue picture element B, the liquid crystal domains D1 through D4 are located in the order of top right, bottom right, bottom left and top left (i.e., clockwise from top right). Therefore, the dark area DR appearing in each of the red picture element R and the blue picture element B is generally shaped like the letter “8”. By contrast, in each of the green picture element G and the yellow picture element Y, the liquid crystal domains D1 through D4 are located in the order of top left, bottom left, bottom right and top right (i.e., counterclockwise from top left). Therefore, the dark area DR appearing in each of the green picture element G and the yellow picture element Y is generally gammadion-shaped.

As described above, in the liquid crystal display device 200 in this embodiment also, the arrangement pattern of the liquid crystal domains D1 through D4 in the red picture element R and the blue picture element B is different from that in the green picture element G and the yellow picture element Y. Since one pixel P includes picture elements having different arrangement patterns of the liquid crystal domains D1 through D4 (having different shapes of the dark area DR), the shifted exposure can be performed in the row direction in addition to the column direction. Hereinafter, the optical alignment processing on a pair of optical alignment films included in the liquid crystal display device 200 will be described.

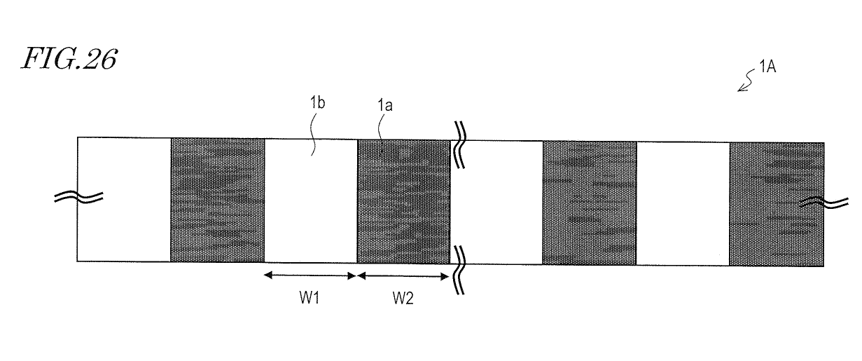

First, with reference to FIG. 26 through FIG. 28, the optical alignment processing on an optical alignment film of a TFT substrate will be described.

First, a photomask 1A shown in FIG. 26 is prepared. As shown in FIG. 26, the photomask 1A includes a plurality of light shielding parts 1a extending like stripes in the column direction (vertical direction) and a plurality of light transmitting parts b located between the plurality of light shielding parts 1a. A width W1 of each of the plurality of light transmitting parts 1b (width in the row direction) is equal to a sum of half of the length L1 of the sides of the red picture element R and the blue picture element B which are parallel to the row direction and half of the length L2 of the sides of the green picture element G and the yellow picture element Y which are parallel to the row direction (i.e., W1=(L1+L2)/2). A width W2 of each of the plurality of light shielding parts 1a (width in the row direction) is also equal to a sum of half of the length L1 of the sides of the red picture element R and the blue picture element B which are parallel to the row direction and half of the length L2 of the sides of the green picture element G and the yellow picture element Y which are parallel to the row direction (i.e., W2=(L1+L2)/2; W1+W2=L1+L2).

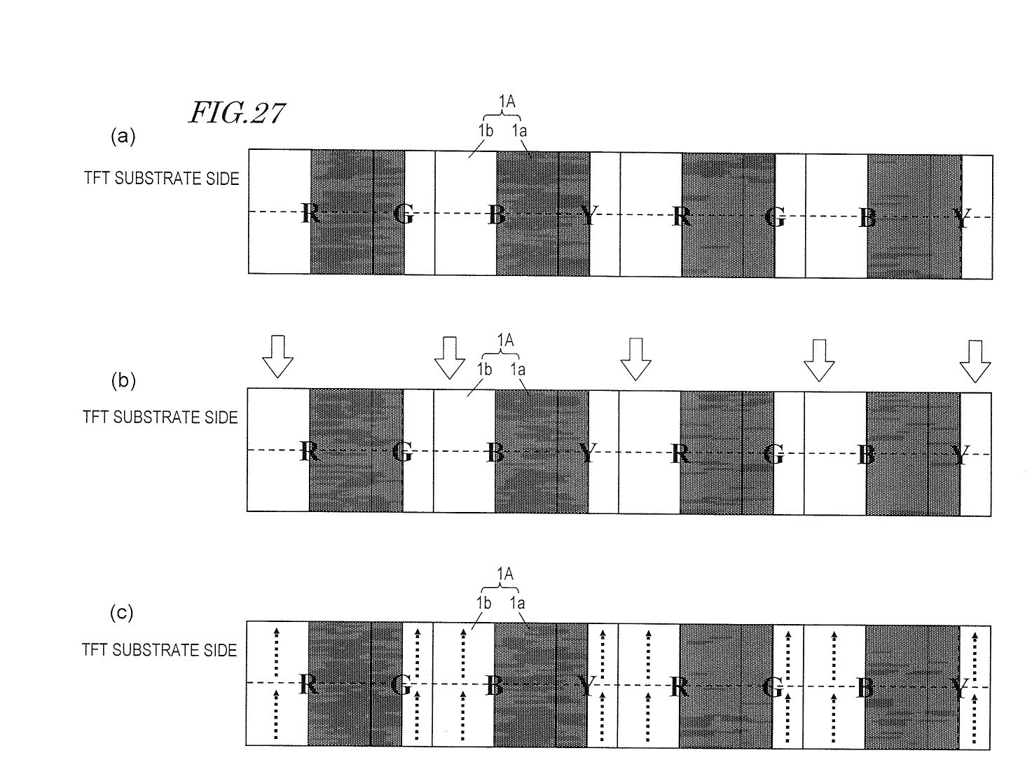

Next, as shown in FIG. 27(a), the photomask 1A is located such that parts of the optical alignment film corresponding to a left half of the red picture element R, a left half the blue picture element B, a right half of the green picture element G and a right half of the yellow picture element Y overlap the light transmitting parts 1b (i.e., such that parts of the optical alignment film corresponding to a right half of the red picture element R, a right half of the blue picture element B, a left half of the green picture element G and a left half of the yellow picture element Y overlap the light shielding parts 1a).

Next, as shown in FIG. 27(b), ultraviolet rays are directed obliquely in the direction represented by the arrows. As a result of this exposure step, as shown in FIG. 27(c), the parts of the optical alignment film corresponding to the left half of the red picture element R, the left half of the blue picture element B, the right half of the green picture element G and the right half of the yellow picture element Y are given a prescribed pretilt direction. The pretilt direction given at this point is the same as the pretilt direction PA2 shown in FIG. 2(a).

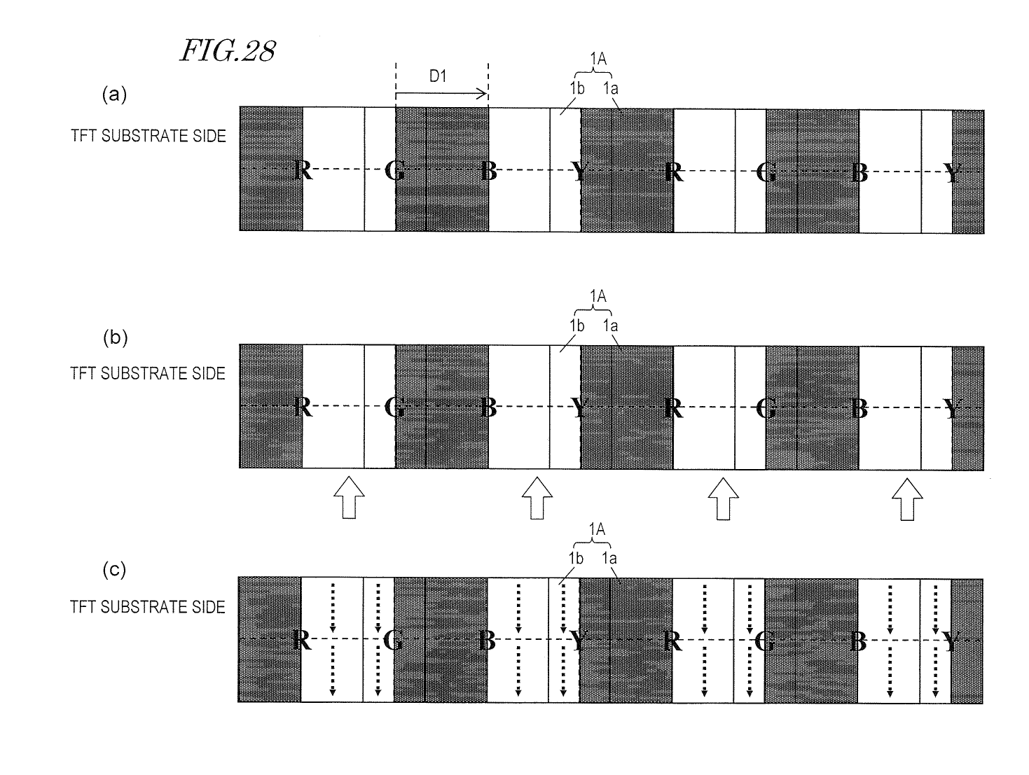

Next, as shown in FIG. 28(a), the photomask 1A is shifted in the row direction by a prescribed distance D1. In this example, the prescribed distance D1 is ¼ of a width PW1 (see FIG. 25) of the pixel P in the row direction. As a result of this movement, the parts of the optical alignment film corresponding to the right half of the red picture element R, the right half of the blue picture element B, the left half of the green picture element G and the left half of the yellow picture element Y overlap the light transmitting parts 1b of the photomask 1A. Namely, the parts of the optical alignment film corresponding to the left half of the red picture element R, the left half of the blue picture element B, the right half of the green picture element G and the right half of the yellow picture element Y overlap the light shielding parts 1a of the photomask 1A.

Next, as shown in FIG. 28(b), ultraviolet rays are directed obliquely in the direction represented by the arrows. As a result of this exposure step, as shown in FIG. 28(c), the remaining parts of the optical alignment film, namely, the parts thereof corresponding to the right half of the red picture element R, the right half of the blue picture element B, the left half of the green picture element G and the left half of the yellow picture element Y are given a prescribed pretilt direction. The pretilt direction given at this point is the same as the pretilt direction PA1 shown in FIG. 2(a) and is antiparallel to the pretilt direction shown in FIG. 27(c).

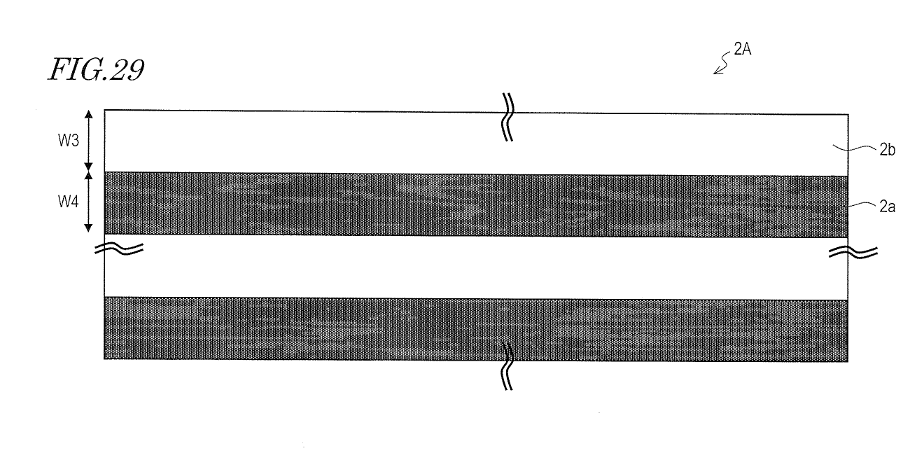

As a result of the above-described optical alignment processing, in an area of the optical alignment film of the TFT substrate corresponding to each picture element, two areas having pretilt directions antiparallel to each other are formed. Now, with reference to FIG. 29 through FIG. 31, the optical alignment processing on an optical alignment film of a CF substrate will be described.

First, a photomask 2A shown in FIG. 29 is prepared. As shown in FIG. 29, the photomask 2A includes a plurality of light shielding parts 2a extending like stripes in the row direction (horizontal direction) and a plurality of light transmitting parts 2b located between the plurality of light shielding parts 2a. A width W3 of each of the plurality of light transmitting parts 2b (width in the column direction) is half of the length L3 of the sides of each picture element which are parallel to the column direction (i.e., W3=L3/2). A width W4 of each of the plurality of light shielding parts 2a (width in the column direction) is also half of the length L3 of the sides of each picture element which are parallel to the column direction (i.e., W4=L3/2; W3+W4=L3).

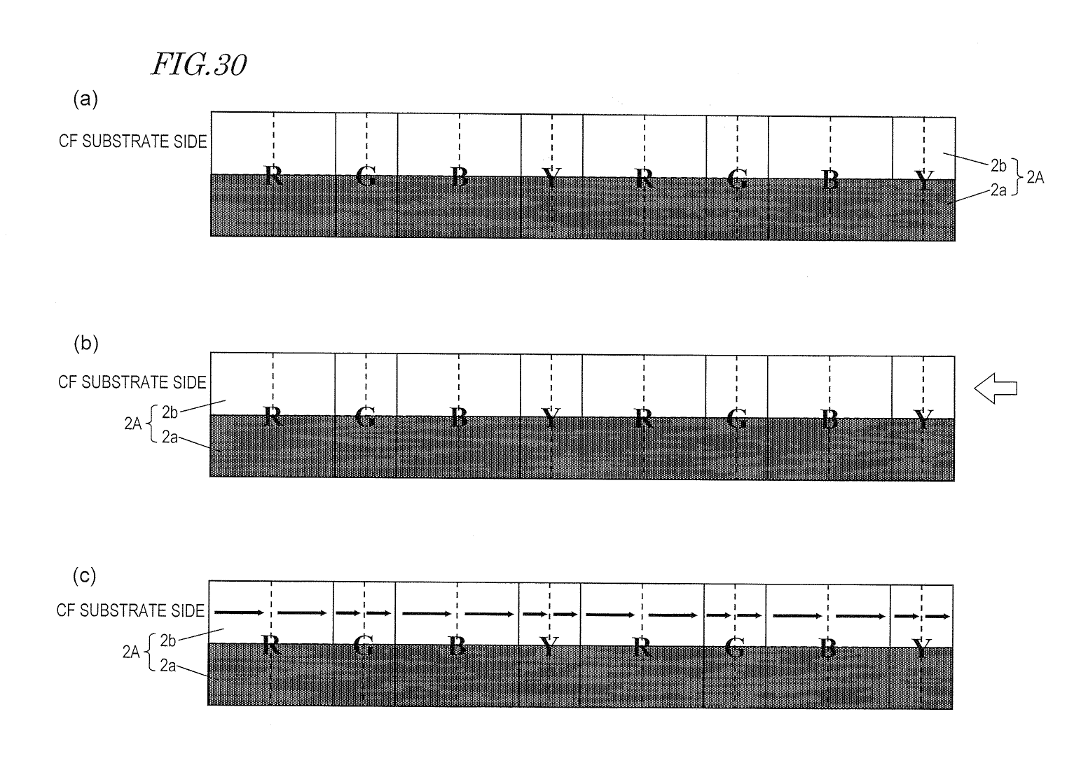

Next, as shown in FIG. 30(a), the photomask 2A is located such that a part of the optical alignment film corresponding to a top half of the picture elements overlaps the light transmitting part 2b (i.e., such that a part of the optical alignment film corresponding to a bottom half of the picture elements overlaps the light shielding part 2a).

Next, as shown in FIG. 30(b), ultraviolet rays are directed obliquely in the direction represented by the arrow. As a result of this exposure step, as shown in FIG. 30(c), the part of the optical alignment film corresponding to the top half of the picture elements is given a prescribed pretilt direction. The pretilt direction given at this point is the same as the pretilt direction PB1 shown in FIG. 2(b).

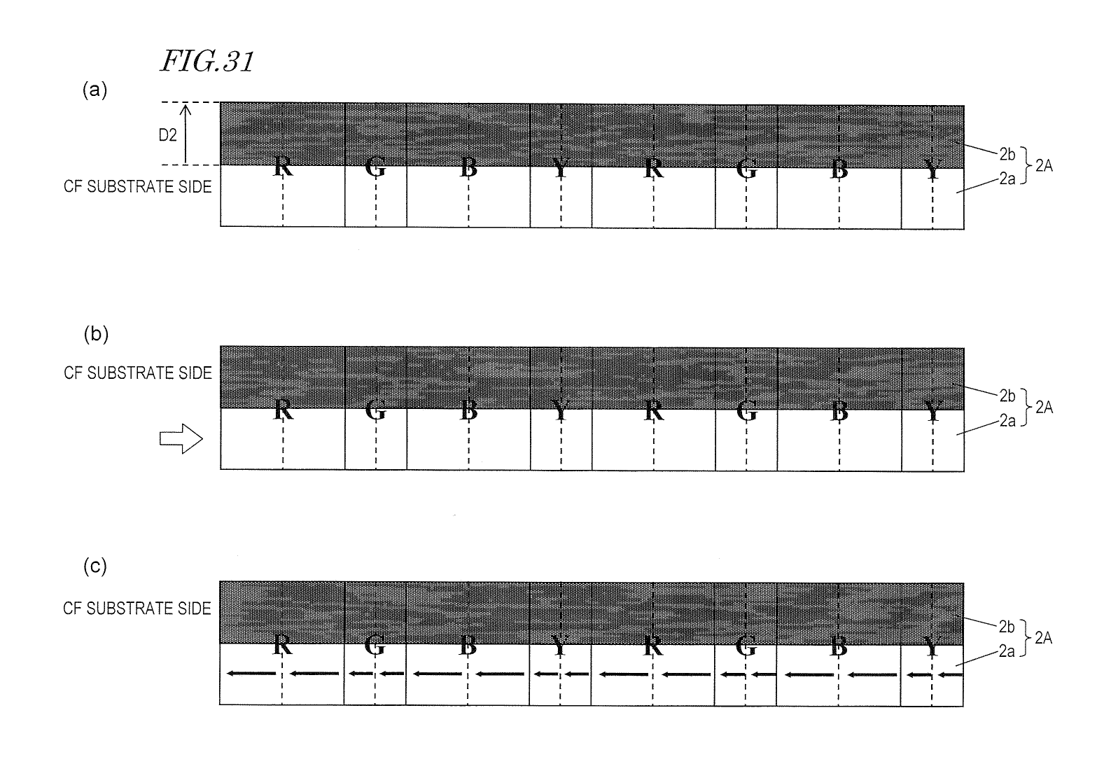

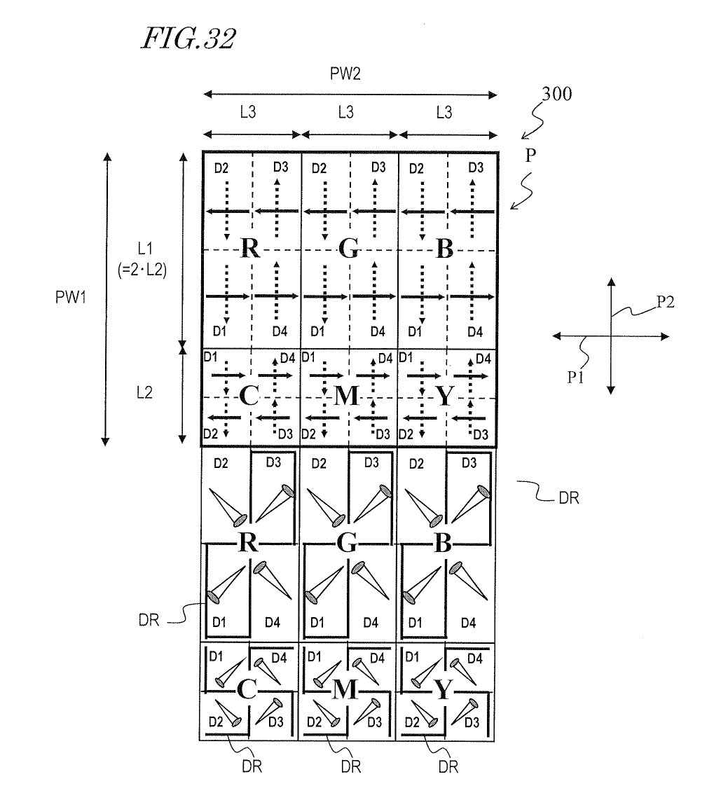

Next, as shown in FIG. 31(a), the photomask 2A is shifted in the column direction by a prescribed distance D2. In this example, the prescribed distance D2 is half (½) of a width PW2 (see FIG. 25) of the pixel P in the column direction, and is half (½) of the length L3 of the sides of each picture element which are parallel to the column direction. As a result of this movement, the part of the optical alignment film corresponding to the bottom half of the picture elements overlaps the light transmitting part 2b of the photomask 2A. Namely, the part of the optical alignment film corresponding to the top half of the picture elements overlaps the light shielding part 2a of the photomask 2A.

Next, as shown in FIG. 31(b), ultraviolet rays are directed obliquely in the direction represented by the arrow. As a result of this exposure step, as shown in FIG. 31(c), the remaining part of the optical alignment film, namely, the part thereof corresponding to the bottom half of the picture elements is given a prescribed pretilt direction. The pretilt direction given at this point is the same as the pretilt direction PB2 shown in FIG. 2(b) and is antiparallel to the pretilt direction shown in FIG. 30(c).

As a result of the above-described optical alignment processing, in an area of the optical alignment film of the CF substrate corresponding to each picture element, two areas having pretilt directions antiparallel to each other are formed. By bringing together the TFT substrate and the CF substrate processed with the optical alignment in the above-described manner, the liquid crystal display device 200 shown in FIG. 25 in which each picture element is divided into liquid crystal domains having different alignment directions is obtained.

In the production method of the liquid crystal display device 200 also, in the step of performing the optical alignment processing on the optical alignment film of the TFT substrate, two exposure steps are performed by use of one, common photomask 1A. In the step of performing the optical alignment processing on the optical alignment film of the CF substrate, two exposure steps are performed by use of one, common photomask 2A. Namely, the shifted exposure can be performed in the row direction in which there are two widths of the picture elements in addition to the column direction in which there is one width of the picture elements. Therefore, the optical alignment processing can be realized at low cost and in a short takt time. As can be seen from the above, in the liquid crystal display device 200 in this embodiment also, because one pixel P includes picture elements having different arrangement patterns of the liquid crystal domains D1 through D4 (having different shapes of the dark area DR), increase of the cost and time required for the optical alignment processing can be suppressed.

In the production method of the liquid crystal display device 100 in Embodiment 1, the moving distance D1 of the photomask 1 in the row direction is ½ of the width PW1 of the pixel P in the row direction (see FIG. 17(a)). By contrast, in the production method of the liquid crystal display device 200 in this embodiment, the moving distance D1 of the photomask 1A in the row direction is ¼ of the width PW1 of the pixel P in the row direction (see FIG. 28(a)). A reason for this is that in the pixel P of the liquid crystal display device 100, the picture elements are arranged in two columns; whereas in the pixel P of the liquid crystal display device 200, the picture elements are arranged in four columns. In the case where there are two widths of the picture elements in the row direction, the moving distance D1 of the photomask in the row direction is about 1/m of the width PW1 of the pixel P in the row direction (m is an even number of 2 or greater). As described in Embodiments 1 and 2, in the case where the picture elements are arranged in two columns in the pixel P, m=2, and in the case where the picture elements are arranged in four columns in the pixel P, m=4. Namely, m is equal to the number of columns of the picture elements in the pixel P. In the meantime, the moving distance D2 of the photomask in the column direction in which there is one width of the picture elements is about half (about ½) of the length L3 of the sides of each picture element which are parallel to the column direction.

### Embodiment 3

FIG. 32 shows a liquid crystal display device 300 in this embodiment. FIG. 32 is a plan view schematically showing two pixels P of the liquid crystal display device 300.

As shown in FIG. 32, each pixel P of the liquid crystal display device 300 includes a cyan picture element C for displaying cyan and a magenta picture element M for displaying magenta in addition to a red picture element R, a green picture element G, a blue picture element B and a yellow picture element Y. Accordingly, the liquid crystal display device 300 provides display by use of six primary colors. The red picture element R, the green picture element G, the blue picture element B, the yellow picture element Y, the cyan picture element C and the magenta picture element M are arranged in a matrix of 2 rows×3 columns in the pixel P.

As shown in FIG. 32, an even number of (six) picture elements forming one pixel P include the red picture element R, the green picture element G and the blue picture element B in which the sides parallel to the column direction have a prescribed length L1, and the yellow picture element Y, the cyan picture element C and the magenta picture element M in which the sides parallel to the column direction have a prescribed length L2, which is different from the length L1. Namely, the length L1 of the sides of the red picture element R, the green picture element G and the blue picture element B which are parallel to the column direction is different from the length L2 of the sides of the yellow picture element Y, the cyan picture element C and the magenta picture element M which are parallel to the column direction. Specifically, the length L1 is twice the length L2 (i.e., L1=2·L2). By contrast, the sides of all the picture elements which are parallel to the row direction have an equal length L3. As can be seen from the above, in the pixel P of the liquid crystal display device 300 in this embodiment, there is one width of the picture elements in the row direction, whereas there are two widths of the picture elements in the column direction.

In each of the red picture element R, the green picture element G and the blue picture element B, the liquid crystal domains D1 through D4 are located in the order of bottom left, top left, top right and bottom right (i.e., clockwise from bottom left). Therefore, the dark area DR appearing in each of the red picture element R, the green picture element G and the blue picture element B is generally shaped like the letter “8”. By contrast, in each of the yellow picture element Y, the cyan picture element C and the magenta picture element M, the liquid crystal domains D1 through D4 are located in the order of top left, bottom left, bottom right and top right (i.e., counterclockwise from top left). Therefore, the dark area DR appearing in each of the yellow picture element Y, the cyan picture element C and the magenta picture element M is generally gammadion-shaped.

As described above, in the liquid crystal display device 300 in this embodiment, the arrangement pattern of the liquid crystal domains D1 through D4 in the red picture element R, the green picture element G and the blue picture element B is different from that in the yellow picture element Y, the cyan picture element C and the magenta picture element M. Since one pixel P includes picture elements having different arrangement patterns of the liquid crystal domains D1 through D4 (having different shapes of the dark area DR), the shifted exposure can be performed in the column direction in addition to the row direction in which there is one width of the picture elements. Hereinafter, the optical alignment processing on a pair of optical alignment films included in the liquid crystal display device 300 will be described.

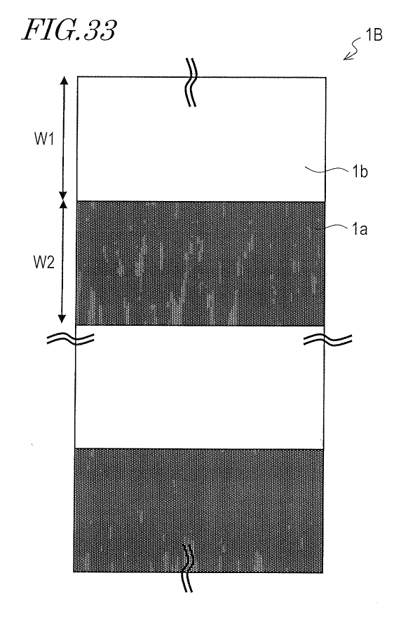

First, with reference to FIG. 33 through FIG. 35, the optical alignment processing on an optical alignment film of a CF substrate will be described.

First, a photomask 1B shown in FIG. 33 is prepared. As shown in FIG. 33, the photomask 1B includes a plurality of light shielding parts 1a extending like stripes in the row direction (horizontal direction) and a plurality of light transmitting parts 1b located between the plurality of light shielding parts 1a. A width W1 of each of the plurality of light transmitting parts 1b (width in the column direction) is equal to a sum of half of the length L1 of the sides of the red picture element R, the green picture element G and the blue picture element B which are parallel to the column direction and half of the length L2 of the sides of the yellow picture element Y, the cyan picture element C and the magenta picture element M which are parallel to the column direction (i.e., W1=(L1+L2)/2=(3·L2)/2). A width W2 of each of the plurality of light shielding parts 1a (width in the column direction) is also equal to a sum of half of the length L1 of the sides of the red picture element R, the green picture element G and the blue picture element B which are parallel to the column direction and half of the length L2 of the sides of the yellow picture element Y, the cyan picture element C and the magenta picture element M which are parallel to the column direction (i.e., W2=(L1+L2)/2=(3·L2)/2); W1+W2=L1+L2=3·L2).

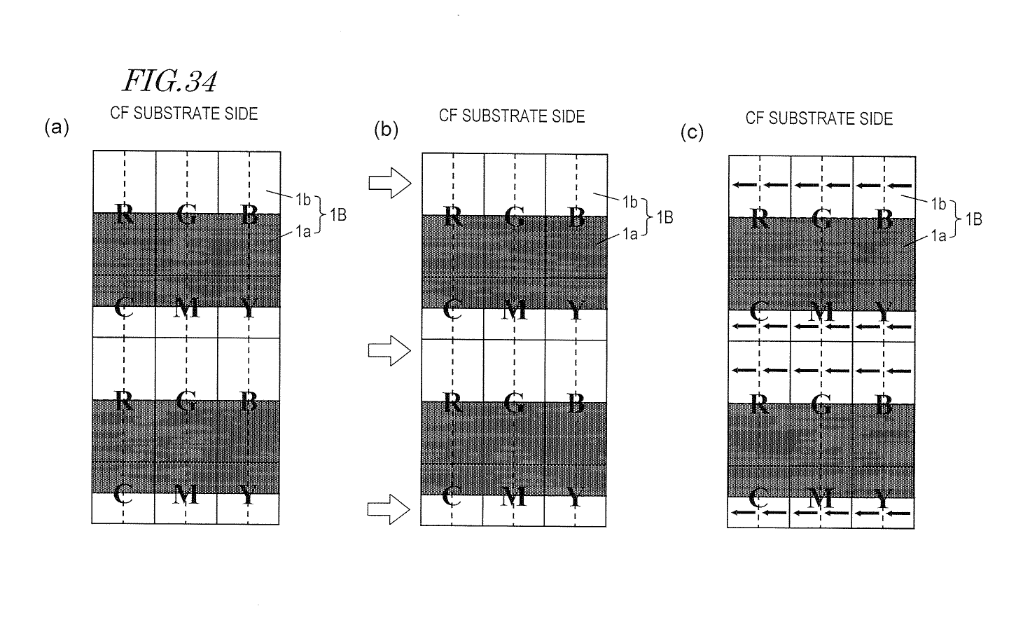

Next, as shown in FIG. 34(a), the photomask 1B is located such that a part of the optical alignment film corresponding to a top half of the red picture element R, the green picture element G and the blue picture element B and a bottom half of the yellow picture element Y, the cyan picture element C and the magenta picture element M overlaps the light transmitting part 1b (i.e., such that a part of the optical alignment film corresponding to a bottom half of the red picture element R, the green picture element G and the blue picture element B and a top half of the yellow picture element Y, the cyan picture element C and the magenta picture element M overlaps the light shielding part 1a).

Next, as shown in FIG. 34(b), ultraviolet rays are directed obliquely in the direction represented by the arrows. As a result of this exposure step, as shown in FIG. 34(c), the part of the optical alignment film corresponding to the top half of the red picture element R, the green picture element G and the blue picture element B and the bottom half of the yellow picture element Y, the cyan picture element C and the magenta picture element M is given a prescribed pretilt direction. The pretilt direction given at this point is the same as the pretilt direction PB2 shown in FIG. 2(b).

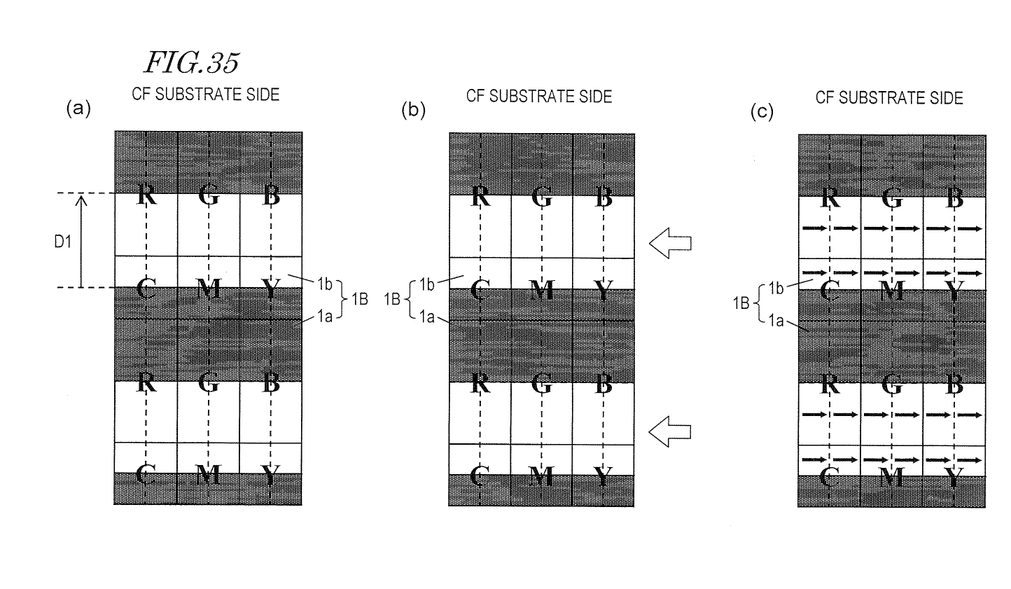

Next, as shown in FIG. 35(a), the photomask 1B is shifted in the column direction by a prescribed distance D1. In this example, the prescribed distance D1 is half (½) of a width PW1 (see FIG. 32) of the pixel P in the column direction. As a result of this movement, the part of the optical alignment film corresponding to the bottom half of the red picture element R, the green picture element G and the blue picture element B and the top half of the yellow picture element Y, the cyan picture element C and the magenta picture element M overlaps the light transmitting part 1b of the photomask 1B. Namely, the part of the optical alignment film corresponding to the top half of the red picture element R, the green picture element G and the blue picture element B and the bottom half of the yellow picture element Y, the cyan picture element C and the magenta picture element M overlaps the light shielding part 1a of the photomask 1B.

Next, as shown in FIG. 35(b), ultraviolet rays are directed obliquely in the direction represented by the arrows. As a result of this exposure step, as shown in FIG. 35(c), the remaining part of the optical alignment film, namely, the part thereof corresponding to the bottom half of the red picture element R, the green picture element G and the blue picture element B and the top half of the yellow picture element Y, the cyan picture element C and the magenta picture element M is given a prescribed pretilt direction. The pretilt direction given at this point is the same as the pretilt direction PB1 shown in FIG. 2(b) and is antiparallel to the pretilt direction shown in FIG. 34(c).

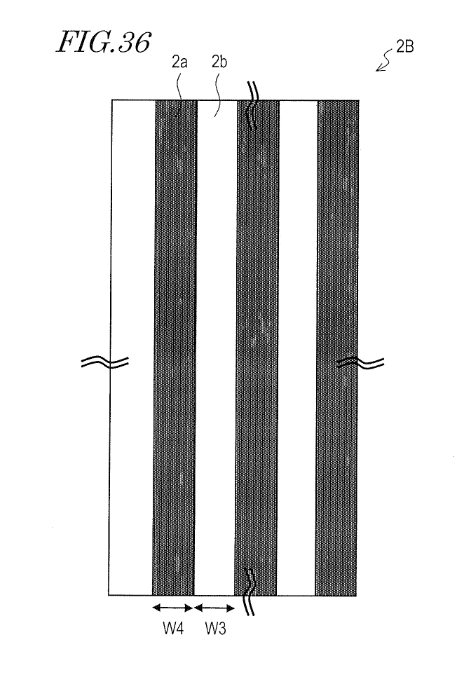

As a result of the above-described optical alignment processing, in an area of the optical alignment film of the CF substrate corresponding to each picture element, two areas having pretilt directions antiparallel to each other are formed. Now, with reference to FIG. 36 through FIG. 38, the optical alignment processing on an optical alignment film of a TFT substrate will be described.

First, a photomask 2B shown in FIG. 36 is prepared. As shown in FIG. 36, the photomask 2B includes a plurality of light shielding parts 2a extending like stripes in the column direction (vertical direction) and a plurality of light transmitting parts 2b located between the plurality of light shielding parts 2a. A width W3 of each of the plurality of light transmitting parts 2b (width in the row direction) is half of the length L3 of the sides of each picture element which are parallel to the row direction (i.e., W3=L3/2). A width W4 of each of the plurality of light shielding parts 2a (width in the row direction) is also half of the length L3 of the sides of each picture element which are parallel to the row direction (i.e., W4=L3/2; W3+W4=L3).

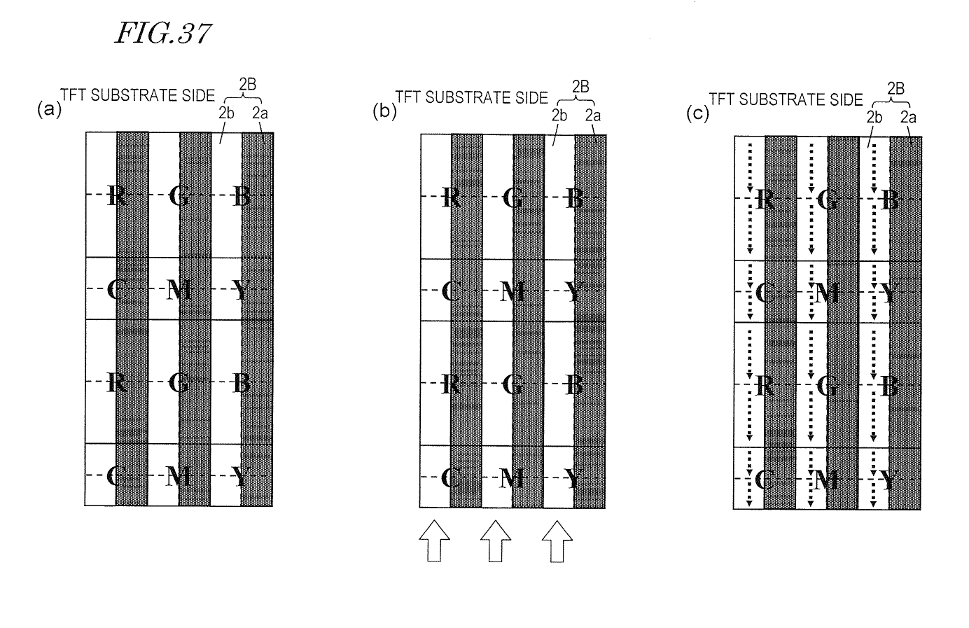

Next, as shown in FIG. 37(a), the photomask 2B is located such that a part of the optical alignment film corresponding to a left half of the picture elements overlaps the light transmitting part 2b (i.e., such that a part of the optical alignment film corresponding to a right half of the picture elements overlaps the light shielding part 2a).

Next, as shown in FIG. 37(b), ultraviolet rays are directed obliquely in the direction represented by the arrows. As a result of this exposure step, as shown in FIG. 37(c), the part of the optical alignment film corresponding to the left half of the picture elements is given a prescribed pretilt direction. The pretilt direction given at this point is the same as the pretilt direction PA1 shown in FIG. 2(a).

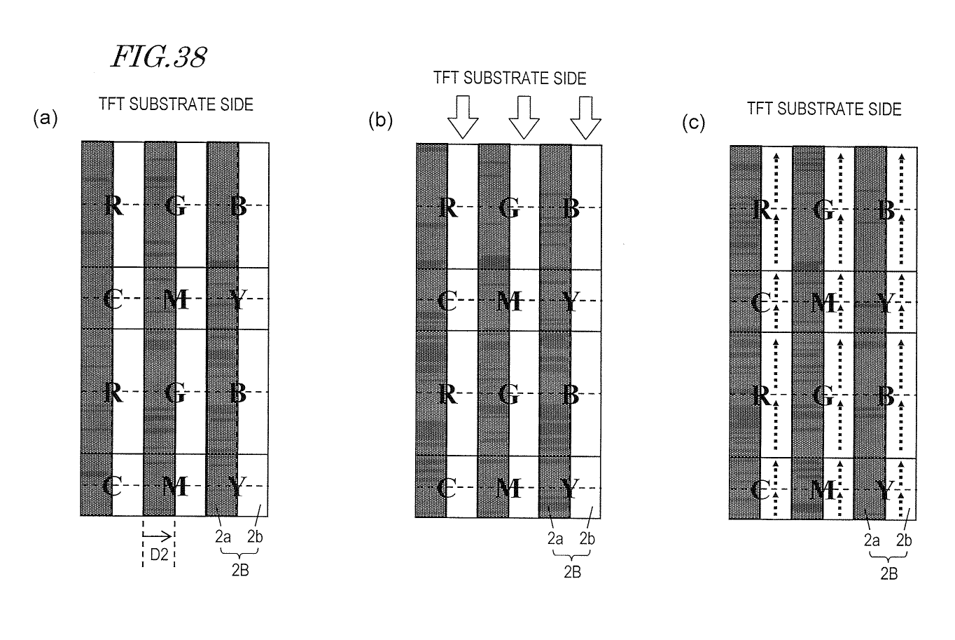

Next, as shown in FIG. 38(a), the photomask 2B is shifted in the row direction by a prescribed distance D2. In this example, the prescribed distance D2 is ⅙ of a width PW2 (see FIG. 32) of the pixel P in the row direction, and is half (½) of the length L3 of the sides of each picture element which are parallel to the row direction. As a result of this movement, the part of the optical alignment film corresponding to the right half of the picture elements overlaps the light transmitting part 2b of the photomask 2B. Namely, the part of the optical alignment film corresponding to the left half of the picture elements overlaps the light shielding part 2a of the photomask 2B.

Next, as shown in FIG. 38(b), ultraviolet rays are directed obliquely in the direction represented by the arrows. As a result of this exposure step, as shown in FIG. 38(c), the remaining part of the optical alignment film, namely, the part thereof corresponding to the right half of the picture elements is given a prescribed pretilt direction. The pretilt direction given at this point is the same as the pretilt direction PA2 shown in FIG. 2(a) and is antiparallel to the pretilt direction shown in FIG. 37(c).

As a result of the above-described optical alignment processing, in an area of the optical alignment film of the TFT substrate corresponding to each picture element, two areas having pretilt directions antiparallel to each other are formed. By bringing together the TFT substrate and the CF substrate processed with the optical alignment in the above-described manner, the liquid crystal display device 300 shown in FIG. 32 in which each picture element is divided into liquid crystal domains having different alignment directions is obtained.

In the production method of the liquid crystal display device 300, in the step of performing the optical alignment processing on the optical alignment film of the CF substrate, two exposure steps are performed by use of one, common photomask 1B. In the step of performing the optical alignment processing on the optical alignment film of the TFT substrate, two exposure steps are performed by use of one, common photomask 2B. Namely, the shifted exposure can be performed in the column direction in which there are two widths of the picture elements in addition to the row direction in which there is one width of the picture elements. Therefore, the optical alignment processing can be realized at low cost and in a short takt time. As can be seen from the above, in the liquid crystal display device 300 in this embodiment also, because one pixel P includes picture elements having different arrangement patterns of the liquid crystal domains D1 through D4 (having different shapes of the dark area DR), increase of the cost and time required for the optical alignment processing can be suppressed.

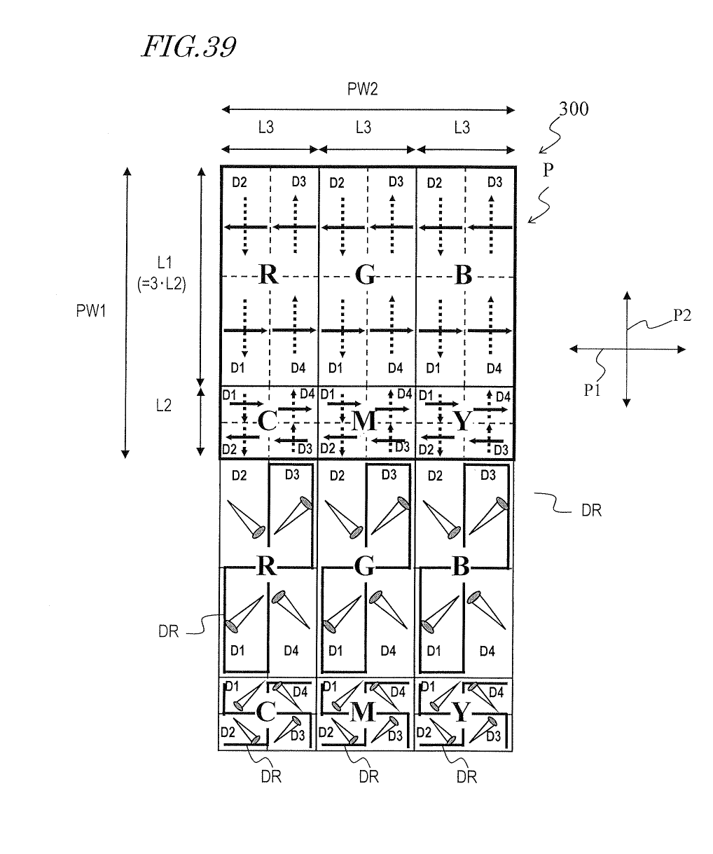

In the example shown in FIG. 32, the length L1 of the sides of the red picture element R, the green picture element G and the blue picture element B which are parallel to the column direction is twice the length L2 of the sides of the yellow picture element Y, the cyan picture element C and the magenta picture element M which are parallel to the column direction (i.e., L1=2·L2). The relationship between the length L1 and the length L2 is not limited to this. For example, as shown in FIG. 39, the length L1 may be three times the length L2 (i.e., L1=3·L2). In this case, the width W1 of the light transmitting part 1b of the photomask 1B is equal to twice the length L2 (i.e., W1=(L1+L2)/2=2·L2). The width W2 of the light shielding part 1a is also equal to twice the length L2 (i.e., W2=(L1+L2)/2=2·L2; W1+W2=L1+L2=4·L2).

### Embodiment 4

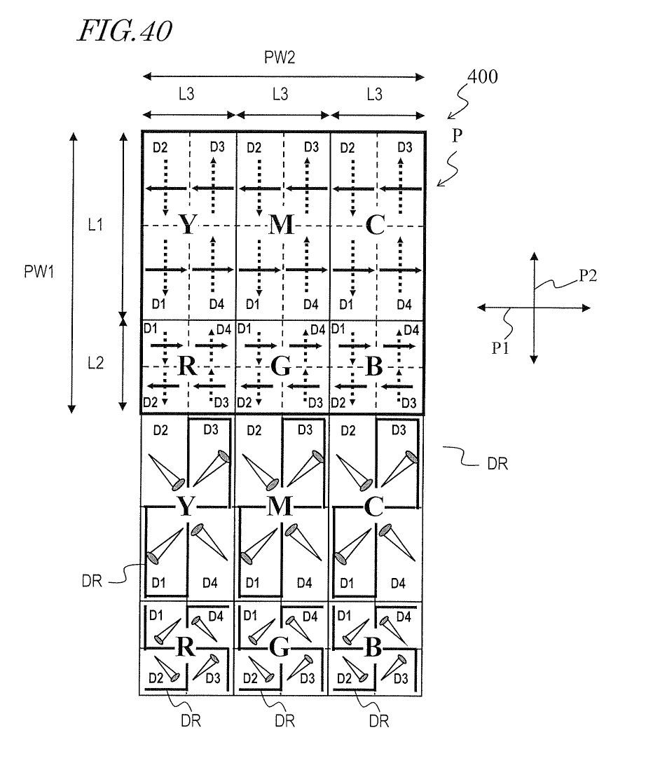

FIG. 40 shows a liquid crystal display device 400 in this embodiment. FIG. 40 is a plan view schematically showing two pixels P of the liquid crystal display device 400.

As shown in FIG. 40, each pixel P of the liquid crystal display device 400 includes a red picture element R, a green picture element G, a blue picture element B, a yellow picture element Y, a cyan picture element C and a magenta picture element M. Accordingly, the liquid crystal display device 400 provides display by use of six primary colors like the liquid crystal display device 300 in Embodiment 3.

In the liquid crystal display device 300 in Embodiment 3, the size of the red picture element R, the green picture element G and the blue picture element B is larger than the size of the yellow picture element Y, the cyan picture element C and the magenta picture element M; whereas in the liquid crystal display device 400 in this embodiment, the size of the yellow picture element Y, the cyan picture element C and the magenta picture element M is larger than the size of the red picture element R, the green picture element G and the blue picture element B. As shown in FIG. 40, a length L1 of the sides of the yellow picture element Y, the cyan picture element C and the magenta picture element M which are parallel to the column direction is larger than a length L2 of the sides of the red picture element R, the green picture element G and the blue picture element B which are parallel to the column direction (i.e., L1>L2). The sides of all the picture elements which are parallel to the row direction have an equal length L3.

In each of the yellow picture element Y, the cyan picture element C and the magenta picture element M, the liquid crystal domains D1 through D4 are located in the order of bottom left, top left, top right and bottom right (i.e., clockwise from bottom left). Therefore, the dark area DR appearing in each of the yellow picture element Y, the cyan picture element C and the magenta picture element M is generally shaped like the letter “8”. By contrast, in each of the red picture element R, the green picture element G and the blue picture element B, the liquid crystal domains D1 through D4 are located in the order of top left, bottom left, bottom right and top right (i.e., counterclockwise from top left). Therefore, the dark area DR appearing in each of the red picture element R, the green picture element G and the blue picture element B is generally gammadion-shaped.

As described above, in the liquid crystal display device 400 in this embodiment, the arrangement pattern of the liquid crystal domains D1 through D4 in the red picture element R, the green picture element G and the blue picture element B is different from that in the yellow picture element Y, the cyan picture element C and the magenta picture element M. Since one pixel P includes picture elements having different arrangement patterns of the liquid crystal domains D1 through D4 (having different shapes of the dark area DR), the shifted exposure can be performed in the column direction in addition to the row direction in which there is one width of the picture elements. Hereinafter, the optical alignment processing on a pair of optical alignment films included in the liquid crystal display device 400 will be described.

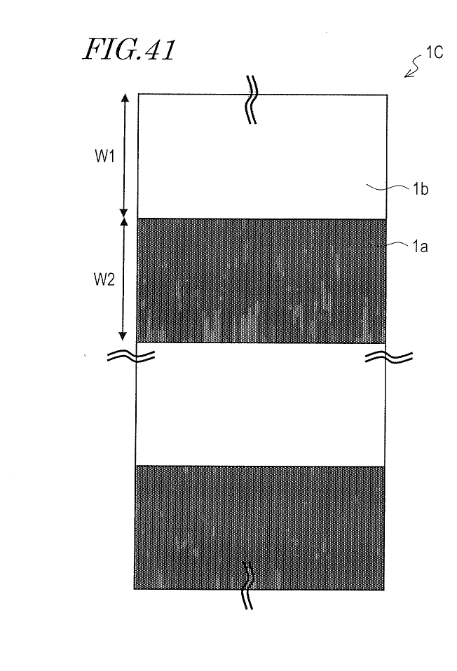

First, with reference to FIG. 41 through FIG. 43, the optical alignment processing on an optical alignment film of a CF substrate will be described.

First, a photomask 1C shown in FIG. 41 is prepared. As shown in FIG. 41, the photomask 1C includes a plurality of light shielding parts 1a extending like stripes in the row direction (horizontal direction) and a plurality of light transmitting parts 1b located between the plurality of light shielding parts 1a. A width W1 of each of the plurality of light transmitting parts 1b (width in the column direction) is equal to a sum of half of the length L1 of the sides of the yellow picture element Y, the cyan picture element C and the magenta picture element M which are parallel to the column direction and half of the length L2 of the sides of the red picture element R, the green picture element G and the blue picture element B which are parallel to the column direction (i.e., W1=(L1+L2)/2). A width W2 of each of the plurality of light shielding parts 1a (width in the column direction) is also equal to a sum of half of the length L1 of the sides of the yellow picture element Y, the cyan picture element C and the magenta picture element M which are parallel to the column direction and half of the length L2 of the sides of the red picture element R, the green picture element G and the blue picture element B which are parallel to the column direction (i.e., W2=(L1+L2)/2; W1+W2=L1+L2).

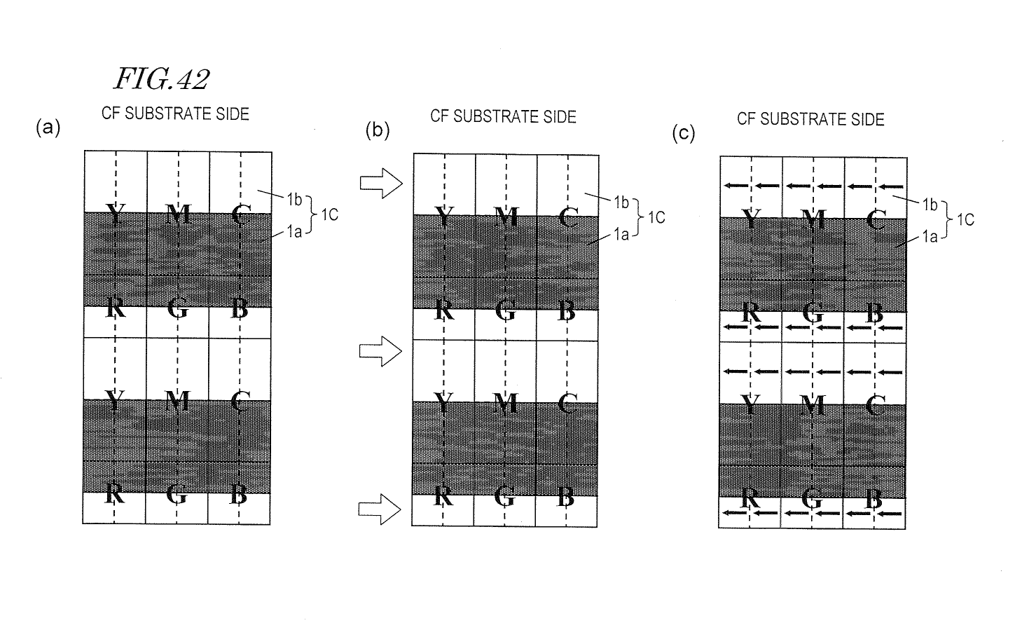

Next, as shown in FIG. 42(a), the photomask 1C is located such that a part of the optical alignment film corresponding to a top half of the yellow picture element Y, the cyan picture element C and the magenta picture element M and a bottom half of the red picture element R, the green picture element G and the blue picture element B overlaps the light transmitting part 1b (i.e., such that a part of the optical alignment film corresponding to a bottom half of the yellow picture element Y, the cyan picture element C and the magenta picture element M and a top half of the red picture element R, the green picture element G and the blue picture element B overlaps the light shielding part 1a).

Next, as shown in FIG. 42(b), ultraviolet rays are directed obliquely in the direction represented by the arrows. As a result of this exposure step, as shown in FIG. 42(c), the part of the optical alignment film corresponding to the top half of the yellow picture element Y, the cyan picture element C and the magenta picture element M and the bottom half of the red picture element R, the green picture element G and the blue picture element B is given a prescribed pretilt direction. The pretilt direction given at this point is the same as the pretilt direction PB2 shown in FIG. 2(b).

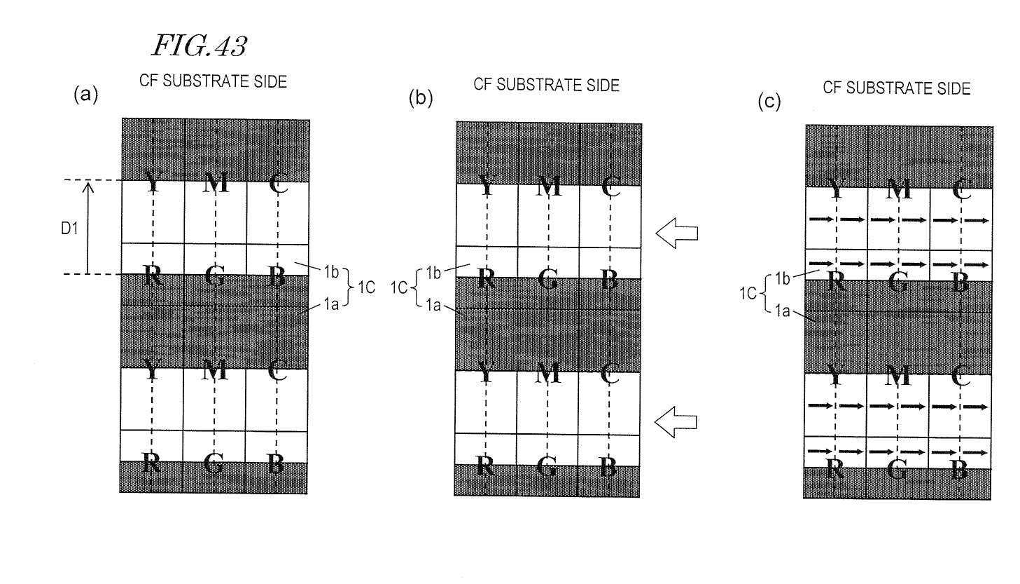

Next, as shown in FIG. 43(a), the photomask 1C is shifted in the column direction by a prescribed distance D1. In this example, the prescribed distance D1 is half (½) of a width PW1 (see FIG. 40) of the pixel P in the column direction. As a result of this movement, the part of the optical alignment film corresponding to the bottom half of the yellow picture element Y, the cyan picture element C and the magenta picture element M and the top half of the red picture element R, the green picture element G and the blue picture element B overlaps the light transmitting part 1b of the photomask 1C. Namely, the part of the optical alignment film corresponding to the top half of the yellow picture element Y, the cyan picture element C and the magenta picture element M and the bottom half of the red picture element R, the green picture element G and the blue picture element B overlaps the light shielding part 1a of the photomask 1C.

Next, as shown in FIG. 43(b), ultraviolet rays are directed obliquely in the direction represented by the arrows. As a result of this exposure step, as shown in FIG. 43(c), the remaining part of the optical alignment film, namely, the part thereof corresponding to the bottom half of the yellow picture element Y, the cyan picture element C and the magenta picture element M and the top half of the red picture element R, the green picture element G and the blue picture element B is given a prescribed pretilt direction. The pretilt direction given at this point is the same as the pretilt direction PB1 shown in FIG. 2(b) and is antiparallel to the pretilt direction shown in FIG. 42(c).

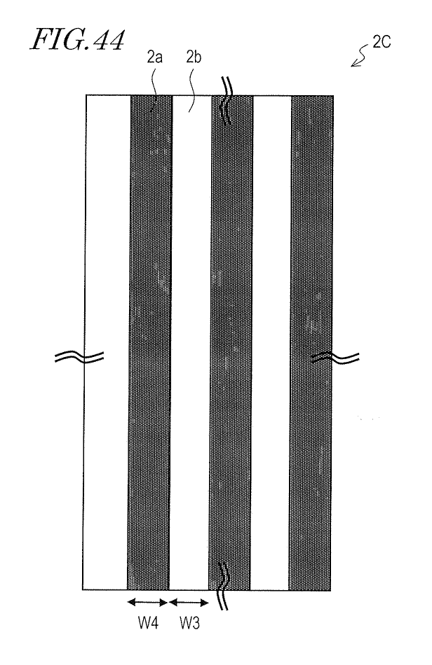

As a result of the above-described optical alignment processing, in an area of the optical alignment film of the CF substrate corresponding to each picture element, two areas having pretilt directions antiparallel to each other are formed. Now, with reference to FIG. 44 through FIG. 46, the optical alignment processing on an optical alignment film of a TFT substrate will be described.

First, a photomask 2C shown in FIG. 44 is prepared. As shown in FIG. 44, the photomask 2C includes a plurality of light shielding parts 2a extending like stripes in the column direction (vertical direction) and a plurality of light transmitting parts 2b located between the plurality of light shielding parts 2a. A width W3 of each of the plurality of light transmitting parts 2b (width in the row direction) is half of the length L3 of the sides of each picture element which are parallel to the row direction (i.e., W3=L3/2). A width W4 of each of the plurality of light shielding parts 2a (width in the row direction) is also half of the length L3 of the sides of each picture element which are parallel to the row direction (i.e., W4=L3/2; W3+W4=L3).

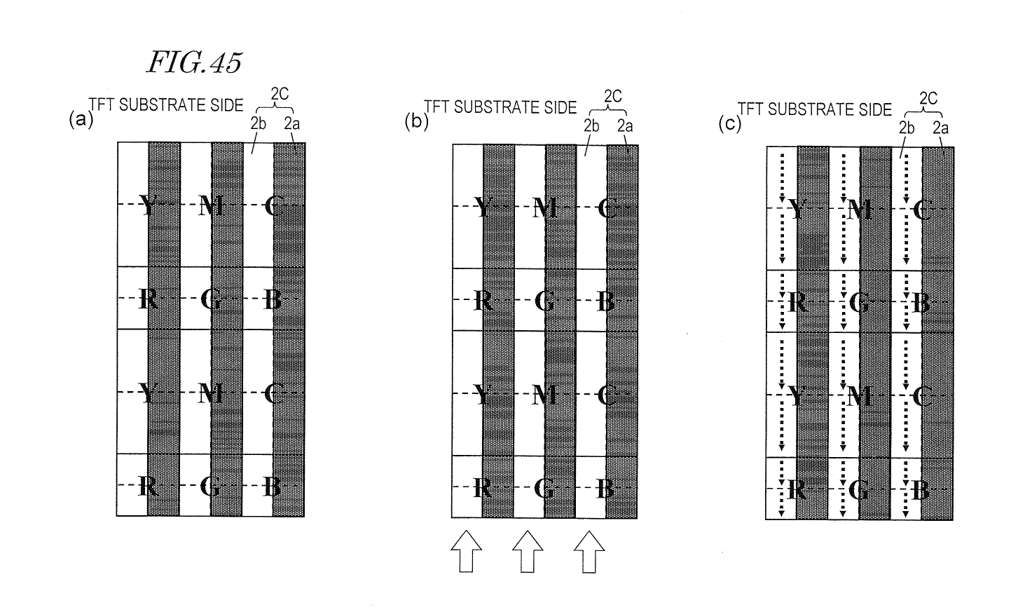

Next, as shown in FIG. 45(a), the photomask 2C is located such that a part of the optical alignment film corresponding to a left half of the picture elements overlaps the light transmitting part 2b (i.e., such that a part of the optical alignment film corresponding to a right half of the picture elements overlaps the light shielding part 2a).

Next, as shown in FIG. 45(b), ultraviolet rays are directed obliquely in the direction represented by the arrows. As a result of this exposure step, as shown in FIG. 45(c), the part of the optical alignment film corresponding to the left half of the picture elements is given a prescribed pretilt direction. The pretilt direction given at this point is the same as the pretilt direction PA1 shown in FIG. 2(a).

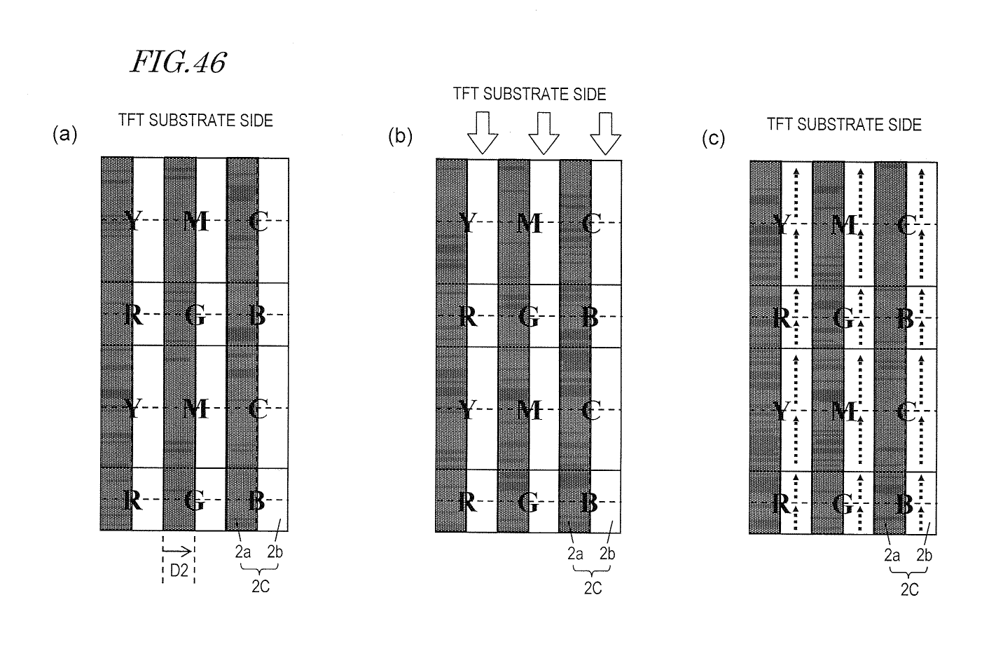

Next, as shown in FIG. 46(a), the photomask 2C is shifted in the row direction by a prescribed distance D2. In this example, the prescribed distance D2 is ⅙ of a width PW2 (see FIG. 40) of the pixel P in the row direction, and is half (½) of the length L3 of the sides of each picture element which are parallel to the row direction. As a result of this movement, the part of the optical alignment film corresponding to the right half of the picture elements overlaps the light transmitting part 2b of the photomask 2C. Namely, the part of the optical alignment film corresponding to the left half of the picture elements overlaps the light shielding part 2a of the photomask 2C.

Next, as shown in FIG. 46(b), ultraviolet rays are directed obliquely in the direction represented by the arrows. As a result of this exposure step, as shown in FIG. 46(c), the remaining part of the optical alignment film, namely, the part thereof corresponding to the right half of the picture elements is given a prescribed pretilt direction.

The pretilt direction given at this point is the same as the pretilt direction PA2 shown in FIG. 2(a) and is antiparallel to the pretilt direction shown in FIG. 45(c).

As a result of the above-described optical alignment processing, in an area of the optical alignment film of the TFT substrate corresponding to each picture element, two areas having pretilt directions antiparallel to each other are formed. By bringing together the TFT substrate and the CF substrate processed with the optical alignment in the above-described manner, the liquid crystal display device 400 shown in FIG. 40 in which each picture element is divided into liquid crystal domains having different alignment directions is obtained.

In the production method of the liquid crystal display device 400, in the step of performing the optical alignment processing on the optical alignment film of the CF substrate, two exposure steps are performed by use of one, common photomask 1C. In the step of performing the optical alignment processing on the optical alignment film of the TFT substrate, two exposure steps are performed by use of one, common photomask 2C. Namely, the shifted exposure can be performed in the column direction in which there are two widths of the picture elements in addition to the row direction in which there is one width of the picture elements. Therefore, the optical alignment processing can be realized at low cost and in a short takt time. As can be seen from the above, in the liquid crystal display device 400 in this embodiment also, because one pixel P includes picture elements having different arrangement patterns of the liquid crystal domains D1 through D4 (having different shapes of the dark area DR), increase of the cost and time required for the optical alignment processing can be suppressed.

### Embodiment 5

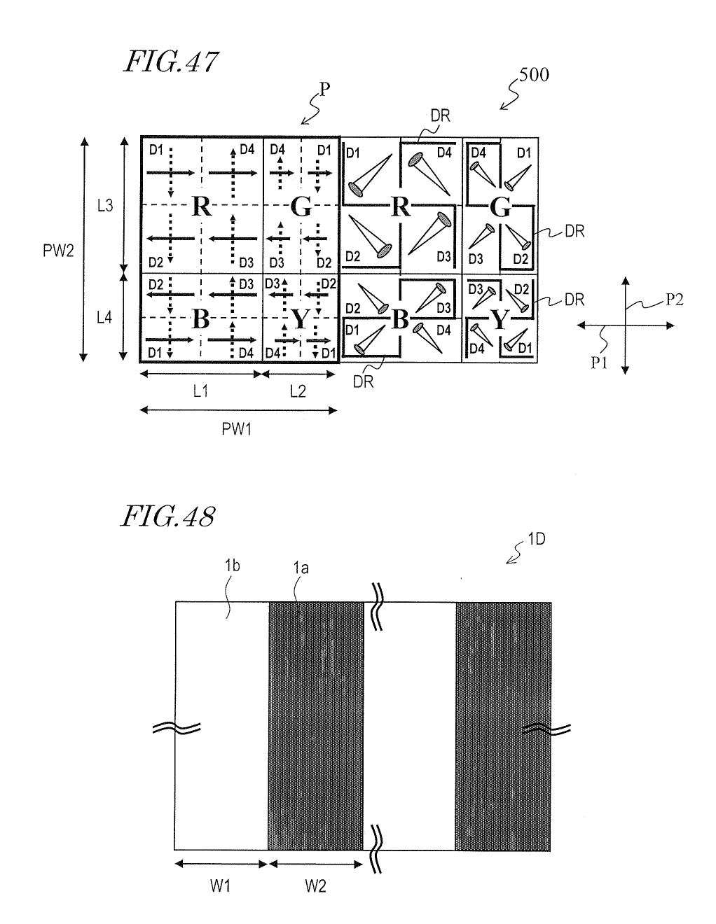

FIG. 47 shows a liquid crystal display device 500 in this embodiment. FIG. 47 is a plan view schematically showing two pixels P of the liquid crystal display device 500.

As shown in FIG. 47, each pixel P of the liquid crystal display device 500 includes a red picture element R, a green picture element G, a blue picture element B and a yellow picture element Y. The red picture element R, the green picture element G, the blue picture element B and the yellow picture element Y are arranged in a matrix of 2 rows×2 columns in the pixel P.

A length L1 of the sides of the red picture element R and the blue picture element B which are parallel to the row direction is different from a length L2 of the sides of the green picture element G and the yellow picture element Y which are parallel to the row direction. Specifically, the length L1 is longer than the length L2 (i.e., L1>L2). A length L3 of the sides of the red picture element R and the green picture element G which are parallel to the column direction is different from a length L4 of the sides of the blue picture element B and the yellow picture element Y which are parallel to the column direction. Specifically, the length L3 is longer than the length L4 (i.e., L3>L4). As can be seen from the above, in the liquid crystal display device 500 in this embodiment, there are two widths of the picture elements in the row direction, and there are two widths of the picture elements also in the column direction.

In the red picture element R, the liquid crystal domains D1 through D4 are located in the order of top left, bottom left, bottom right and top right (i.e., counterclockwise from top left). Therefore, the dark area DR appearing in the red picture element R is generally gammadion-shaped, and more specifically, is right gammadion-shaped.

In the blue picture element B, the liquid crystal domains D1 through D4 are located in the order of bottom left, top left, top right and bottom right (i.e., clockwise from bottom left). Therefore, the dark area DR appearing in the blue picture element B is generally shaped like the letter “8”, and more specifically, is shaped like the letter “8” inclined rightward from the vertical direction (rotated clockwise).

In the green picture element G, the liquid crystal domains D1 through D4 are located in the order of top right, bottom right, bottom left and top left (i.e., clockwise from top right). Therefore, the dark area DR appearing in the green picture element G is generally shaped like the letter “8”, and more specifically, is shaped like the letter “8” inclined leftward from the vertical direction (rotated counterclockwise).

In the yellow picture element Y, the liquid crystal domains D1 through D4 are located in the order of bottom right, top right, top left and bottom left (i.e., counterclockwise from bottom right). Therefore, the dark area DR appearing in the yellow picture element Y is generally gammadion-shaped, and more specifically, is left gammadion-shaped.

As described above, in the liquid crystal display device 500 in this embodiment, the arrangement pattern of the liquid crystal domains D1 through D4 is different among in the red picture element R, the blue picture element B, the green picture element G and the yellow picture element Y. In the liquid crystal display device 500, there are two widths of the picture elements in both of the row direction and the column direction. Since one pixel P includes four arrangement patterns as described above, the shifted exposure can be performed in the row direction and the column direction. Hereinafter, the optical alignment processing on a pair of optical alignment films included in the liquid crystal display device 500 will be described.

First, with reference to FIG. 48 through FIG. 50, the optical alignment processing on an optical alignment film of a TFT substrate will be described.

First, a photomask 1D shown in FIG. 48 is prepared. As shown in FIG. 48, the photomask 1D includes a plurality of light shielding parts 1a extending like stripes in the column direction (vertical direction) and a plurality of light transmitting parts 1b located between the plurality of light shielding parts 1a. A width W1 of each of the plurality of light transmitting parts 1b (width in the row direction) is equal to a sum of half of the length L1 of the sides of the red picture element R and the blue picture element B which are parallel to the row direction and half of the length L2 of the sides of the green picture element G and the yellow picture element Y which are parallel to the row direction (i.e., W1=(L1+L2)/2). A width W2 of each of the plurality of light shielding parts 1a (width in the row direction) is also equal to a sum of half of the length L1 of the sides of the red picture element R and the blue picture element B which are parallel to the row direction and half of the length L2 of the sides of the green picture element G and the yellow picture element Y which are parallel to the row direction (i.e., W2=(L1+L2)/2; W1+W2=L1+L2).

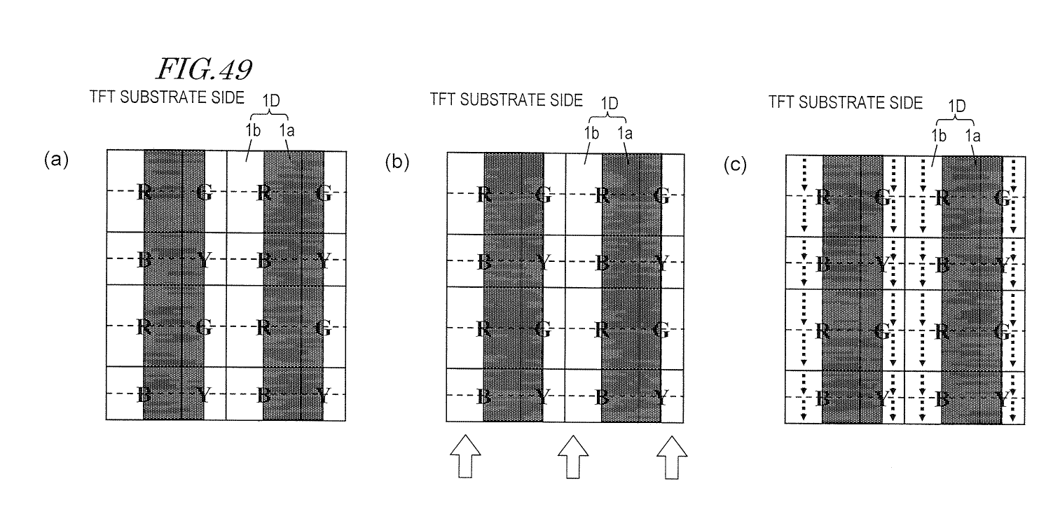

Next, as shown in FIG. 49(a), the photomask 1D is located such that a part of the optical alignment film corresponding to a left half of the red picture elements R and the blue picture elements B and a right half of the green picture elements G and the yellow picture elements Y overlaps the light transmitting part 1b (i.e., such that a part of the optical alignment film corresponding to a right half of the red picture elements R and the blue picture elements B and a left half of the green picture elements G and the yellow picture elements Y overlaps the light shielding part 1a).

Next, as shown in FIG. 49(b), ultraviolet rays are directed obliquely in the direction represented by the arrows. As a result of this exposure step, as shown in FIG. 49(c), the part of the optical alignment film corresponding to the left half of the red picture elements R and the blue picture elements B and the right half of the green picture elements G and the yellow picture elements Y is given a prescribed pretilt direction. The pretilt direction given at this point is the same as the pretilt direction PA1 shown in FIG. 2(a).

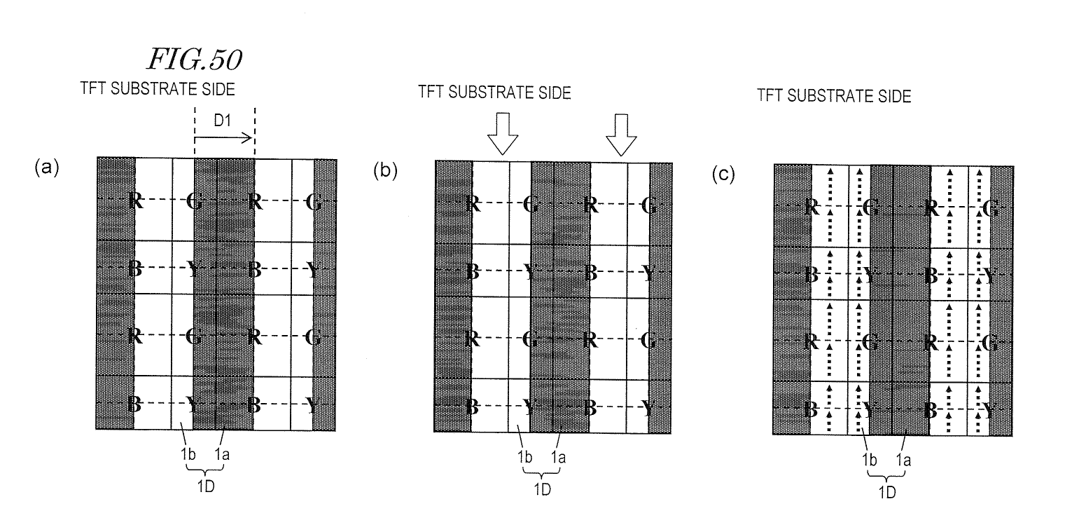

Next, as shown in FIG. 50(a), the photomask 1D is shifted in the row direction by a prescribed distance D1. In this example, the prescribed distance D1 is half (½) of a width PW1 (see FIG. 47) of the pixel P in the row direction. As a result of this movement, the part of the optical alignment film corresponding to the right half of the red picture elements R and the blue picture elements B and the left half of the green picture elements G and the yellow picture elements Y overlaps the light transmitting part 1b of the photomask 1D. Namely, the part of the optical alignment film corresponding to the left half of the red picture elements R and the blue picture elements B and the right half of the green picture elements G and the yellow picture elements Y overlaps the light shielding part 1a of the photomask 1D.

Next, as shown in FIG. 50(b), ultraviolet rays are directed obliquely in the direction represented by the arrows. As a result of this exposure step, as shown in FIG. 50(c), the remaining part of the optical alignment film, namely, the part thereof corresponding to the right half of the red picture elements R and the blue picture elements B and the left half of the green picture elements G and the yellow picture elements Y is given a prescribed pretilt direction. The pretilt direction given at this point is the same as the pretilt direction PA2 shown in FIG. 2(a) and is antiparallel to the pretilt direction shown in FIG. 49(c).

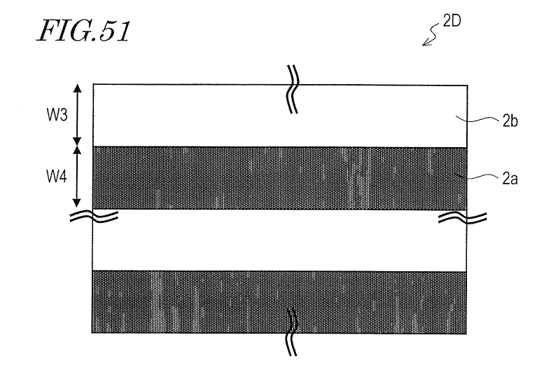

As a result of the above-described optical alignment processing, in an area of the optical alignment film of the TFT substrate corresponding to each picture element, two areas having pretilt directions antiparallel to each other are formed. Now, with reference to FIG. 51 through FIG. 53, the optical alignment processing on an optical alignment film of a CF substrate will be described.

First, a photomask 2D shown in FIG. 51 is prepared. As shown in FIG. 51, the photomask 2D includes a plurality of light shielding parts 2a extending like stripes in the row direction (horizontal direction) and a plurality of light transmitting parts 2b located between the plurality of light shielding parts 2a. A width W3 of each of the plurality of light transmitting parts 2b (width in the column direction) is equal to a sum of half of the length L3 of the sides of the red picture element R and the green picture element G which are parallel to the column direction and half of the length L4 of the sides of the blue picture element B and the yellow picture element Y which are parallel to the column direction (i.e., W3=(L3+L4)/2). A width W4 of each of the plurality of light shielding parts 2a (width in the column direction) is also equal to a sum of half of the length L3 of the sides of the red picture element R and the green picture element G which are parallel to the column direction and half of the length L4 of the sides of the blue picture element B and the yellow picture element Y which are parallel to the column direction (i.e., W4=(L3+L4)/2; W3+W4=L3+L4).

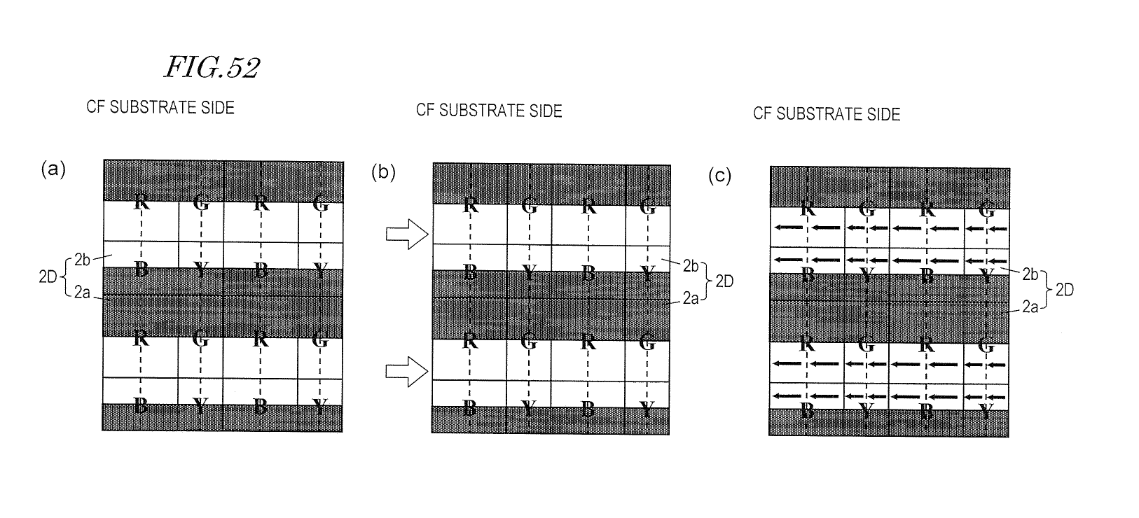

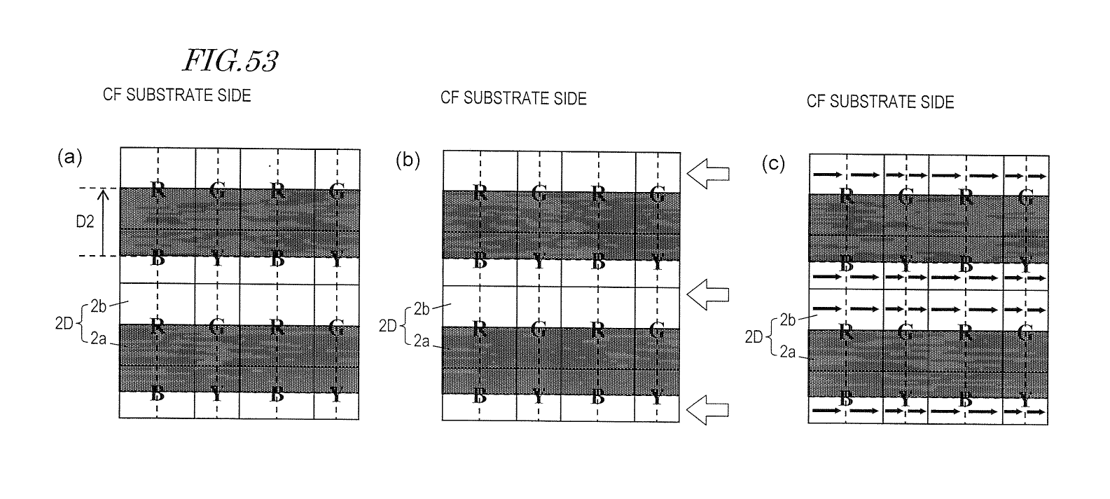

Next, as shown in FIG. 52(a), the photomask 2D is located such that a part of the optical alignment film corresponding to a bottom half of the red picture elements R and the green picture elements G and a top half of the blue picture elements B and the yellow picture elements Y overlaps the light transmitting part 2b (i.e., such that a part of the optical alignment film corresponding to a top half of the red picture elements R and the green picture elements G and a bottom half of the blue picture elements B and the yellow picture elements Y overlaps the light shielding part 2a).

Next, as shown in FIG. 52(b), ultraviolet rays are directed obliquely in the direction represented by the arrows. As a result of this exposure step, as shown in FIG. 52(c), the part of the optical alignment film corresponding to the bottom half of the red picture elements R and the green picture elements G and the top half of the blue picture elements B and the yellow picture elements Y is given a prescribed pretilt direction. The pretilt direction given at this point is the same as the pretilt direction PB2 shown in FIG. 2(b).

Next, as shown in FIG. 53(a), the photomask 2D is shifted in the column direction by a prescribed distance D2. In this example, the prescribed distance D2 is half (½) of a width PW2 (see FIG. 47) of the pixel P in the column direction. As a result of this movement, the part of the optical alignment film corresponding to the top half of the red picture elements R and the green picture elements G and the bottom half of the blue picture elements B and the yellow picture elements Y overlaps the light transmitting part 2b of the photomask 2D. Namely, the part of the optical alignment film corresponding to the bottom half of the red picture elements R and the green picture elements G and the top half of the blue picture elements B and the yellow picture elements Y overlaps the light shielding part 2a of the photomask 2D.

Next, as shown in FIG. 53(b), ultraviolet rays are directed obliquely in the direction represented by the arrows. As a result of this exposure step, as shown in FIG. 53(c), the remaining part of the optical alignment film, namely, the part thereof corresponding to the top half of the red picture elements R and the green picture elements G and the bottom half of the blue picture elements B and the yellow picture elements Y is given a prescribed pretilt direction. The pretilt direction given at this point is the same as the pretilt direction PB1 shown in FIG. 2(b) and is antiparallel to the pretilt direction shown in FIG. 52(c).

As a result of the above-described optical alignment processing, in an area of the optical alignment film of the CF substrate corresponding to each picture element, two areas having pretilt directions antiparallel to each other are formed. By bringing together the TFT substrate and the CF substrate processed with the optical alignment in the above-described manner, the liquid crystal display device 500 shown in FIG. 47 in which each picture element is divided into liquid crystal domains having different alignment directions is obtained.

In the production method of the liquid crystal display device 500, in the step of performing the optical alignment processing on the optical alignment film of the TFT substrate, two exposure steps are performed by use of one, common photomask 1D. In the step of performing the optical alignment processing on the optical alignment film of the CF substrate, two exposure steps are performed by use of one, common photomask 2D. Namely, the shifted exposure can be performed in both of the row direction and the column direction in which there are two widths of the picture elements. As can be seen from the above, in the liquid crystal display device 500 in this embodiment, because one pixel P includes four arrangement patterns of the liquid crystal domains D1 through D4, increase of the cost and time required for the optical alignment processing can be suppressed although there are two widths of the picture elements in both of the row direction and the column direction.

In this embodiment, there are two widths of the picture elements in the row direction and also in the column direction. The moving distance D2 of the photomask 2D in the column direction is about 1/n of the width PW2 of the pixel P in the column direction (n is an even number of 2 or greater). n is equal to the number of picture elements (in this example, 2) in the pixel P.

As described above, from the viewpoint of reliability it is preferable that as a result of the optical alignment processing on an optical alignment film, a double-exposed area DE is formed than an unexposed area is formed. Accordingly, as described above with reference to FIG. 22 and the like, it is preferable that the width W1 of the light transmitting part 1b of the photomask 1D, the width W2 of the light shielding part 1a of the photomask 1D, the length L1 of the sides of the red picture element R and the blue picture element B which are parallel to the row direction, and the length L2 of the sides of the green picture element G and the yellow picture element Y which are parallel to the row direction fulfill the relationships of W1=(L1+L2)/2+Δ and W2=(L1+L2)/2−Δ. It is preferable that 0<A 10.

The same is true with the column direction. Namely, the width W3 of the light transmitting part 2b of the photomask 2D may be increased by a prescribed increasing amount Δ′ (i.e., W3=(L3+L4)/2+Δ′) and the width W4 of the light shielding part 2a may be decreased by the same amount (i.e., W4=(L3+L4)/2−Δ′). From the viewpoint of suppressing the decrease of the transmittance, it is preferable that the increasing amount Δ′ of the width W3 of the light transmitting part 2b is equal to or smaller than 10 μm (i.e., 0<Δ′≦10). From the viewpoint of further suppressing the decrease of the transmittance and preventing the formation of an unexposed area with more certainty, it is preferable that the increasing amount Δ′ is equal to or larger than 1 μm and equal to or smaller than 5 μm (i.e., 1≦Δ′≦5).

### Embodiment 6

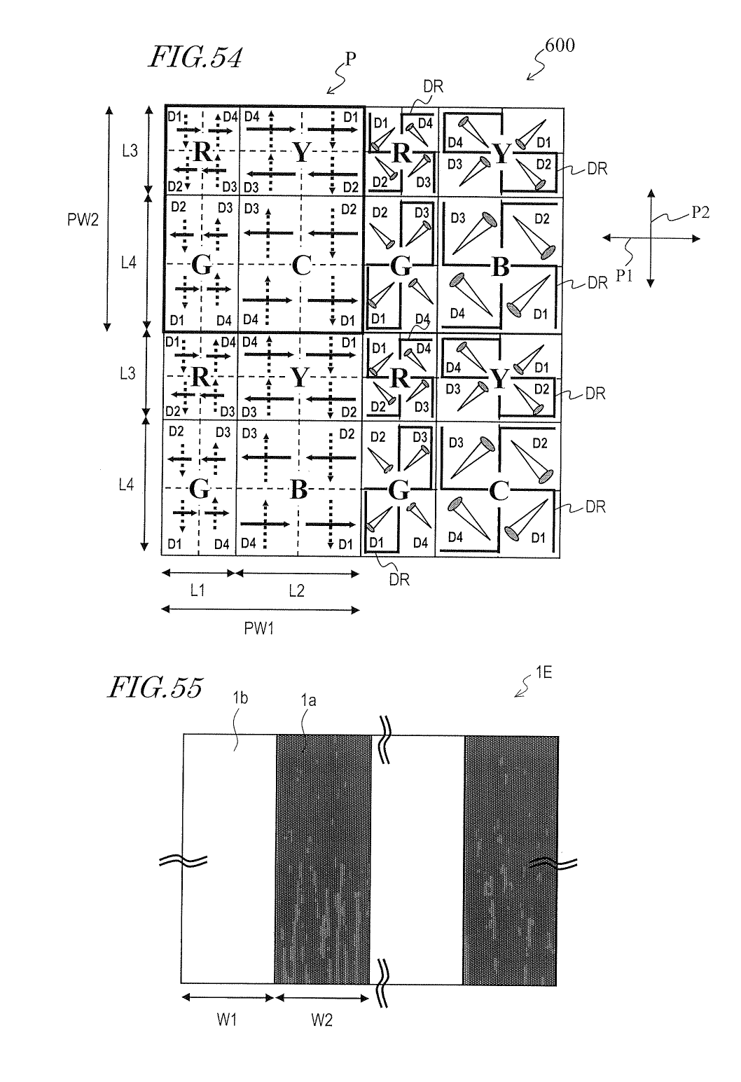

FIG. 54 shows a liquid crystal display device 600 in this embodiment. FIG. 54 is a plan view schematically showing four pixels P of the liquid crystal display device 600.

As shown in FIG. 54, a part of pixels P of the liquid crystal display device 600 (in FIG. 54, the top right pixel P and the bottom left pixel P) each include a red picture element R, a green picture element G, a blue picture element B and a yellow picture element Y. The red picture element R, the green picture element G, the blue picture element B and the yellow picture element Y are arranged in a matrix of 2 rows×2 columns in the pixel P. The remaining pixels P of the liquid crystal display device 600 (in FIG. 54, the bottom right pixel P and the top left pixel P) each include a red picture element R, a green picture element G, a cyan picture element C and a yellow picture element Y (i.e., include the cyan picture element C instead of the blue picture element B). The red picture element R, the green picture element G, the cyan picture element C and the yellow picture element Y are arranged in a matrix of 2 rows×2 columns in the pixel P.

As described above, the plurality of pixels P of the liquid crystal display device 600 include pixels P each defined by the red picture element R, the green picture element G, the blue picture element B and the yellow picture element Y and pixels P each defined by the red picture element R, the green picture element G, the cyan picture element C and the yellow picture element Y. The pixels P each including the blue picture element B and the pixels P each including the cyan picture element C are located alternately in the row direction and also in the column direction. Namely, the pixels P each including the blue picture element B and the pixels P each including the cyan picture element C are located in a checkered pattern.

In each pixel P including the blue picture element B, a length L1 of the sides of the red picture element R and the green picture element G which are parallel to the row direction is different from a length L2 of the sides of the blue picture element B and the yellow picture element Y which are parallel to the row direction. Specifically, the length L1 is shorter than the length L2 (i.e., L1<L2). A length L3 of the sides of the red picture element R and the yellow picture element Y which are parallel to the column direction is different from a length L4 of the sides of the green picture element G and the blue picture element B which are parallel to the column direction. Specifically, the length L3 is shorter than the length L4 (i.e., L3<L4). As can be seen from the above, in the pixel P including the blue picture element B, there are two widths of the picture elements in both of the row direction and the column direction.

In each pixel P including the cyan picture element C, the length L1 of the sides of the red picture element R and the green picture element G which are parallel to the row direction is different from the length L2 of the sides of the cyan picture element C and the yellow picture element Y which are parallel to the row direction. Specifically, the length L1 is shorter than the length L2 (i.e., L1<L2). The length L3 of the sides of the red picture element R and the yellow picture element Y which are parallel to the column direction is different from the length L4 of the sides of the green picture element G and the cyan picture element C which are parallel to the column direction. Specifically, the length L3 is shorter than the length L4 (i.e., L3<L4). As can be seen from the above, in the pixel P including the cyan picture element C also, there are two widths of the picture elements in both of the row direction and the column direction.

In the red picture element R, the liquid crystal domains D1 through D4 are located in the order of top left, bottom left, bottom right and top right (i.e., counterclockwise from top left). Therefore, the dark area DR appearing in the red picture element R is generally gammadion-shaped, and more specifically, is right gammadion-shaped.

In the green picture element G, the liquid crystal domains D1 through D4 are located in the order of bottom left, top left, top right and bottom right (i.e., clockwise from bottom left). Therefore, the dark area DR appearing in the green picture element G is generally shaped like the letter “8”, and more specifically, is shaped like the letter “8” inclined rightward from the vertical direction (rotated clockwise).

In the yellow picture element Y, the liquid crystal domains D1 through D4 are located in the order of top right, bottom right, bottom left and top left (i.e., clockwise from top right). Therefore, the dark area DR appearing in the yellow picture element Y is generally shaped like the letter “8”, and more specifically, is shaped like the letter “8” inclined leftward from the vertical direction (rotated counterclockwise).

In each of the blue picture element B and the cyan picture element C, the liquid crystal domains D1 through D4 are located in the order of bottom right, top right, top left and bottom left (i.e., counterclockwise from bottom right). Therefore, the dark area DR appearing in each of the blue picture element B and the cyan picture element C is generally gammadion-shaped, and more specifically, is left gammadion-shaped.

As described above, in the liquid crystal display device 600 in this embodiment, the pixel P including the blue picture element B and the pixel P including the cyan picture element C each include four arrangement patterns of the liquid crystal domains D1 through D4. Therefore, the shifted exposure can be performed in both of the row direction and the column direction. Hereinafter, the optical alignment processing on a pair of optical alignment films included in the liquid crystal display device 600 will be described.

First, with reference to FIG. 55 through FIG. 57, the optical alignment processing on an optical alignment film of a TFT substrate will be described.

First, a photomask 1E shown in FIG. 55 is prepared. As shown in FIG. 55, the photomask 1E includes a plurality of light shielding parts 1a extending like stripes in the column direction (vertical direction) and a plurality of light transmitting parts 1b located between the plurality of light shielding parts 1a. A width W1 of each of the plurality of light transmitting parts 1b (width in the row direction) is equal to a sum of half of the length L1 of the sides of the red picture element R and the green picture element G which are parallel to the row direction and half of the length L2 of the sides of the blue picture element B, the cyan picture element C and the yellow picture element Y which are parallel to the row direction (i.e., W1=(L1+L2)/2). A width W2 of each of the plurality of light shielding parts 1a (width in the row direction) is also equal to a sum of half of the length L1 of the sides of the red picture element R and the green picture element G which are parallel to the row direction and half of the length L2 of the sides of the blue picture element B, the cyan picture element C and the yellow picture element Y which are parallel to the row direction (i.e., W2=(L1+L2)/2; W1+W2=L1+L2).

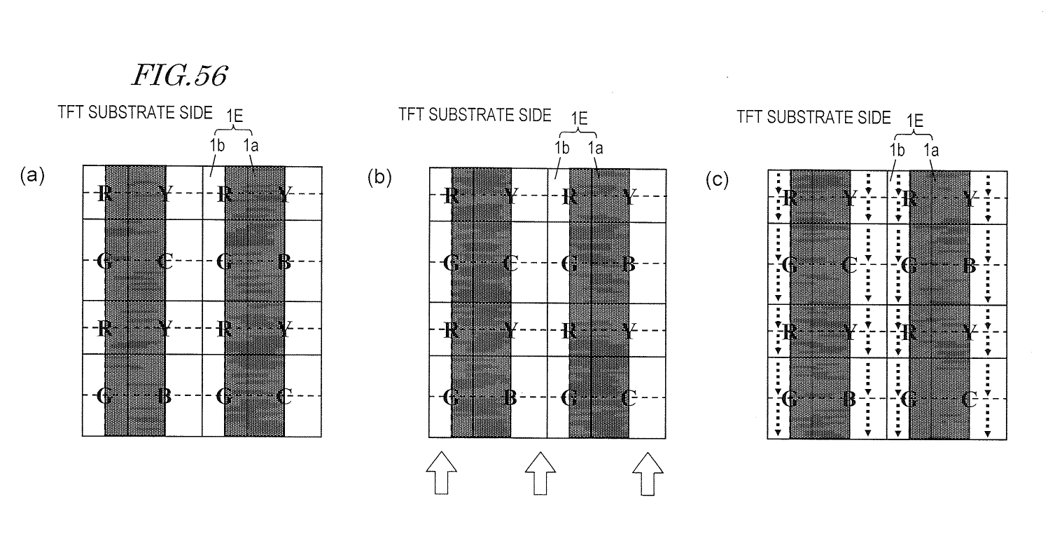

Next, as shown in FIG. 56(a), the photomask 1E is located such that a part of the optical alignment film corresponding to a left half of the red picture elements R and the green picture elements G and a right half of the blue picture element B, the cyan picture element C and the yellow picture elements Y overlaps the light transmitting part 1b (i.e., such that a part of the optical alignment film corresponding to a right half of the red picture elements R and the green picture elements G and a left half of the blue picture element B, the cyan picture element C and the yellow picture elements Y overlaps the light shielding part 1a).

Next, as shown in FIG. 56(b), ultraviolet rays are directed obliquely in the direction represented by the arrows. As a result of this exposure step, as shown in FIG. 56(c), the part of the optical alignment film corresponding to the left half of the red picture elements R and the green picture elements G and the right half of the blue picture element B, the cyan picture element C and the yellow picture elements Y is given a prescribed pretilt direction. The pretilt direction given at this point is the same as the pretilt direction PA1 shown in FIG. 2(a).

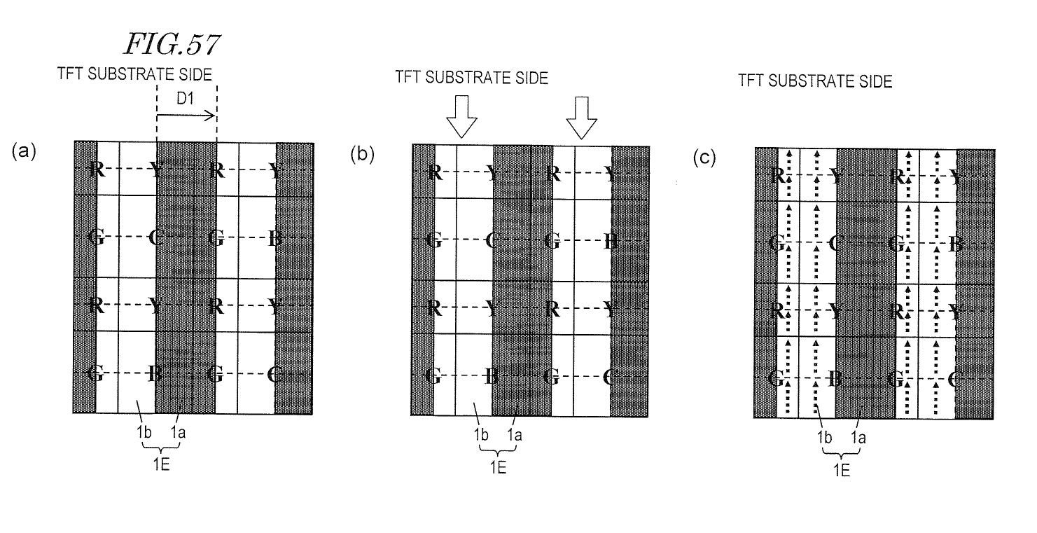

Next, as shown in FIG. 57(a), the photomask E is shifted in the row direction by a prescribed distance D1. In this example, the prescribed distance D1 is half (½) of a width PW1 (see FIG. 54) of the pixel P in the row direction. As a result of this movement, the part of the optical alignment film corresponding to the right half of the red picture elements R and the green picture elements G and the left half of the blue picture element B, the cyan picture element C and the yellow picture elements Y overlaps the light transmitting part 1b of the photomask 1E. Namely, the part of the optical alignment film corresponding to the left half of the red picture elements R and the green picture element G and the right half of the blue picture element B, the cyan picture element C and the yellow picture elements Y overlaps the light shielding part 1a of the photomask 1E.

Next, as shown in FIG. 57(b), ultraviolet rays are directed obliquely in the direction represented by the arrows. As a result of this exposure step, as shown in FIG. 57(c), the remaining part of the optical alignment film, namely, the part thereof corresponding to the right half of the red picture elements R and the green picture elements G and the left half of the blue picture element B, the cyan picture element C and the yellow picture elements Y is given a prescribed pretilt direction. The pretilt direction given at this point is the same as the pretilt direction PA2 shown in FIG. 2(a) and is antiparallel to the pretilt direction shown in FIG. 56(c).

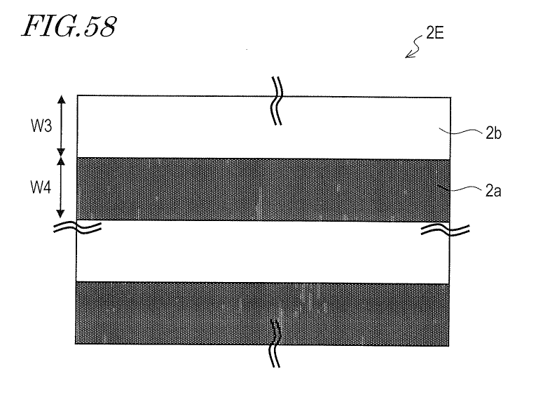

As a result of the above-described optical alignment processing, in an area of the optical alignment film of the TFT substrate corresponding to each picture element, two areas having pretilt directions antiparallel to each other are formed. Now, with reference to FIG. 58 through FIG. 60, the optical alignment processing on an optical alignment film of a CF substrate will be described.

First, a photomask 2E shown in FIG. 58 is prepared. As shown in FIG. 58, the photomask 2E includes a plurality of light shielding parts 2a extending like stripes in the row direction (horizontal direction) and a plurality of light transmitting parts 2b located between the plurality of light shielding parts 2a. A width W3 of each of the plurality of light transmitting parts 2b (width in the column direction) is equal to a sum of half of the length L3 of the sides of the red picture element R and the yellow picture element Y which are parallel to the column direction and half of the length L4 of the sides of the green picture element G, the blue picture element B and the cyan picture element C which are parallel to the column direction (i.e., W3=(L3+L4)/2). A width W4 of each of the plurality of light shielding parts 2a (width in the column direction) is also equal to a sum of half of the length L3 of the sides of the red picture element R and the yellow picture element Y which are parallel to the column direction and half of the length L4 of the sides of the green picture element G, the blue picture element B and the cyan picture element C which are parallel to the column direction (i.e., W4=(L3+L4)/2; W3+W4=L3+L4).

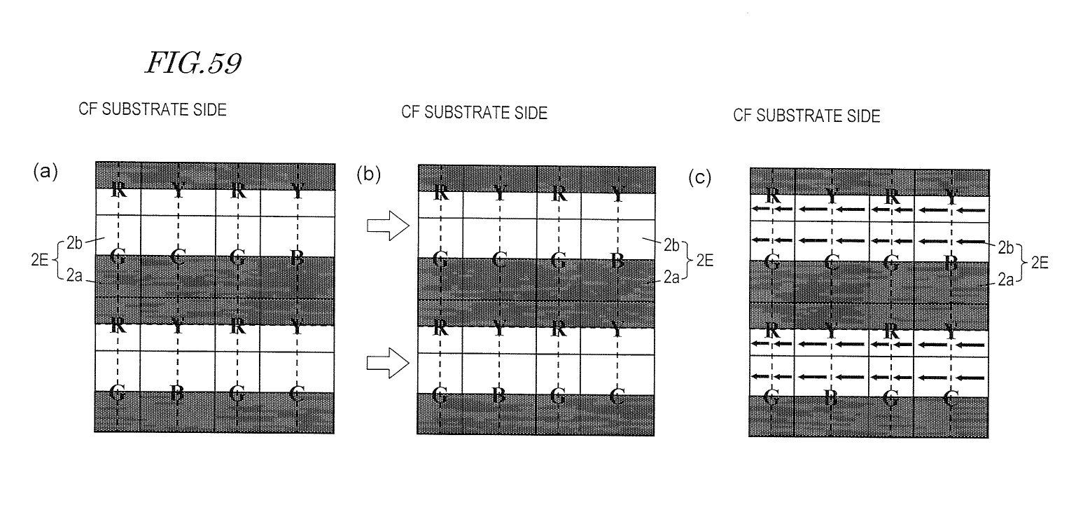

Next, as shown in FIG. 59(a), the photomask 2E is located such that a part of the optical alignment film corresponding to a bottom half of the red picture elements R and the yellow picture elements Y and a top half of the green picture elements G, the blue picture element B and the cyan picture element C overlaps the light transmitting part 2b (i.e., such that a part of the optical alignment film corresponding to a top half of the red picture elements R and the yellow picture elements Y and a bottom half of the green picture elements G, the blue picture element B and the cyan picture element C overlaps the light shielding part 2a).

Next, as shown in FIG. 59(b), ultraviolet rays are directed obliquely in the direction represented by the arrows. As a result of this exposure step, as shown in FIG. 59(c), the part of the optical alignment film corresponding to the bottom half of the red picture elements R and the yellow picture elements Y and the top half of the green picture elements G, the blue picture element B and the cyan picture element C is given a prescribed pretilt direction. The pretilt direction given at this point is the same as the pretilt direction PB2 shown in FIG. 2(b).

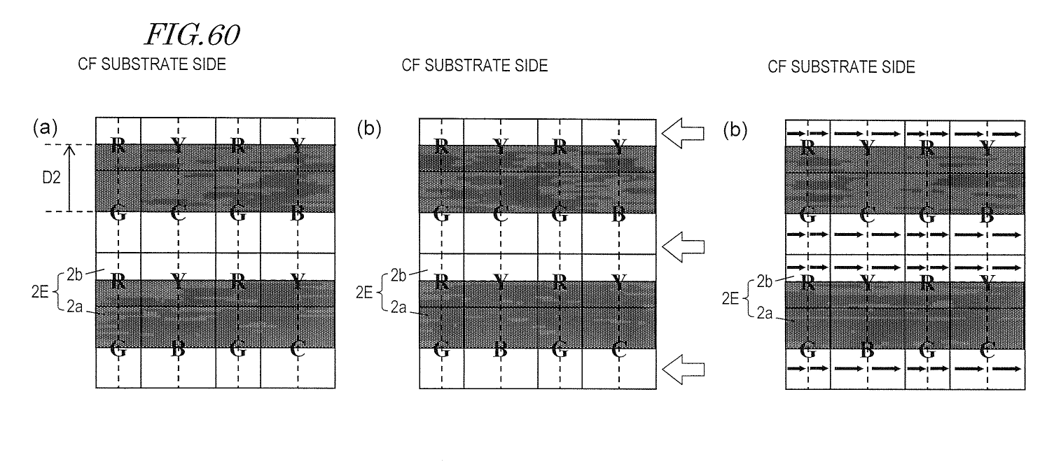

Next, as shown in FIG. 60(a), the photomask 2E is shifted in the column direction by a prescribed distance D2. In this example, the prescribed distance D2 is half (½) of a width PW2 (see FIG. 54) of the pixel P in the column direction. As a result of this movement, the part of the optical alignment film corresponding to the top half of the red picture elements R and the yellow picture elements Y and the bottom half of the green picture elements G, the blue picture element B and the cyan picture element C overlaps the light transmitting part 2b of the photomask 2E. Namely, the part of the optical alignment film corresponding to the bottom half of the red picture elements R and the yellow picture elements Y and the top half of the green picture elements G, the blue picture element B and the cyan picture element C overlaps the light shielding part 2a of the photomask 2E.

Next, as shown in FIG. 60(b), ultraviolet rays are directed obliquely in the direction represented by the arrows. As a result of this exposure step, as shown in FIG. 60(c), the remaining part of the optical alignment film, namely, the part thereof corresponding to the top half of the red picture elements R and the yellow picture elements Y and the bottom half of the green picture elements G, the blue picture element B and the cyan picture element C is given a prescribed pretilt direction. The pretilt direction given at this point is the same as the pretilt direction PB1 shown in FIG. 2(b) and is antiparallel to the pretilt direction shown in FIG. 59(c).

As a result of the above-described optical alignment processing, in an area of the optical alignment film of the CF substrate corresponding to each picture element, two areas having pretilt directions antiparallel to each other are formed. By bringing together the TFT substrate and the CF substrate processed with the optical alignment in the above-described manner, the liquid crystal display device 600 shown in FIG. 54 in which each picture element is divided into liquid crystal domains having different alignment directions is obtained.

In the production method of the liquid crystal display device 600, in the step of performing the optical alignment processing on the optical alignment film of the TFT substrate, two exposure steps are performed by use of one, common photomask 1E. In the step of performing the optical alignment processing on the optical alignment film of the CF substrate, two exposure steps are performed by use of one, common photomask 2E. Namely, the shifted exposure can be performed in both of the row direction and the column direction in which there are two widths of the picture elements. As can be seen from the above, in the liquid crystal display device 600 in this embodiment also, because one pixel P includes four arrangement patterns of the liquid crystal domains D1 through D4, increase of the cost and time required for the optical alignment processing can be suppressed although there are two widths of the picture elements in both of the row direction and the column direction.

In Embodiments 1 through 6 described above, a plurality of picture elements which define one pixel P display different primary colors from each other. Alternatively, one pixel P may include two or more picture elements for displaying the same primary color. For example, one pixel P may include two red picture elements R for displaying red, or two blue picture elements B for displaying blue. A multiple primary color liquid crystal display device in which one pixel P includes two red picture elements R is disclosed in WO2007/034770. When one pixel P includes two red picture elements R, brighter red (red having a higher lightness) can be displayed.

### Embodiment 7

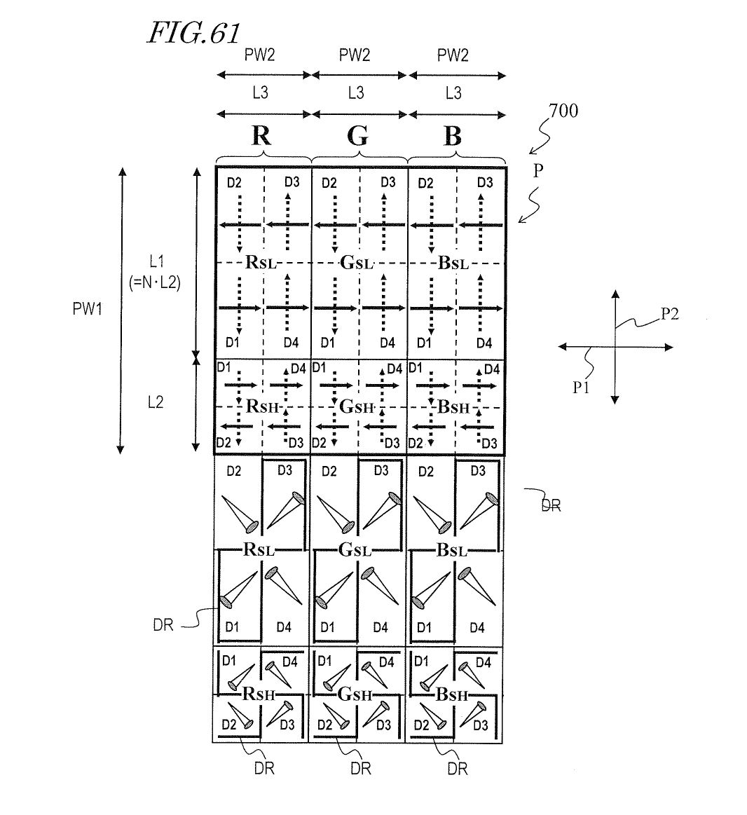

FIG. 61 shows a liquid crystal display device 700 in this embodiment. FIG. 61 is a plan view schematically showing two pixels P of the liquid crystal display device 700. The liquid crystal display device 700 provides display by use of three primary colors and is not a multiple primary color liquid crystal display device. As described later, the liquid crystal display device 700 uses the picture element division driving technology. When the 4D-RTN mode is merely adopted to a liquid crystal display device using the picture element division driving technology, in the case where one picture element includes a sub picture element having a different size from that of another sub picture element, substantially the same problem as that in a multiple primary color liquid crystal display device occurs. The liquid crystal display device 700 in this embodiment can prevent such a problem owing to the structure described below.

As shown in FIG. 61, the liquid crystal display device 700 includes pixels P each defined by a red picture element R, a green picture element G and a blue picture element B. Each of the picture elements defining the pixel P includes an even number of sub picture elements which can apply different voltages to respective parts of the liquid crystal layer from each other.

Specifically, the red picture element R includes a dark sub picture element Rs_{L} for providing a relatively low luminance and a bright sub picture element Rs_{H} for providing a relatively high luminance. Similarly, the green picture element G includes a dark sub picture element Gs_{L} for providing a relatively low luminance and a bright sub picture element Gs_{H} for providing a relatively high luminance. The blue picture element B includes a dark sub picture element Bs_{L} for providing a relatively low luminance and a bright sub picture element Bs_{H} for providing a relatively high luminance. In each picture element, the dark sub picture element and the bright picture element are arranged in the column direction (i.e., in one line). As a specific structure for realizing the picture element division driving, any of various structures as disclosed in Patent Documents 3 and 4 is usable.

The dark sub picture element and the bright sub picture element included in each picture element are each divided into four domains having different alignment directions. Specifically, each sub picture element includes four liquid crystal domains D1 through D4 respectively having tilt directions of about 225°, about 315°, about 45° and about 135° when a voltage is applied. The tilt directions of the liquid crystal domains D1 through D4 have an angle of about 45° with respect to transmission axes P1 and P2 of a pair of polarizing plates located in crossed Nicols. The liquid crystal domains D1 through D4 are arranged in a matrix of 2 rows×2 columns.

In the liquid crystal display devices 100 through 600 in Embodiments 1 through 6, four liquid crystal domains D1 through D4 are formed in one picture element. By contrast, in the liquid crystal display device 700 in this embodiment, one picture element includes a plurality of sub picture elements, and four liquid crystal domains D1 through D4 are formed in one sub picture element as described above. In the case where four liquid crystal domains D1 through D4 are formed in one sub picture element also, a dark area DR appears which has a different shape in accordance with the arrangement of the liquid crystal domains D1 through D4 in the sub picture element.

A length L1 of sides of the dark sub picture elements Rs_{L}, Gs_{L} and Bs_{L} which are parallel to the column direction is different from a length L2 of sides of the bright sub picture elements Rs_{H}, Gs_{H} and Bs_{H} which are parallel to the column direction. Specifically, the length L1 is N times the length L2 (i.e., L1=N·L2). N is an integer of 2 or greater. By contrast, sides of all the sub picture elements which are parallel to the row direction have an equal length L3. As can be seen from the above, in the picture element of the liquid crystal display device 700 in this embodiment, there is one width of the sub picture elements in the row direction, whereas there are two widths of the sub picture elements in the column direction.

In each of the dark sub picture elements Rs_{L}, Gs_{L}, and Bs_{L}, the liquid crystal domains D1 through D4 are located in the order of bottom left, top left, top right and bottom right (i.e., clockwise from bottom left). Therefore, the dark area DR appearing in each of the dark sub picture elements Rs_{L}, Gs_{L} and Bs_{L} is generally shaped like the letter “8”. By contrast, in each of the bright sub picture elements Rs_{H}, Gs_{H} and Bs_{H}, the liquid crystal domains D1 through D4 are located in the order of top left, bottom left, bottom right and top right (i.e., counterclockwise from top left). Therefore, the dark area DR appearing in each of the bright sub picture elements Rs_{H}, Gs_{H} and Bs_{H} is generally gammadion-shaped.

As described above, in the liquid crystal display device 700 in this embodiment, the arrangement pattern of the liquid crystal domains D1 through D4 in the dark sub picture elements Rs_{L}, Gs_{L} and Bs_{L} is different from that in the bright sub picture elements Rs_{H}, Gs_{H} and Bs_{H}. One picture element includes sub picture elements having different arrangement patterns of the liquid crystal domains D1 through D4 (having different shapes of the dark area DR). Therefore, the shifted exposure can be performed in the column direction in which there are two widths of the sub picture elements in addition to the row direction in which there is one width of the sub picture elements. Hereinafter, the optical alignment processing on a pair of optical alignment films included in the liquid crystal display device 700 will be described.

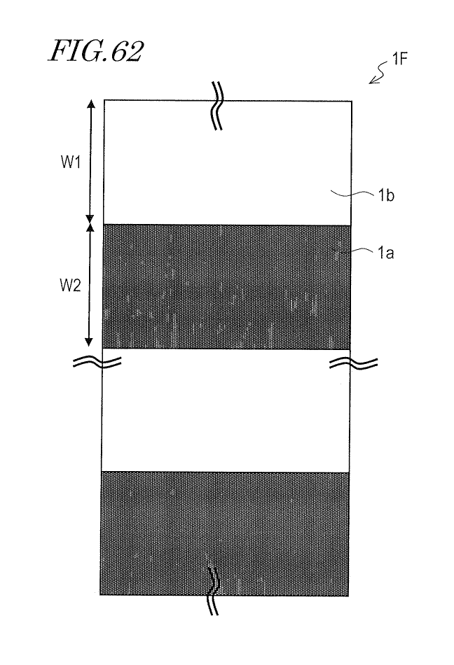

First, with reference to FIG. 62 through FIG. 64, the optical alignment processing on an optical alignment film of a CF substrate will be described.

First, a photomask 1F shown in FIG. 62 is prepared. As shown in FIG. 62, the photomask 1F includes a plurality of light shielding parts 1a extending like stripes in the row direction (horizontal direction) and a plurality of light transmitting parts 1b located between the plurality of light shielding parts 1a. A width W1 of each of the plurality of light transmitting parts 1b (width in the column direction) is equal to a sum of half of the length L1 of the sides of the dark sub picture elements Rs_{L}, Gs_{L} and Bs_{L} which are parallel to the column direction and half of the length L2 of the sides of the bright sub picture elements Rs_{H}, Gs_{H} and Bs_{H} which are parallel to the column direction (i.e., W1=(L1+L2)/2={(N+1)·L2}/2). A width W2 of each of the plurality of light shielding parts 1a (width in the column direction) is also equal to a sum of half of the length L1 of the sides of the dark sub picture elements Rs_{L}, Gs_{L} and Bs_{L} which are parallel to the column direction and half of the length L2 of the sides of the bright sub picture elements Rs_{H}, Gs_{H} and Bs_{H} which are parallel to the column direction (i.e., W2=(L1+L2)/2={(N+1)·L2}/2; W1+W2=L1+L2=(N+1)·L2).

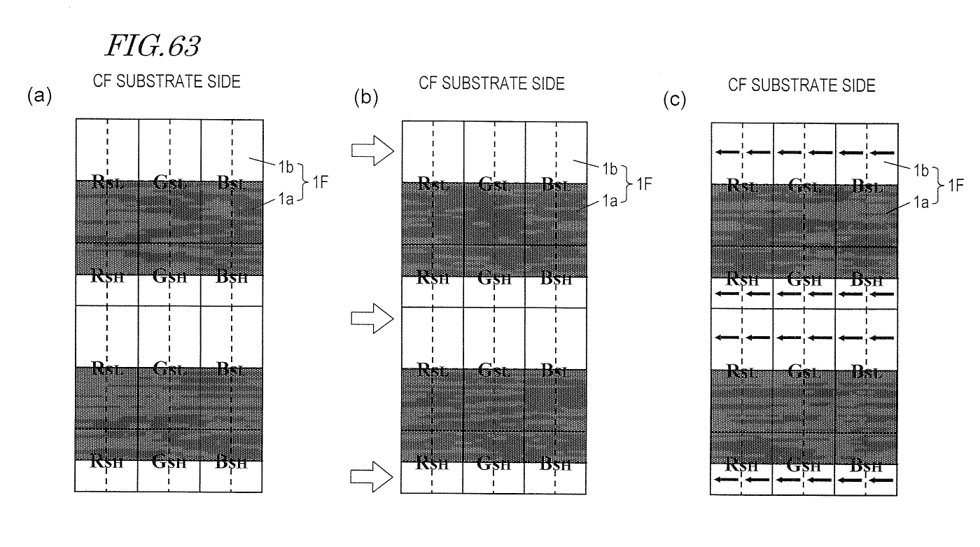

Next, as shown in FIG. 63(a), the photomask 1F is located such that a part of the optical alignment film corresponding to a top half of the dark sub picture elements Rs_{L}, Gs_{L} and Bs_{L} and a bottom half of the bright sub picture elements Rs_{H}, Gs_{H} and Bs_{H} overlaps the light transmitting part 1b (i.e., such that a part of the optical alignment film corresponding to a bottom half of the dark sub picture elements Rs_{L}, Gs_{L} and Bs_{L} and a top half of the bright sub picture elements Rs_{H}, Gs_{H} and Bs_{H} overlaps the light shielding part 1a).

Next, as shown in FIG. 63(b), ultraviolet rays are directed obliquely in the direction represented by the arrows. As a result of this exposure step, as shown in FIG. 63(c), the part of the optical alignment film corresponding to the top half of the dark sub picture elements Rs_{L}, Gs_{L} and Bs_{L} and the bottom half of the bright sub picture elements Rs_{H}, Gs_{H} and Bs_{H} is given a prescribed pretilt direction. The pretilt direction given at this point is the same as the pretilt direction PB2 shown in FIG. 2(b).

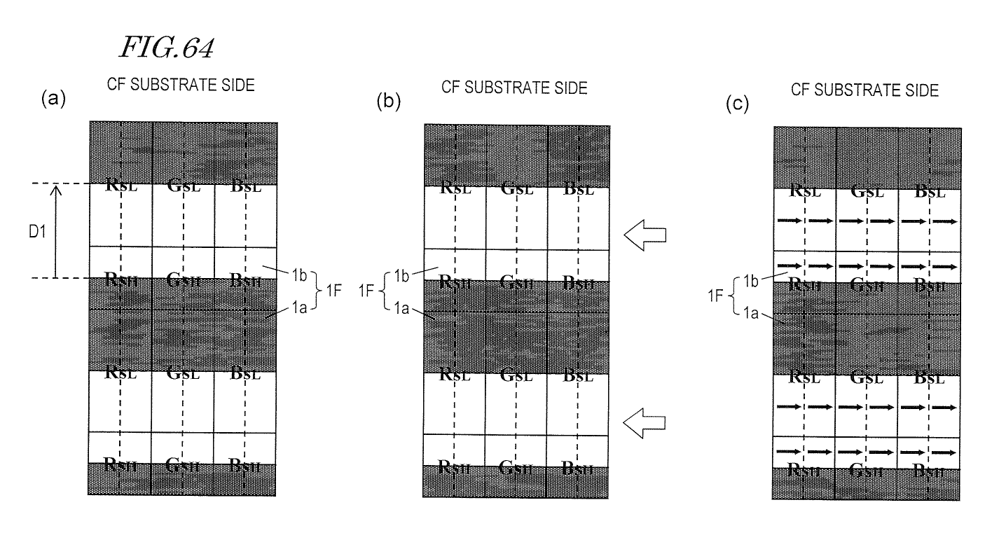

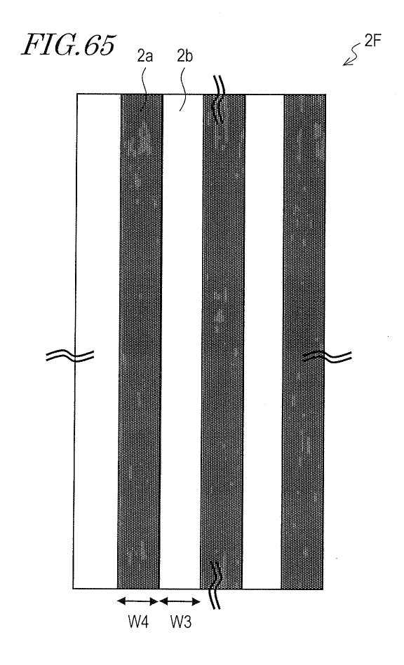

Next, as shown in FIG. 64(a), the photomask 1F is shifted in the column direction by a prescribed distance D1. In this example, the prescribed distance D1 is half (½) of a width PW1 (see FIG. 61) of the picture element in the column direction. As a result of this movement, the part of the optical alignment film corresponding to the bottom half of the dark sub picture elements Rs_{L}, Gs_{L} and Bs_{L} and the top half of the bright sub picture elements Rs_{H}, Gs_{H} and Bs_{H} overlaps the light transmitting part 1b of the photomask 1F. Namely, the part of the optical alignment film corresponding to the top half of the dark sub picture elements Rs_{L}, Gs_{L} and Bs_{L} and the bottom half of the bright sub picture elements Rs_{H}, Gs_{H} and Bs_{H} overlaps the light shielding part 1a of the photomask 1F.

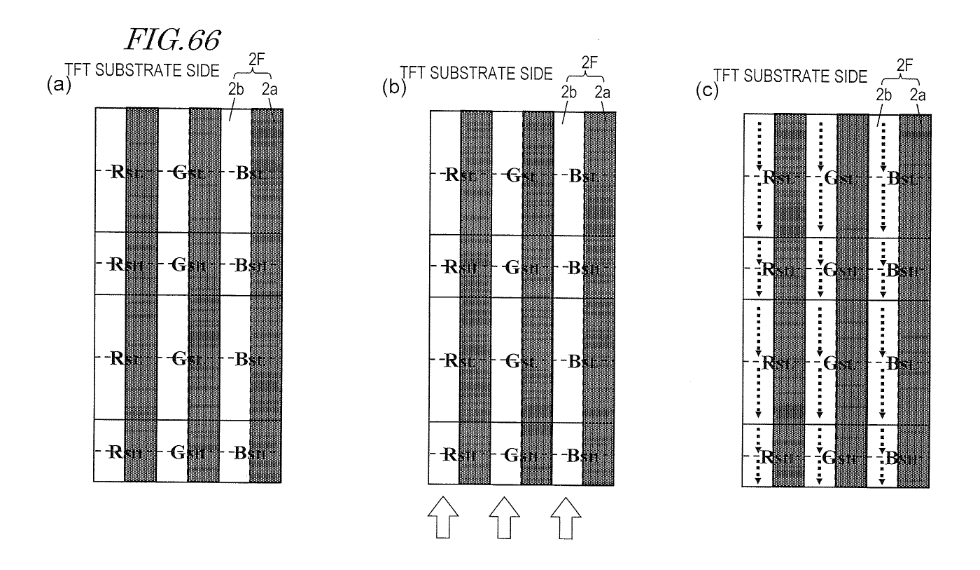

Next, as shown in FIG. 64(b), ultraviolet rays are directed obliquely in the direction represented by the arrows. As a result of this exposure step, as shown in FIG. 65(c), the remaining part of the optical alignment film, namely, the part thereof corresponding to the bottom half of the dark sub picture elements Rs_{L}, Gs_{L} and Bs_{L} and the top half of the bright sub picture elements Rs_{H}, Gs_{H} and Bs_{H} is given a prescribed pretilt direction. The pretilt direction given at this point is the same as the pretilt direction PB1 shown in FIG. 2(b) and is antiparallel to the pretilt direction shown in FIG. 63(c).

As a result of the above-described optical alignment processing, in an area of the optical alignment film of the CF substrate corresponding to each picture element, two areas having pretilt directions antiparallel to each other are formed. Now, with reference to FIG. 65 through FIG. 67, the optical alignment processing on an optical alignment film of a TFT substrate will be described.

First, a photomask 2F shown in FIG. 65 is prepared. As shown in FIG. 65, the photomask 2F includes a plurality of light shielding parts 2a extending like stripes in the column direction (vertical direction) and a plurality of light transmitting parts 2b located between the plurality of light shielding parts 2a. A width W3 of each of the plurality of light transmitting parts 2b (width in the row direction) is half of the length L3 of the sides of each sub picture element which are parallel to the row direction (i.e., W3=L3/2). A width W4 of each of the plurality of light shielding parts 2a (width in the row direction) is also half of the length L3 of the sides of each sub picture element which are parallel to the row direction (i.e., W4=L3/2; W3+W4=L3).

Next, as shown in FIG. 66(a), the photomask 2F is located such that a part of the optical alignment film corresponding to a left half of the sub picture elements overlaps the light transmitting part 2b (i.e., such that a part of the optical alignment film corresponding to a right half of the sub picture elements overlaps the light shielding part 2a).

Next, as shown in FIG. 66(b), ultraviolet rays are directed obliquely in the direction represented by the arrows. As a result of this exposure step, as shown in FIG. 66(c), the part of the optical alignment film corresponding to the left half of the sub picture elements is given a prescribed pretilt direction. The pretilt direction given at this point is the same as the pretilt direction PA1 shown in FIG. 2(a).

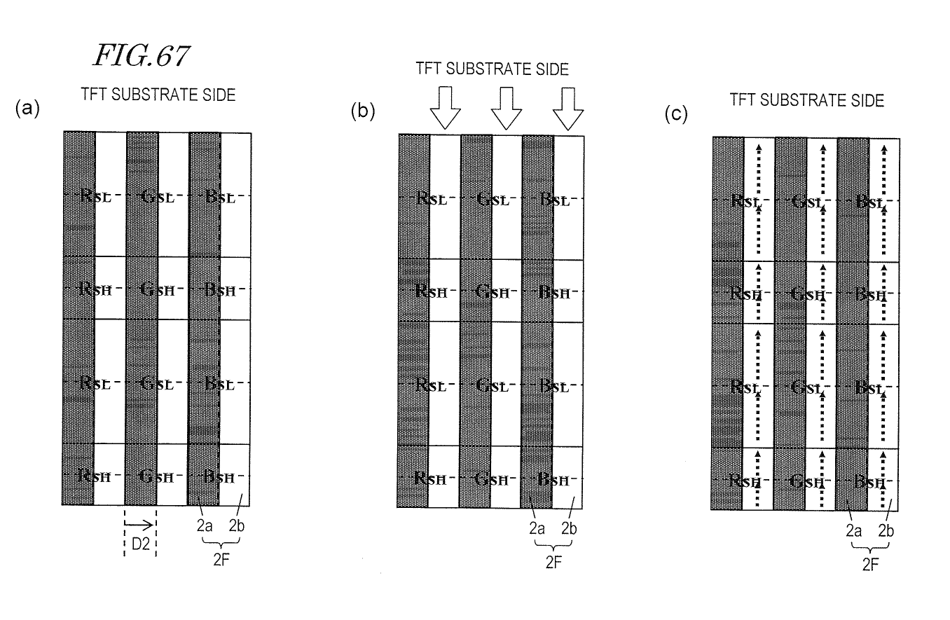

Next, as shown in FIG. 67(a), the photomask 2F is shifted in the row direction by a prescribed distance D2. In this example, the prescribed distance D2 is half (½) of a width PW2 (see FIG. 61) of the picture element in the row direction, and is half (½) of the length of the sides of the sub picture element which are parallel to the row direction. As a result of this movement, the part of the optical alignment film corresponding to the right half of the sub picture elements overlaps the light transmitting part 2b of the photomask 2F. Namely, the part of the optical alignment film corresponding to the left half of the sub picture elements overlaps the light shielding part 2a of the photomask 2F.

Next, as shown in FIG. 67(b), ultraviolet rays are directed obliquely in the direction represented by the arrows. As a result of this exposure step, as shown in FIG. 67(c), the remaining part of the optical alignment film, namely, the part thereof corresponding to the right half of the sub picture elements is given a prescribed pretilt direction. The pretilt direction given at this point is the same as the pretilt direction PA2 shown in FIG. 2(a) and is antiparallel to the pretilt direction shown in FIG. 66(c).

As a result of the above-described optical alignment processing, in an area of the optical alignment film of the TFT substrate corresponding to each picture element, two areas having pretilt directions antiparallel to each other are formed. By bringing together the TFT substrate and the CF substrate processed with the optical alignment in the above-described manner, the liquid crystal display device 700 shown in FIG. 61 in which each sub picture element is divided into liquid crystal domains having different alignment directions is obtained.

In the production method of the liquid crystal display device 700, in the step of performing the optical alignment processing on the optical alignment film of the CF substrate, two exposure steps are performed by use of one, common photomask 1F. In the step of performing the optical alignment processing on the optical alignment film of the TFT substrate, two exposure steps are performed by use of one, common photomask 2F. Namely, the shifted exposure can be performed in the column direction in which there are two widths of the sub picture elements in addition to the row direction in which there is one width of the sub picture elements. Therefore, the optical alignment processing can be realized at low cost and in a short takt time. As can be seen from the above, in the liquid crystal display device 700 in this embodiment, because one picture element includes sub picture elements having different arrangement patterns of the liquid crystal domains D1 through D4 (having different shapes of the dark area DR), increase of the cost and time required for the optical alignment processing can be suppressed.

In this embodiment, the moving distance D1 of the photomask 1F in the column direction is half (½) of the width PW1 of the picture element in the column direction. A reason for this is that in the picture element of the liquid crystal display device 700, the sub picture elements are arranged in two rows. In the case where there are two widths of the sub picture elements in the column direction, the moving distance D1 of the photomask 1F in the column direction is about 1/m of the width PW1 of the picture element in the column direction (m is an even number of 2 or greater). m is equal to the number of rows of the picture elements in the picture element. In the meantime, the moving distance D2 of the photomask 1F in the row direction in which there is one width of the sub picture elements is about half (about ½) of the length L3 of the sides of each sub picture element which are parallel to the row direction.

For dividing one sub picture element into four areas having different alignment directions, like for dividing one picture element into four areas having different alignment directions, it is preferable that as a result of the optical alignment processing on an optical alignment film, a double-exposed area DE is formed than an unexposed area is formed from the viewpoint of reliability. Accordingly, it is preferable that the width W1 of the light transmitting part 1b of the photomask 1F, the width W2 of the light shielding part 1a of the photomask 1F, the length L1 of the sides of the dark sub picture elements Rs_{L}, Gs_{L} and Bs_{L} which are parallel to the column direction, and the length L2 of the sides of the bright sub picture elements Rs_{H}, Gs_{H} and Bs_{H} which are parallel to the column direction fulfill the relationships of W1=(L1+L2)/2+Δ and W2=(L1+L2)/2−Δ. It is preferable that 0<Δ≦10.

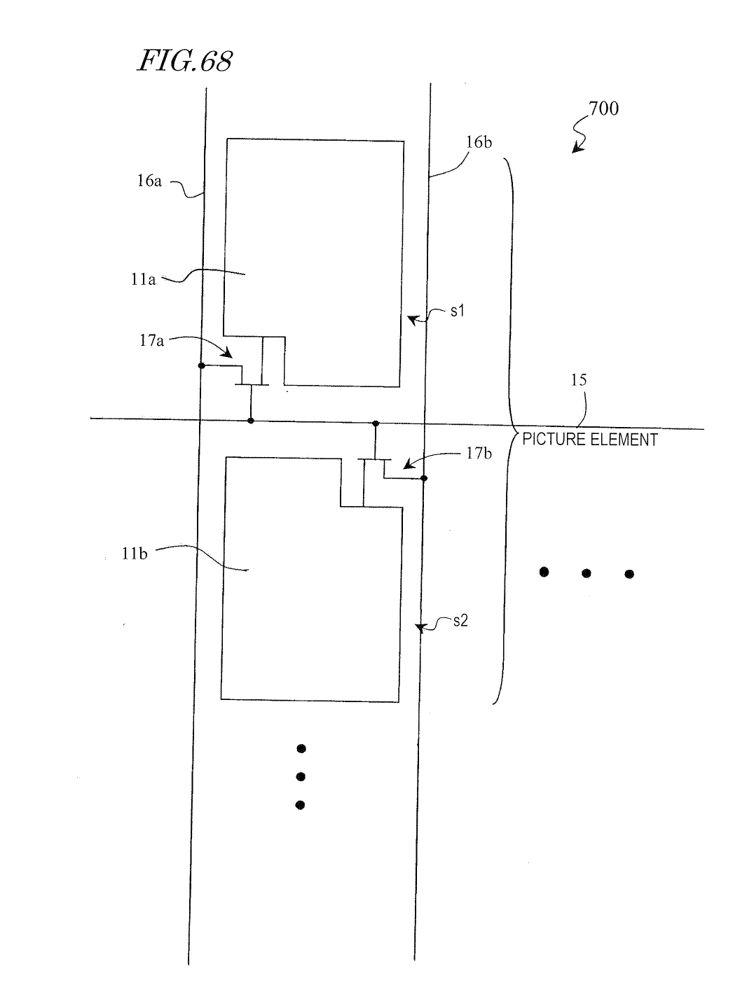

Now, a specific structure for performing picture element division driving will be described. FIG. 68 shows an example of specific structure of a picture element. As shown in FIG. 68, the picture element includes a first sub picture element s1 and a second sub picture element s2 which can provide different levels of luminance from each other. Namely, for displaying a gray scale, each picture element is driven such that an effective voltage applied to a part of the liquid crystal layer corresponding to the first sub picture element s1 is different from an effective voltage applied to a part of the liquid crystal layer corresponding to the second sub picture element s2. One of the first sub picture element s1 and the second sub picture element s2 is each of the dark sub picture elements Rs_{L}, Gs_{L} and Bs_{L}, and the other of the first sub picture element s1 and the second sub picture element s2 is each of the bright sub picture elements Rs_{H}, Gs_{H} and Bs_{H}. The number of sub picture elements included in one picture element (also referred to as the “dividing number of the picture element) is not limited to 2, and may be, for example, 4.

When a picture element is divided into a plurality of sub picture elements, for example, the sub picture element s1 and the sub picture element s2, which can provide different levels of luminance from each other, the picture element is observed in the state where different characteristics are present in a mixed state. Therefore, the viewing angle dependence of the γ characteristic (the problem that the γ characteristic as observed in a front direction and the γ characteristic as observed in an oblique direction are different from each other) is alleviated. The γ characteristic is gray scale dependence of the display luminance. The γ characteristic as observed in the front direction being different from the γ characteristic as observed in an oblique direction means that the display gray scale is different in accordance with the direction of observation.

A structure for applying different effective voltages to the parts of the liquid crystal layer corresponding to the first sub picture element s1 and the second sub picture element s2 may be any of the structures disclosed in, for example, Patent Documents 3 and 4.

For example, a structure shown in FIG. 68 can be adopted. In a general liquid crystal display device which does not perform picture element division driving, one picture element includes one picture element electrode connected to a signal line via a switching element (e.g., TFT), whereas the one picture element shown in FIG. 68 includes two sub picture element electrodes 11a and 11b respectively connected to different signal lines 16a and 16b via corresponding TFTs 17a and 17b. In FIG. 68, the two sub picture element electrodes 11a and 11b have substantially the same size. As shown in FIG. 61 and the like, in the liquid crystal display device 700 in this embodiment, each picture element includes a plurality of sub picture elements having different sizes from each other. Typically, the two sub picture element electrodes 11a and 11b have different sizes from each other.

The first sub picture element s1 and the second sub picture element s2 form one picture element. Therefore, gate electrodes of the TFTs 17a and 17b are connected to a common scanning line (gate line) 15 and are controlled to be turned on or off by the same scanning signal. Signal lines (source lines) 16a and 16b are supplied with signal voltages (gray scale voltages) such that the first sub picture element s1 and the second sub picture element s2 provide different levels of luminance. The signal voltages supplied to the signal lines 16a and 16b are adjusted such that an average luminance of the first sub picture element s1 and the second sub picture element s2 matches the picture element luminance indicated by a display signal (video signal) input from an external device.

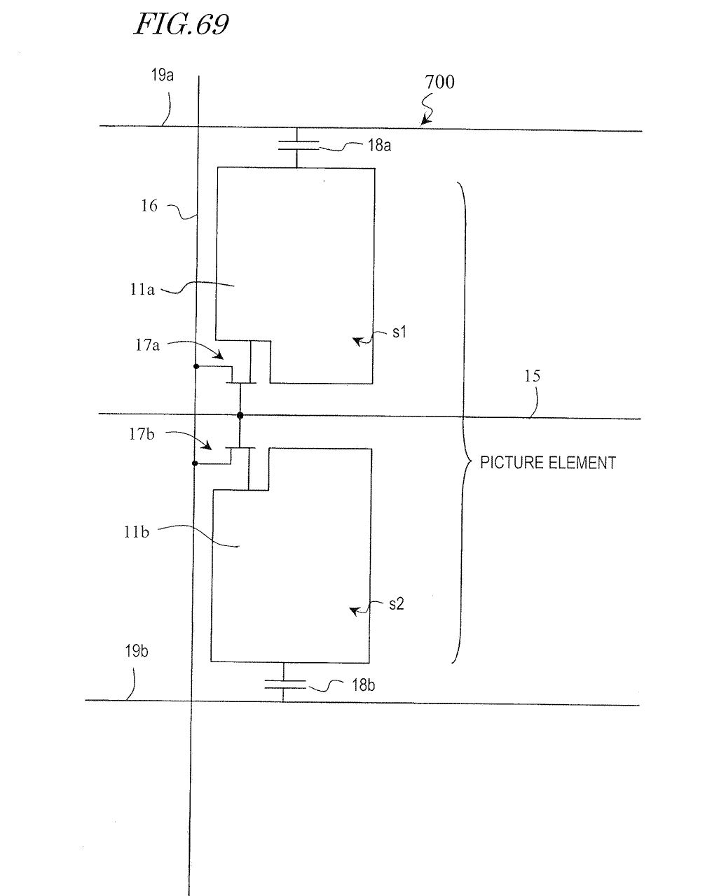

Alternatively, a structure shown in FIG. 69 may be adopted. In the structure shown in FIG. 69, source electrodes of the TFTs 17a and 17b are connected to a common (same) signal line 16. The first sub picture element s1 and the second sub picture element s2 respectively include storage capacitances (CS) 18a and 18b. The storage capacitances 18a and 18b are respectively connected to storage capacitance lines (CS lines) 19a and 19b. The storage capacitances 18a and 18b respectively include storage capacitance electrodes electrically connected to the sub picture element electrodes 11a and 11b, storage capacitance counter electrodes electrically connected to the storage capacitance lines 19a and 19b, and an insulating layer provided these electrodes (the storage capacitance electrodes, the storage capacitance counter electrodes, and the insulating layer are not shown). The storage capacitance counter electrodes of the storage capacitances 18a and 18b are independent from each other and are supplied with voltages different from each other (referred to as the storage capacitance counter voltages) from the storage capacitance lines 19a and 19b. By changing the storage capacitance counter voltages supplied to the storage capacitance counter electrodes, the effective voltage to be applied to the part of the liquid crystal layer corresponding to the first sub picture element s1 can be made different from the effective voltage to be applied to the part of the liquid crystal layer corresponding to the second picture element s2, by use of capacitance division.

In the structure shown in FIG. 68, the first sub picture element s1 and the second sub picture element s2 are respectively connected to the TFTs 17a and 17b which are independent from each other. The source electrodes of the TFTs 17a and 17b are respectively connected to the signal lines 16a and 16b. Accordingly, any effective voltage can be applied to each of the plurality of sub picture elements s1 and s2. However, the number of the signal lines (16a, 16b) is twice the number of the signal lines in a liquid crystal display device which does not perform the picture element division driving, and the number of signal line driving circuits also needs to be twice the number of signal line driving circuits in such a liquid crystal display device.

By contrast, in the structure shown in FIG. 69, the sub picture element electrodes 11a and 11b do not need to be supplied with different signal voltages. Thus, the TFTs 17a and 17b may be connected to the common signal line 16 and supplied with the same signal voltage. Accordingly, the number of the signal lines 16 is the same as that in a liquid crystal display device which does not perform picture element division driving, and the structure of the signal line driving circuits can be the same as that in a liquid crystal display device which does not perform picture element division driving.

### Embodiment 8

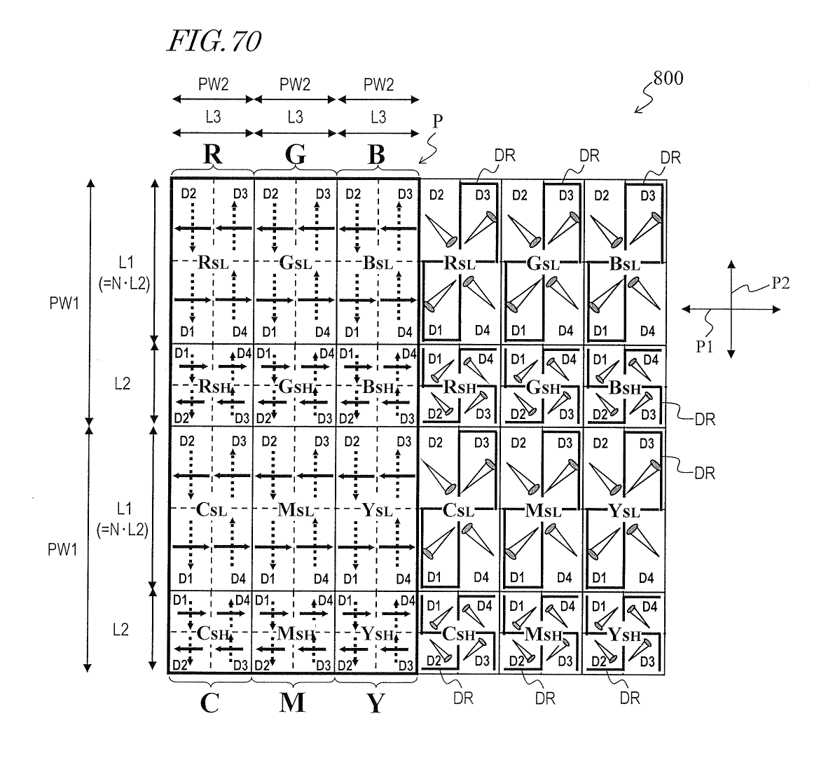

FIG. 70 shows a liquid crystal display device 800 in this embodiment. FIG. 70 is a plan view schematically showing two pixels P of the liquid crystal display device 800. The liquid crystal display device 800 is a multiple primary color liquid crystal display device which provides display by use of six primary colors. The liquid crystal display device 800 uses the picture element division driving technology.

As shown in FIG. 70, the liquid crystal display device 800 includes a pixel P defined by a red picture element R, a green picture element G, a blue picture element B, a cyan picture element C, a magenta picture element M and a yellow picture element Y. Each picture element defining the pixel P includes an even number of sub picture elements which can apply different voltages to parts of the liquid crystal layer corresponding thereto.

Specifically, the red picture element R includes a dark sub picture element Rs_{L} and a bright sub picture element RS_{H}. The green picture element G includes a dark sub picture element Gs_{L} and a bright sub picture element Gs_{H}. The blue picture element B includes a dark sub picture element Bs_{L} and a bright sub picture element Bs_{H}. The cyan picture element C includes a dark sub picture element Cs_{L} and a bright sub picture element Cs_{H}. The magenta picture element M includes a dark sub picture element Ms_{L} and a bright sub picture element Ms_{H}. The yellow picture element Y includes a dark sub picture element Ys_{L} and a bright sub picture element Ys_{H}. In each picture element, the dark sub picture element and the bright picture element are arranged in the column direction (i.e., in one line).

A length L1 of sides of the dark sub picture elements Rs_{L}, Gs_{L}, Bs_{L}, Cs_{L}, Ms_{L} and Ys_{L} which are parallel to the column direction is different from a length L2 of sides of the bright sub picture elements Rs_{H}, Gs_{H}, Bs_{H}, Cs_{H}, Ms_{H} and Ys_{H} which are parallel to the column direction. Specifically, the length L1 is N times the length L2 (i.e., L1=N·L2). N is an integer of 2 or greater. By contrast, sides of all the sub picture elements which are parallel to the row direction have an equal length L3. As can be seen from the above, in the picture element of the liquid crystal display device 800 in this embodiment, there is one width of the sub picture elements in the row direction, whereas there are two widths of the sub picture elements in the column direction.

In each of the dark sub picture elements Rs_{L}, Gs_{L}, Bs_{L}, Cs_{L}, Ms_{L} and Ys_{L}, the liquid crystal domains D1 through D4 are located in the order of bottom left, top left, top right and bottom right (i.e., clockwise from bottom left). Therefore, the dark area DR appearing in each of dark sub picture elements Rs_{L}, Gs_{L}, Bs_{L}, Cs_{L}, Ms_{L} and Ys_{L} is generally shaped like the letter “8”. By contrast, in each of the bright sub picture elements Rs_{H}, Gs_{H}, Bs_{H}, Cs_{H}, Ms_{H} and Ys_{H}, the liquid crystal domains D1 through D4 are located in the order of top left, bottom left, bottom right and top right (i.e., counterclockwise from top left). Therefore, the dark area DR appearing in each of the bright sub picture elements Rs_{H}, Gs_{H}, Bs_{H}, Cs_{H}, Ms_{H} and Ys_{H} is generally gammadion-shaped.

As described above, in the liquid crystal display device 800 in this embodiment, the arrangement pattern of the liquid crystal domains D1 through D4 in the dark sub picture elements Rs_{L}, Gs_{L}, Bs_{L}, Cs_{L}, Ms_{L} and Ys_{L} is different from that in the bright sub picture elements Rs_{H}, Gs_{H}, Bs_{H}, Cs_{H}, Ms_{H} and Ys_{H}. One picture element includes sub picture elements having different arrangement patterns of the liquid crystal domains D1 through D4 (having different shapes of the dark area DR). Therefore, the shifted exposure can be performed in the column direction in addition to the row direction in which there is one width of the sub picture elements. Hereinafter, the optical alignment processing on a pair of optical alignment films included in the liquid crystal display device 800 will be described.

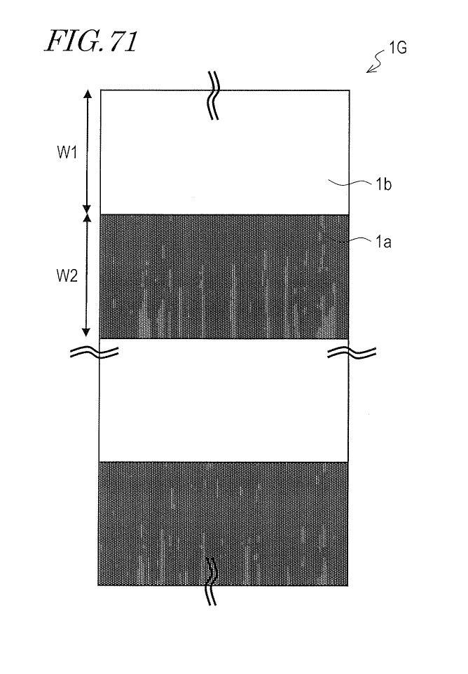

First, with reference to FIG. 71 through FIG. 73, the optical alignment processing on an optical alignment film of a CF substrate will be described.

First, a photomask 1G shown in FIG. 71 is prepared. As shown in FIG. 71, the photomask 1G includes a plurality of light shielding parts 1a extending like stripes in the row direction (horizontal direction) and a plurality of light transmitting parts 1b located between the plurality of light shielding parts 1a. A width W1 of each of the plurality of light transmitting parts 1b (width in the column direction) is equal to a sum of half of the length L1 of the sides of the dark sub picture elements Rs_{L}, Gs_{L}, Bs_{L}, Cs_{L}, Ms_{L} and Ys_{L} which are parallel to the column direction and half of the length L2 of the sides of the bright sub picture elements Rs_{H}, Gs_{H}, Bs_{H}, Cs_{H}, Ms_{H} and Ys_{H} which are parallel to the column direction (i.e., W1=(L1+L2)/2={(N+1)·L2}/2). A width W2 of each of the plurality of light shielding parts 1a (width in the column direction) is also equal to a sum of half of the length L1 of the sides of the dark sub picture elements Rs_{L}, Gs_{L}, Bs_{L}, Cs_{L}, Ms_{L} and Ys_{L} which are parallel to the column direction and half of the length L2 of the sides of the bright sub picture elements Rs_{H}, Gs_{H}, Bs_{H}, Cs_{H}, Ms_{H} and Ys_{H} which are parallel to the column direction (i.e., W2=(L1+L2)/2={(N+1)·L2}/2; W1+W2=L1+L2=(N+1)·L2).

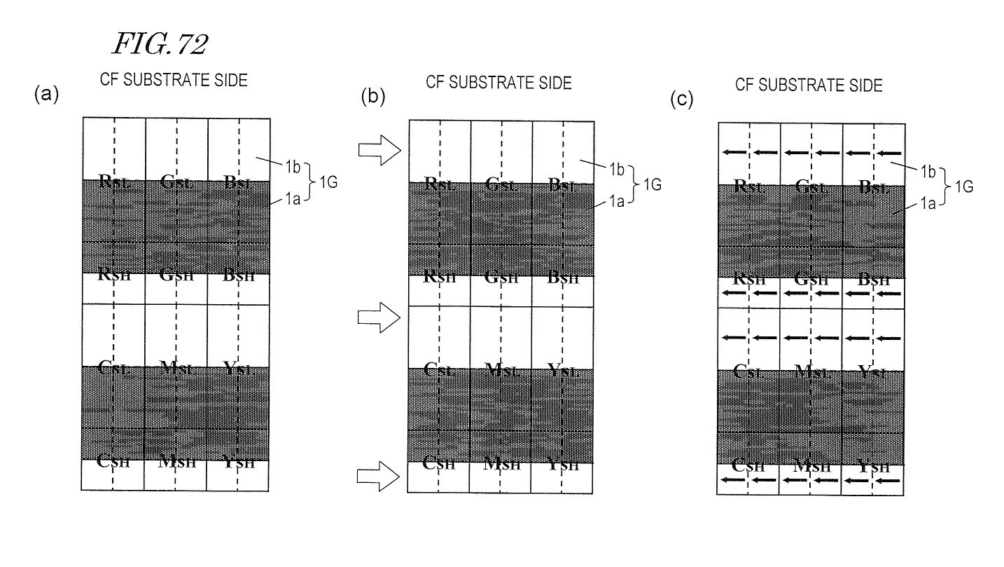

Next, as shown in FIG. 72(a), the photomask 1G is located such that parts of the optical alignment film corresponding to a top half of the dark sub picture elements Rs_{L}, Gs_{L} and Bs_{L}, a top half of the dark sub picture elements Cs_{L}, Ms_{L} and Ys_{L}, a bottom half of the bright sub picture elements Rs_{H}, Gs_{H} and Bs_{H} and a bottom half of the bright sub picture elements Cs_{H}, Ms_{H} and Ys_{H} overlap the light transmitting parts 1b (i.e., such that parts of the optical alignment film corresponding to a bottom half of the dark sub picture elements Rs_{L}, Gs_{L} and Bs_{L}, a bottom half of the dark sub picture elements Cs_{L}, Ms_{L} and Ys_{L}, a top half of the bright sub picture elements Rs_{H}, Gs_{H} and Bs_{H} a top half of the bright sub picture elements Cs_{H}, Ms_{H} and Ys_{H} overlap the light shielding parts 1a).

Next, as shown in FIG. 72(b), ultraviolet rays are directed obliquely in the direction represented by the arrows. As a result of this exposure step, as shown in FIG. 72(c), the parts of the optical alignment film corresponding to the top half of the dark sub picture elements Rs_{L}, Gs_{L} and Bs_{L}, the top half of the dark sub picture elements Cs_{L}, Ms_{L} and Ys_{L}, the bottom half of the bright sub picture elements Rs_{H}, Gs_{H} and Bs_{H} and the bottom half of the bright sub picture elements Cs_{H}, Ms_{H} and Ys_{H} are given a prescribed pretilt direction. The pretilt direction given at this point is the same as the pretilt direction PB2 shown in FIG. 2(b).

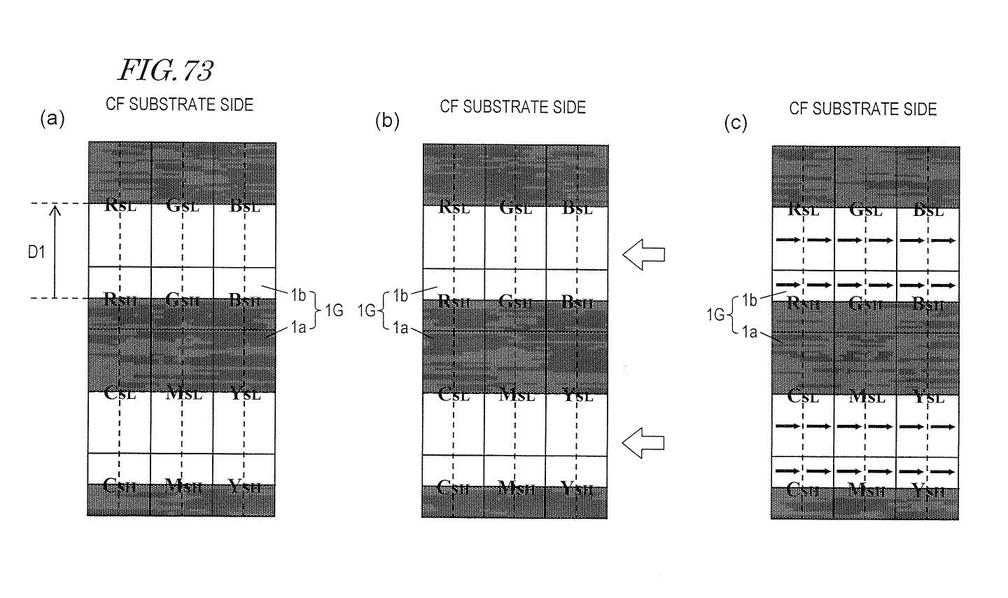

Next, as shown in FIG. 73(a), the photomask 1G is shifted in the column direction by a prescribed distance D1. In this example, the prescribed distance D1 is half (½) of a width PW1 (see FIG. 70) of the picture element in the column direction. As a result of this movement, the parts of the optical alignment film corresponding to the bottom half of the dark sub picture elements Rs_{L}, Gs_{L} and Bs_{L}, the bottom half of the dark sub picture elements Cs_{L}, Ms_{L} and Ys_{L}, the top half of the bright sub picture elements Rs_{H}, Gs_{H} and Bs_{H} and the top half of the bright sub picture elements Cs_{H}, Ms_{H} and Ys_{H} overlap the light transmitting parts 1b of the photomask 1G. Namely, the parts of the optical alignment film corresponding to the top half of the dark sub picture elements Rs_{L}, Gs_{L} and Bs_{L}, the top half of the dark sub picture elements Cs_{L}, Ms_{L} and Ys_{L}, the bottom half of the bright sub picture elements Rs_{H}, Gs_{H} and Bs_{H} and the bottom half of the bright sub picture elements Cs_{H}, Ms_{H} and Ys_{H} overlap the light shielding parts 1a of the photomask 1G.

Next, as shown in FIG. 73(b), ultraviolet rays are directed obliquely in the direction represented by the arrows. As a result of this exposure step, as shown in FIG. 73(c), the remaining parts of the optical alignment film, namely, the parts thereof corresponding to the bottom half of the dark sub picture elements Rs_{L}, Gs_{L} and Bs_{L}, bottom half of the dark sub picture elements Cs_{L}, Ms_{L} and Ys_{L}, the top half of the bright sub picture elements Rs_{H}, Gs_{H} and Bs_{H} and the top half of the bright sub picture elements sub picture elements Rs_{H}, Gs_{H}, Bs_{H} are given a prescribed pretilt direction. The pretilt direction given at this point is the same as the pretilt direction PB1 shown in FIG. 2(b) and is antiparallel to the pretilt direction shown in FIG. 72(c).

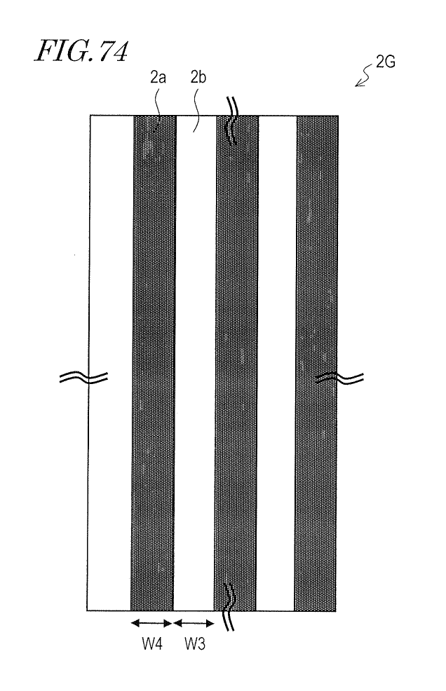

As a result of the above-described optical alignment processing, in an area of the optical alignment film of the CF substrate corresponding to each picture element, two areas having pretilt directions antiparallel to each other are formed. Now, with reference to FIG. 74 through FIG. 76, the optical alignment processing on an optical alignment film of a TFT substrate will be described.

First, a photomask 2G shown in FIG. 74 is prepared. As shown in FIG. 74, the photomask 2G includes a plurality of light shielding parts 2a extending like stripes in the column direction (vertical direction) and a plurality of light transmitting parts 2b located between the plurality of light shielding parts 2a. A width W3 of each of the plurality of light transmitting parts 2b (width in the row direction) is half of the length L3 of the sides of each sub picture element which are parallel to the row direction (i.e., W3=L3/2). A width W4 of each of the plurality of light shielding parts 2a (width in the row direction) is also half of the length L3 of the sides of each sub picture element which are parallel to the row direction (i.e., W4=L3/2; W3+W4=L3).

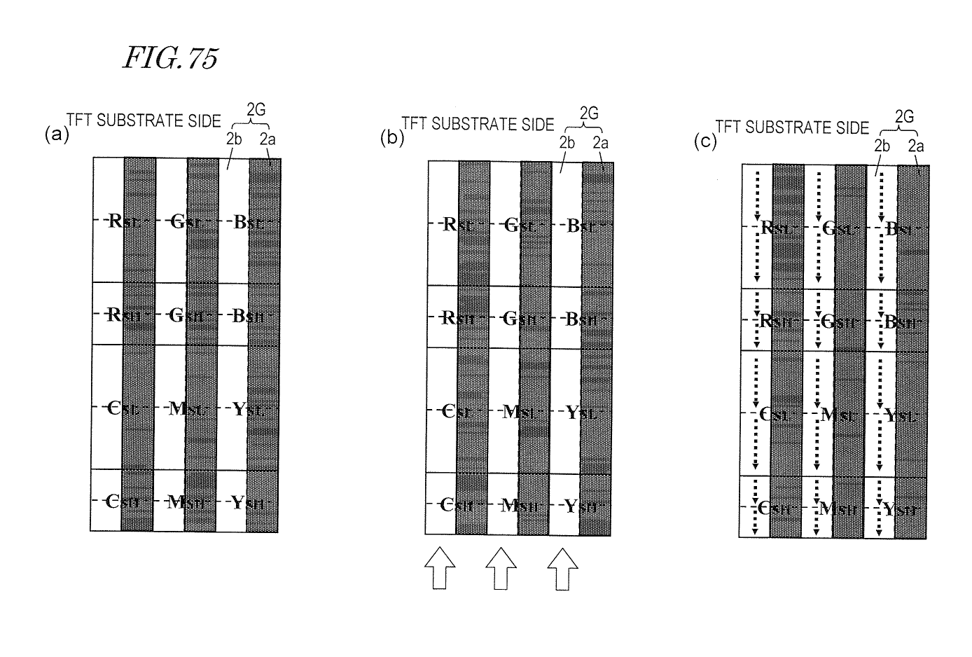

Next, as shown in FIG. 75(a), the photomask 2G is located such that a part of the optical alignment film corresponding to a left half of the sub picture elements overlaps the light transmitting part 2b (i.e., such that a part of the optical alignment film corresponding to a right half of the sub picture elements overlaps the light shielding part 2a).

Next, as shown in FIG. 75(b), ultraviolet rays are directed obliquely in the direction represented by the arrows. As a result of this exposure step, as shown in FIG. 75(c), the part of the optical alignment film corresponding to the left half of the sub picture elements is given a prescribed pretilt direction. The pretilt direction given at this point is the same as the pretilt direction PA1 shown in FIG. 2(a).

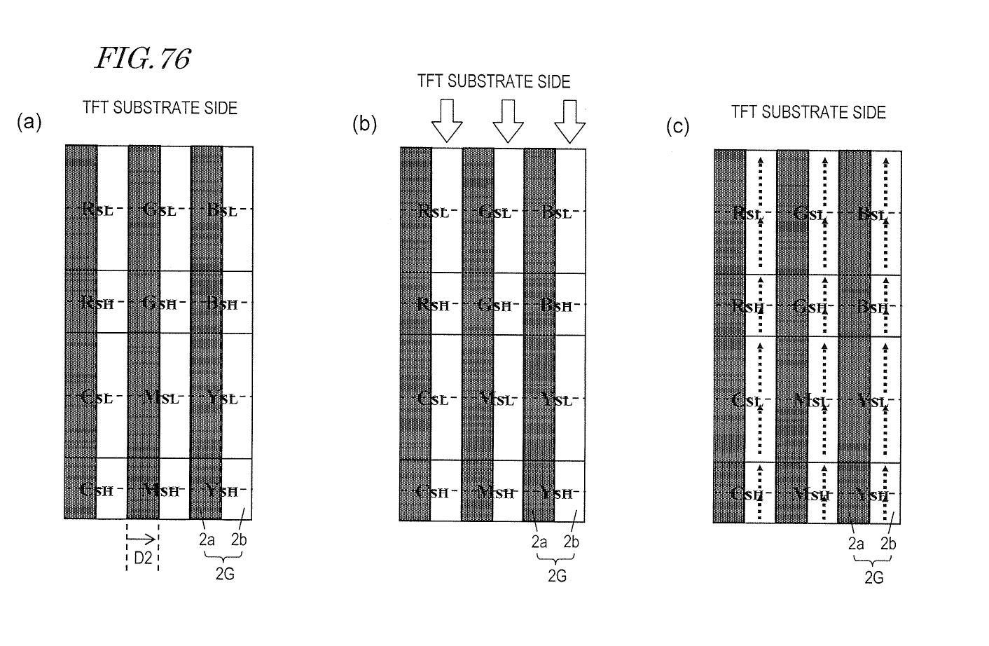

Next, as shown in FIG. 76(a), the photomask 2G is shifted in the row direction by a prescribed distance D2. In this example, the prescribed distance D2 is half (½) of a width PW2 (see FIG. 70) of the sub picture element in the row direction, and is half (½) of the length L3 of the sides of each sub picture element which are parallel to the row direction. As a result of this movement, the part of the optical alignment film corresponding to the right half of the sub picture elements overlaps the light transmitting part 2b of the photomask 2G. Namely, the part of the optical alignment film corresponding to the left half of the sub picture elements overlaps the light shielding part 2a of the photomask 2G.

Next, as shown in FIG. 76(b), ultraviolet rays are directed obliquely in the direction represented by the arrows. As a result of this exposure step, as shown in FIG. 76(c), the remaining part of the optical alignment film, namely, the part thereof corresponding to the right half of the sub picture elements is given a prescribed pretilt direction. The pretilt direction given at this point is the same as the pretilt direction PA2 shown in FIG. 2(a) and is antiparallel to the pretilt direction shown in FIG. 75(c).

As a result of the above-described optical alignment processing, in an area of the optical alignment film of the TFT substrate corresponding to each picture element, two areas having pretilt directions antiparallel to each other are formed. By bringing together the TFT substrate and the CF substrate processed with the optical alignment in the above-described manner, the liquid crystal display device 800 shown in FIG. 70 in which each sub picture element is divided into liquid crystal domains having different alignment directions is obtained.

In the production method of the liquid crystal display device 800, in the step of performing the optical alignment processing on the optical alignment film of the CF substrate, two exposure steps are performed by use of one, common photomask 1G. In the step of performing the optical alignment processing on the optical alignment film of the TFT substrate, two exposure steps are performed by use of one, common photomask 2G. Namely, the shifted exposure can be performed in the column direction in which there are two widths of the sub picture elements in addition to the row direction in which there is one width of the sub picture elements. Therefore, the optical alignment processing can be realized at low cost and in a short takt time. As can be seen from the above, in the liquid crystal display device 800 in this embodiment, because one picture element includes sub picture elements having different arrangement patterns of the liquid crystal domains D1 through D4 (having different shapes of the dark area DR), increase of the cost and time required for the optical alignment processing can be suppressed.

### INDUSTRIAL APPLICABILITY

A liquid crystal display device according to the present invention is preferably usable for uses of TV receivers and other devices required to provide a high quality of display.

### REFERENCE SIGNS LIST

1, 1A, 1B, 1C, 1D, 1E, 1F, 1G Photomask
2, 2A, 2B, 2C, 2D, 2E, 2F, 2G Photomask
1a, 2a Light shielding part of the photomask
1b, 2b Light transmitting part of the photomask
3 Liquid crystal layer
3a Liquid crystal molecule
10, 20, 30, 40 Picture element
11 Picture element electrode
12, 22 Optical alignment film
13, 23 Polarizing plate
21 Counter electrode
100, 200, 300, 400 Liquid crystal display device
500, 600, 700, 800 Liquid crystal display device
R Red picture element
G Green picture element
B Blue picture element
C Cyan picture element
M Magenta picture element
Y Yellow picture element
S1 TFT substrate (active matrix substrate)
S2 CF substrate (counter substrate)
S1a, S2a Transparent plate
SD1-SD4 Edge of the picture element electrode
EG1-EG4 Edge portion of the picture element electrode
D1-D4 Liquid crystal domain
t1-t4 Tilt direction (reference alignment direction)
e1-e4 Azimuthal angle direction perpendicular to the edge of the picture element electrode and directed to the inside of the picture element electrode
DR Dark area
SL Straight dark line
CL Cross-shaped dark line
P Pixel
DE Double-exposed area

1. A liquid crystal display device, comprising:
a vertical alignment type liquid crystal layer;
a first substrate and a second substrate facing each other with the liquid crystal layer interposed therebetween;
a first electrode provided on the liquid crystal layer side of the first substrate and a second electrode provided on the liquid crystal layer side of the second substrate; and
a pair of optical alignment films provided between the first electrode and the liquid crystal layer and between the second electrode and the liquid crystal layer;
wherein:
there are pixels which are each defined by a plurality of picture elements each having a shape including a side parallel to a prescribed first direction and a side parallel to a second direction crossing the first direction;
each of the plurality of picture elements includes a first liquid crystal domain in which a tilt direction of liquid crystal molecules at a center and in the vicinity thereof in a layer plane and in a thickness direction of the liquid crystal layer when a voltage is applied between the first electrode and the second electrode is a predetermined first tilt direction, a second liquid crystal domain in which the tilt direction is a predetermined second tilt direction, a third liquid crystal domain in which the tilt direction is a predetermined third tilt direction, and a fourth liquid crystal domain in which the tilt direction is a predetermined fourth tilt direction; the first, second, third and fourth tilt directions are such that a difference between any two these four directions is approximately equal to an integral multiple of 90°; and the first, second, third and fourth liquid crystal domains are arranged in a matrix of 2 rows×2 columns;
the plurality of picture elements are an even number of picture elements including at least four picture elements for displaying different colors from each other;
the even number of picture elements include a first picture element of which the side parallel to the first direction has a prescribed first length L1 and a second picture element of which the side parallel to the first direction has a second length L2 which is different from the first length L1;
in the first picture element, the first, second, third and fourth liquid crystal domains are arranged in a first pattern; and
in the second picture element, the first, second, third and fourth liquid crystal domains are arranged in a second pattern which is different from the first pattern.

2. The liquid crystal display device of claim 1, wherein:
in each of the even number of picture elements, when a gray scale is displayed, a dark area darker than the gray scale appears;
the dark area appearing in the first picture element is generally gammadion-shaped; and
the dark area appearing in the second picture element is generally shaped like the letter “8”.

3. The liquid crystal display device of claim 1, wherein:
the first, second, third and fourth liquid crystal domains are located such that the tilt directions of two adjacent liquid crystal domains thereamong are different by 90° from each other;
the first tilt direction and the third tilt direction have an angle of about 180° with respect to each other;
in the first picture element,
a portion of edges of the first electrode close to the first liquid crystal domain includes a first edge portion such that an azimuthal angle direction perpendicular to the first edge portion and directed to the inside of the first electrode has an angle exceeding 90° with respect to the first tilt direction;
a portion of edges of the first electrode close to the second liquid crystal domain includes a second edge portion such that an azimuthal angle direction perpendicular to the second edge portion and directed to the inside of the first electrode has an angle exceeding 90° with respect to the second tilt direction;
a portion of edges of the first electrode close to the third liquid crystal domain includes a third edge portion such that an azimuthal angle direction perpendicular to the third edge portion and directed to the inside of the first electrode has an angle exceeding 90° with respect to the third tilt direction;
a portion of edges of the first electrode close to the fourth liquid crystal domain includes a fourth edge portion such that an azimuthal angle direction perpendicular to the fourth edge portion and directed to the inside of the first electrode has an angle exceeding 90° with respect to the fourth tilt direction; and
the first edge portion and the third edge portion are generally parallel to one of a horizontal direction and a vertical direction of a display plane, and the second edge portion and the fourth edge portion are generally parallel to the other of the horizontal direction and the vertical direction of the display plane; and
in the second picture element,
a portion of edges of the first electrode close to a first liquid crystal domain includes a first edge portion such that an azimuthal angle direction perpendicular to the first edge portion and directed to the inside of the first electrode has an angle exceeding 90° with respect to the first tilt direction;
a portion of edges of the first electrode close to the third liquid crystal domain includes a third edge portion such that an azimuthal angle direction perpendicular to the third edge portion and directed to the inside of the first electrode has an angle exceeding 90° with respect to the third tilt direction; and
the first edge portion and the third edge portion each include a first portion generally parallel to the horizontal direction of the display plane and a second portion generally parallel to the vertical direction of the display plane.

4. The liquid crystal display device of claim 1, wherein:
the side of each of the first picture element and the second picture element which is parallel to the second direction has a prescribed third length L3; and
the even number of picture elements further include a third picture element of which the side parallel to the second direction has a fourth length L4 which is different from the third length L3, and a fourth picture element of which the side parallel to the second direction has the fourth length L4.

5. The liquid crystal display device of claim 4, wherein:
in the third picture element, the first, second, third and fourth liquid crystal domains are arranged in a third pattern which is different from the first and second patterns; and
in the fourth picture element, the first, second, third and fourth liquid crystal domains are arranged in a fourth pattern which is different from the first, second and third patterns.

6. The liquid crystal display device of claim 1, wherein the at least four picture elements for displaying different colors from each other include a red picture element for displaying red, a green picture element for displaying green, a blue picture element for displaying blue, and a yellow picture element for displaying yellow.

7. The liquid crystal display device of claim 6, wherein the at least four picture elements further include a cyan picture element for displaying cyan, and a magenta picture element for displaying magenta.

8. A liquid crystal display device, comprising:
a vertical alignment type liquid crystal layer;
a first substrate and a second substrate facing each other with the liquid crystal layer interposed therebetween;
a first electrode provided on the liquid crystal layer side of the first substrate and a second electrode provided on the liquid crystal layer side of the second substrate; and
a pair of optical alignment films provided between the first electrode and the liquid crystal layer and between the second electrode and the liquid crystal layer;
wherein:
there are pixels which are each defined by a plurality of picture elements;
each of the plurality of picture elements includes a plurality of sub picture elements capable of applying different voltages to parts of the liquid crystal layer corresponding to the respective sub picture elements;
each of the plurality of sub picture elements includes a first liquid crystal domain in which a tilt direction of liquid crystal molecules at a center and in the vicinity thereof in a layer plane and in a thickness direction of the liquid crystal layer when a voltage is applied between the first electrode and the second electrode is a predetermined first tilt direction, a second liquid crystal domain in which the tilt direction is a predetermined second tilt direction, a third liquid crystal domain in which the tilt direction is a predetermined third tilt direction, and a fourth liquid crystal domain in which the tilt direction is a predetermined fourth tilt direction; the first, second, third and fourth tilt directions are such that a difference between any two of these four directions is approximately equal to an integral multiple of 90°; and the first, second, third and fourth liquid crystal domains are arranged in a matrix of 2 rows×2 columns;
the plurality of sub picture elements are an even number of sub picture elements each having a shape including a side parallel to a prescribed first direction and a side parallel to a second direction crossing the first direction;
the even number of sub picture elements include a first sub picture element of which the side parallel to the first direction has a prescribed first length L1 and a second sub picture element of which the side parallel to the first direction has a second length L2 which is different from the first length L1;
in the first sub picture element, the first, second, third and fourth liquid crystal domains are arranged in a first pattern; and
in the second sub picture element, the first, second, third and fourth liquid crystal domains are arranged in a second pattern which is different from the first pattern.

9. The liquid crystal display device of claim 8, wherein:
in each of the even number of sub picture elements, when a gray scale is displayed, a dark area darker than the gray scale appears;
the dark area appearing in the first sub picture element is generally gammadion-shaped; and
the dark area appearing in the second sub picture element is generally shaped like the letter “8”.

10. The liquid crystal display device of claim 8, wherein:
the first, second, third and fourth liquid crystal domains are located such that the tilt directions of two adjacent liquid crystal domains thereamong are different by 90° from each other;
the first tilt direction and the third tilt direction have an angle of about 180° with respect to each other;
in the first sub picture element,
a portion of edges of the first electrode close to the first liquid crystal domain includes a first edge portion such that an azimuthal angle direction perpendicular to the first edge portion and directed to the inside of the first electrode has an angle exceeding 90° with respect to the first tilt direction;
a portion of edges of the first electrode close to the second liquid crystal domain includes a second edge portion such that an azimuthal angle direction perpendicular to the second edge portion and directed to the inside of the first electrode has an angle exceeding 90° with respect to the second tilt direction;
a portion of edges of the first electrode close to the third liquid crystal domain includes a third edge portion such that an azimuthal angle direction perpendicular to the third edge portion and directed to the inside of the first electrode has an angle exceeding 90° with respect to the third tilt direction;
a portion of edges of the first electrode close to the fourth liquid crystal domain includes a fourth edge portion such that an azimuthal angle direction perpendicular to the fourth edge portion and directed to the inside of the first electrode has an angle exceeding 90° with respect to the fourth tilt direction; and
the first edge portion and the third edge portion are generally parallel to one of a horizontal direction and a vertical direction of a display plane, and the second edge portion and the fourth edge portion are generally parallel to the other of the horizontal direction and the vertical direction of the display plane; and
in the second sub picture element,
a portion of edges of the first electrode close to a first liquid crystal domain includes a first edge portion such that an azimuthal angle direction perpendicular to the first edge portion and directed to the inside of the first electrode has an angle exceeding 90° with respect to the first tilt direction;
a portion of edges of the first electrode close to the third liquid crystal domain includes a third edge portion such that an azimuthal angle direction perpendicular to the third edge portion and directed to the inside of the first electrode has an angle exceeding 90° with respect to the third tilt direction; and
the first edge portion and the third edge portion each include a first portion generally parallel to the horizontal direction of the display plane and a second portion generally parallel to the vertical direction of the display plane.

11. The liquid crystal display device of claim 1, further comprising a pair of polarizing plates facing each other with the liquid crystal layer interposed therebetween and located such that transmission axes thereof are generally perpendicular to each other;
wherein the tilt directions of the first, second, third and fourth liquid crystal domains have an angle of about 45° with respect to the transmission axes of the pair of polarizing plates.

12. The liquid crystal display device of claim 1, wherein:
the liquid crystal layer contains the liquid crystal molecules having a negative dielectric anisotropy; and
a pretilt direction defined by one of the pair of optical alignment films and a pretilt direction defined by the other of the pair of optical alignment films are different by 90° from each other.

13. A method for producing a liquid crystal display device, the liquid crystal display device including:
a vertical alignment type liquid crystal layer;
a first substrate and a second substrate facing each other with the liquid crystal layer interposed therebetween;
a first electrode provided on the liquid crystal layer side of the first substrate and a second electrode provided on the liquid crystal layer side of the second substrate; and
a first optical alignment film provided between the first electrode and the liquid crystal layer and a second optical alignment film provided between the second electrode and the liquid crystal layer;
wherein:
there are pixels which are each defined by a plurality of picture elements each having a shape including a side parallel to a prescribed first direction and a side parallel to a second direction crossing the first direction;
each of the plurality of picture elements includes a first liquid crystal domain in which a tilt direction of liquid crystal molecules at a center and in the vicinity thereof in a layer plane and in a thickness direction of the liquid crystal layer when a voltage is applied between the first electrode and the second electrode is a predetermined first tilt direction, a second liquid crystal domain in which the tilt direction is a predetermined second tilt direction, a third liquid crystal domain in which the tilt direction is a predetermined third tilt direction, and a fourth liquid crystal domain in which the tilt direction is a predetermined fourth tilt direction; the first, second, third and fourth tilt directions are such that a difference between any two of these four directions is approximately equal to an integral multiple of 90°; and the first, second, third and fourth liquid crystal domains are arranged in a matrix of 2 rows×2 columns;
the plurality of picture elements are an even number of picture elements including at least four picture elements for displaying different colors from each other; and
the even number of picture elements include a first picture element of which the side parallel to the first direction has a prescribed first length L1 and a second picture element of which the side parallel to the first direction has a second length L2 which is different from the first length L1;
the method comprising:
a step (A) of forming a first area having a first pretilt direction and a second area having a second pretilt direction which is antiparallel to the first pretilt direction, in an area of the first optical alignment film corresponding to each of the even number of picture elements by optical alignment processing; and
a step (B) of forming a third area having a third pretilt direction and a fourth area having a fourth pretilt direction which is antiparallel to the third pretilt direction, in an area of the second optical alignment film corresponding to each of the even number of picture elements by optical alignment processing;
wherein:
the step (A) of forming the first area and the second area includes:
a first exposure step of directing light to a part of the first optical alignment film which is to be the first area; and
a second exposure step of directing light to a part of the first optical alignment film which is to be the second area, after the first exposure step;
the first exposure step and the second exposure step are performed by use of one, common first photomask including a plurality of light shielding parts extending like stripes parallel to the second direction and a plurality of light transmitting parts located between the plurality of light shielding parts; and
each of the plurality of light transmitting parts of the first photomask has a width W1 which is equal to a sum of half of the first length L1 and half of the second length L2.

14. The method for producing a liquid crystal display device of claim 13, wherein:
the step (A) of forming the first area and the second area further includes:
a first photomask locating step of, before the first exposure step, locating the first photomask such that a part of the first optical alignment film corresponding to about half of the first picture element and about half of the second picture element overlaps each of the plurality of light transmitting parts; and
a first photomask moving step of, between the first exposure step and the second exposure step, shifting the first photomask in the first direction by a prescribed distance D1.

15. The method for producing a liquid crystal display device of claim 14, wherein the prescribed distance D1 is about 1/m (m is an even number of 2 or greater) of a width PW1 of the pixel in the first direction.

16. The method for producing a liquid crystal display device of claim 13, wherein the width W1 of each of the plurality of light transmitting parts, a width W2 of each of the plurality of light shielding parts, the first length L1 and the second L2 fulfill the following relationship expression:
W1=W2=(L1+L2)/2.

17. The method for producing a liquid crystal display device of claim 13, wherein the width W1 (μm) of each of the plurality of light transmitting parts, a width W2 (μm) of each of the plurality of light shielding parts, the first length L1 (μm) and the second length L2 (μm) fulfill the following relationship expressions:
W1=(L1+L2)/2+Δ
W2=(L1+L2)/2−Δ
0<Δ≦10.

18. The method for producing a liquid crystal display device of claim 13, wherein:
the side of each of the first picture element and the second picture element which is parallel to the second direction has a prescribed third length L3;
the even number of picture elements further include a third picture element of which the side parallel to the second direction has a fourth length L4 which is different from the third length L3, and a fourth picture element of which the side parallel to the second direction has the fourth length L4;
the step (B) of forming the third area and the fourth area includes:
a third exposure step of directing light to a part of the second optical alignment film which is to be the third area; and
a fourth exposure step of directing light to a part of the second optical alignment film which is to be the fourth area, after the third exposure step;
the third exposure step and the fourth exposure step are performed by use of one, common second photomask including a plurality of light shielding parts extending like stripes parallel to the first direction and a plurality of light transmitting parts located between the plurality of light shielding parts; and
each of the plurality of light transmitting parts of the second photomask has a width W3 which is equal to a sum of half of the third length L3 and half of the fourth length L4.

19. The method for producing a liquid crystal display device of claim 18, wherein:
the step (B) of forming the third area and the fourth area further includes:
a second photomask locating step of, before the third exposure step, locating the second photomask such that a part of the second optical alignment film corresponding to about half of the third picture element and about half of the fourth picture element overlaps each of the plurality of light transmitting parts; and
a second photomask moving step of, between the third exposure step and the fourth exposure step, shifting the second photomask in the second direction by a prescribed distance D2.

20. The method for producing a liquid crystal display device of claim 19, wherein the prescribed distance D2 is about 1/n (n is an even number of 2 or greater) of a width PW2 of the pixel in the second direction.

21. The method for producing a liquid crystal display device of claim 18, wherein the width W3 of each of the plurality of light transmitting parts of the second photomask, a width W4 of each of the plurality of light shielding parts of the second photomask, the third length L3 and the fourth length L4 fulfill the following relationship expression:
W3=W4=(L3+L4)/2.

22. The method for producing a liquid crystal display device of claim 18, wherein the width W3 (μm) of each of the plurality of light transmitting parts of the second photomask, a width W4 (μm) of each of the plurality of light shielding parts of the second photomask, the third length L3 (μm) and the fourth length L4 (μm) fulfill the following relationship expressions:
W3=(L3+L4)/2+Δ′
W4=(L3+L4)/2−Δ′
0<Δ′≦10.

23. A method for producing a liquid crystal display device, the liquid crystal display device including:
a vertical alignment type liquid crystal layer;
a first substrate and a second substrate facing each other with the liquid crystal layer interposed therebetween;
a first electrode provided on the liquid crystal layer side of the first substrate and a second electrode provided on the liquid crystal layer side of the second substrate; and
a first of optical alignment film provided between the first electrode and the liquid crystal layer and a second optical alignment film provided between the second electrode and the liquid crystal layer;
wherein:
there are pixels which are each defined by a plurality of picture elements;
each of the plurality of picture elements includes a plurality of sub picture elements capable of applying different voltages to parts of the liquid crystal layer corresponding to the respective sub picture elements;
each of the plurality of sub picture elements includes a first liquid crystal domain in which a tilt direction of liquid crystal molecules at a center and in the vicinity thereof in a layer plane and in a thickness direction of the liquid crystal layer when a voltage is applied between the first electrode and the second electrode is a predetermined first tilt direction, a second liquid crystal domain in which the tilt direction is a predetermined second tilt direction, a third liquid crystal domain in which the tilt direction is a predetermined third tilt direction, and a fourth liquid crystal domain in which the tilt direction is a predetermined fourth tilt direction; the first, second, third and fourth tilt directions are such that a difference between any two of these four directions is approximately equal to an integral multiple of 90°; and the first, second, third and fourth liquid crystal domains are arranged in a matrix of 2 rows×2 columns;
the plurality of sub picture elements are an even number of sub picture elements each having a shape including a side parallel to a prescribed first direction and a side parallel to a second direction crossing the first direction; and
the even number of sub picture elements include a first sub picture element of which the side parallel to the first direction has a prescribed first length L1 and a second sub picture element of which the side parallel to the first direction has a second length L2 which is different from the first length L1;
the method comprising:
a step (A) of forming a first area having a first pretilt direction and a second area having a second pretilt direction which is antiparallel to the first pretilt direction, in an area of the first optical alignment film corresponding to each of the even number of sub picture elements by optical alignment processing; and
a step (B) of forming a third area having a third pretilt direction and a fourth area having a fourth pretilt direction which is antiparallel to the third pretilt direction, in an area of the second optical alignment film corresponding to each of the even number of sub picture elements by optical alignment processing;
wherein:
the step (A) of forming the first area and the second area includes:
a first exposure step of directing light to a part of the first optical alignment film which is to be the first area; and
a second exposure step of directing light to a part of the first optical alignment film which is to be the second area, after the first exposure step;
the first exposure step and the second exposure step are performed by use of one, common first photomask including a plurality of light shielding parts extending like stripes parallel to the second direction and a plurality of light transmitting parts located between the plurality of light shielding parts; and
each of the plurality of light transmitting parts of the first photomask has a width W1 which is equal to a sum of half of the first length L1 and half of the second length L2.

24. The method for producing a liquid crystal display device of claim 23, wherein:
the step (A) of forming the first area and the second area further includes:
a first photomask locating step of, before the first exposure step, locating the first photomask such that a part of the first optical alignment film corresponding to about half of the first sub picture element and about half of the second sub picture element overlaps each of the plurality of light transmitting parts; and
a first photomask moving step of, between the first exposure step and the second exposure step, shifting the first photomask in the first direction by a prescribed distance D1.

25. The method for producing a liquid crystal display device of claim 24, wherein the prescribed distance D1 is about 1/m (m is an even number of 2 or greater) of a width PW1 of the picture element in the first direction.

26. The method for producing a liquid crystal display device of claim 23, wherein the width W1 of each of the plurality of light transmitting parts, a width W2 of each of the plurality of light shielding parts, the first length L1 and the second L2 fulfill the following relationship expression:
W1=W2=(L1+L2)/2.

27. The method for producing a liquid crystal display device of claim 23, wherein the width W1 (μm) of each of the plurality of light transmitting parts, a width W2 (μm) of each of the plurality of light shielding parts, the first length L1 (μm) and the second length L2 (μm) fulfill the following relationship expressions:
W1=(L1+L2)/2+Δ
W2=(L1+L2)/2−Δ
0<Δ≦10.
